(19) United States
(12) Patent Application Publication
(10) Pub. No.: US 2025/0208507 A1
(43) Pub. Date: Jun. 26, 2025

(54) FILM-FORMING COMPOSITION, METHOD FOR PRODUCING CURED FILM, CAGE-TYPE SILSESQUIOXANE, AND CYCLIC SILOXANE

(71) Applicant: TOKYO OHKA KOGYO CO., LTD., Kawasaki-shi (JP)

(72) Inventors: Keiichi IBATA, Kawasaki-shi (JP); Hayato OUCHI, Kawasaki-shi (JP)

(21) Appl. No.: 19/001,974

(22) Filed: Dec. 26, 2024

(30) Foreign Application Priority Data
Dec. 26, 2023 (JP) 2023-219954

(51) Int. Cl. G03F 7/075; G03F 7/004; G03F 7/20

(52) U.S. Cl. CPC G03F 7/0757; G03F 7/0045; G03F 7/0752; G03F 7/2004

(57) ABSTRACT

A film-forming composition containing a silicon-containing compound and having an enhanced effect of reducing roughness of a pattern, a method for producing a patterned cured film using the composition, and a cage-type silsesquioxane and a cyclic siloxane used for the composition. The film-forming composition contains a silicon-containing polymer having a phenolic hydroxy group; a photoacid generating agent; a silicon-containing crosslinking agent having a methylol group and/or an alkoxymethyl group; and a base component that controls diffusion of an acid generated upon exposure, or the photoacid generating agent; a silicon-containing crosslinking agent having a methylol group and/or an alkoxymethyl group and a phenolic hydroxy group; and the base component.

This application claims priority to Japanese Patent Application No. 2023-219954, filed Dec. 26, 2023, the entire content of which is incorporated herein by reference.

### BACKGROUND OF THE INVENTION

### Field of the Invention

The present invention relates to a film-forming composition, a method for producing a patterned cured film, a cage-type silsesquioxane, and a cyclic siloxane.

### Related Art

In the production of electronic components, a laminate obtained by forming a resist film on a substrate such as a silicon wafer using a resist material is subjected to a treatment including etching. For example, a treatment is performed in which a resist pattern is formed on a resist film by selectively exposing the resist film, and dry etching is performed using the resist pattern as a mask to form a pattern on a substrate.

In recent years, in the production of semiconductor devices and liquid crystal display devices, advances in lithography techniques have led to rapid progress in the field of pattern miniaturization. As a method for miniaturizing a pattern, a wavelength of an exposure light source is generally shortened (energy is increased).

Resist materials are required to exhibit lithography properties such as sensitivity to these exposure light sources and resolution capable of reproducing patterns having very small dimensions. As a resist material that satisfies these requirements, a chemically amplified resist composition is used. The chemically amplified resist composition contains a base material component that exhibits changed solubility in a developing solution under action of an acid and an acid generation agent component to generate an acid upon exposure to light. In a chemically amplified resist composition, a resin having a plurality of constitutional units is generally used for improving lithography properties and the like. Further, a chemically amplified resist composition obtained by using an acid diffusion control agent for controlling diffusion of the acid generated from the acid generation agent component upon exposure to light in combination with the acid generation agent component has been proposed.

The resist material is required to be a material having etching resistance in order to function as a mask for substrate processing. In contrast, a silicon-containing compound is generally used as the base component. For example, Patent Document 1 discloses a resist composition that contains a silicon-containing resin, an acid generation agent component, and a photodegradable base for controlling acid diffusion in order to cope with pattern miniaturization and etching.
Patent Document 1: Japanese Unexamined Patent Application, Publication No. 2022-59575

### SUMMARY OF THE INVENTION

With further progress in lithography techniques and expansion of application fields, pattern miniaturization is rapidly progressing. Accordingly, when a semiconductor device or the like is produced, a technique capable of forming a pattern having very small dimensions in a good shape is required. For example, in lithography using extreme ultraviolet rays (EUV), formation of a fine pattern of several tens of nanometers is targeted. In this way, as the pattern dimension is reduced, it becomes more difficult to achieve both etching resistance and lithography properties. In contrast, the film-forming composition containing a silicon-containing compound as a base component as disclosed in Patent Document 1 has an advantage of high dry etching resistance as compared with a film-forming composition containing a general organic material as a base component, but in the formation of a target fine pattern, it is necessary to further improve the effect of reducing the roughness of the pattern.

The present invention has been made in view of the above circumstances, and an object of the present invention is to provide a film-forming composition containing a silicon-containing compound and having an enhanced effect of reducing roughness of a pattern, a method for producing a patterned cured film using the film-forming composition, and a cage-type silsesquioxane used for the film-forming composition.

As a result of intensive studies to solve the above problems, the present inventors have found that the above problems can be solved by using a silicon-containing crosslinking agent having a methylol group and/or an alkoxymethyl group, and have completed the present invention. Specifically, the present invention provides the following aspects.

[1]A film-forming composition containing: a silicon-containing polymer (A) having a phenolic hydroxy group; a photoacid generating agent (B); a silicon-containing crosslinking agent (C1) having a methylol group and/or an alkoxymethyl group; and a base component (D) that controls diffusion of an acid generated upon exposure to light, or
the photoacid generating agent (B); a silicon-containing crosslinking agent (C2) having a methylol group and/or an alkoxymethyl group and a phenolic hydroxy group; and the base component (D).
   [2] The film-forming composition as described in aspect [1], in which the methylol group and/or the alkoxymethyl group contained in the silicon-containing crosslinking agent (C1) or the silicon-containing crosslinking agent (C2) are/is bonded to an aromatic group or a nitrogen atom.
   [3] The film-forming composition as described in aspect [1] or [2], in which the silicon-containing crosslinking agent (C1) contains at least one selected from the group consisting of a cage-type silsesquioxane (C1-1) represented by the following formula (c1-1) and a cyclic siloxane (C1-2) represented by the following formula (c1-2), and
the silicon-containing crosslinking agent (C2) contains at least one selected from the group consisting of a cage-type silsesquioxane (C2-1) represented by the following formula (c2-1) and a cyclic siloxane (C2-2) represented by the following formula (c2-2):

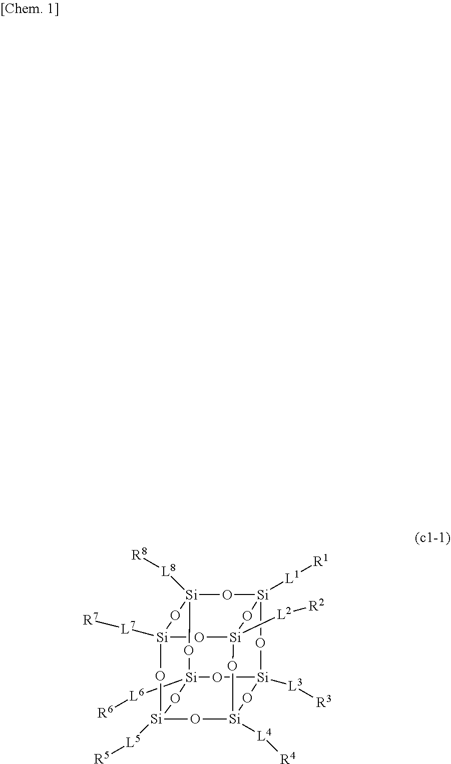

wherein R¹ to R⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R¹ to R⁸ represents an aromatic group having a methylol group or an alkoxymethyl group, or a nitrogen atom-containing group having a methylol group or an alkoxymethyl group, L¹ to L⁸ each independently represent a divalent linking group represented by any one of the following formulas (c1-L-1) to (c1-L-7):

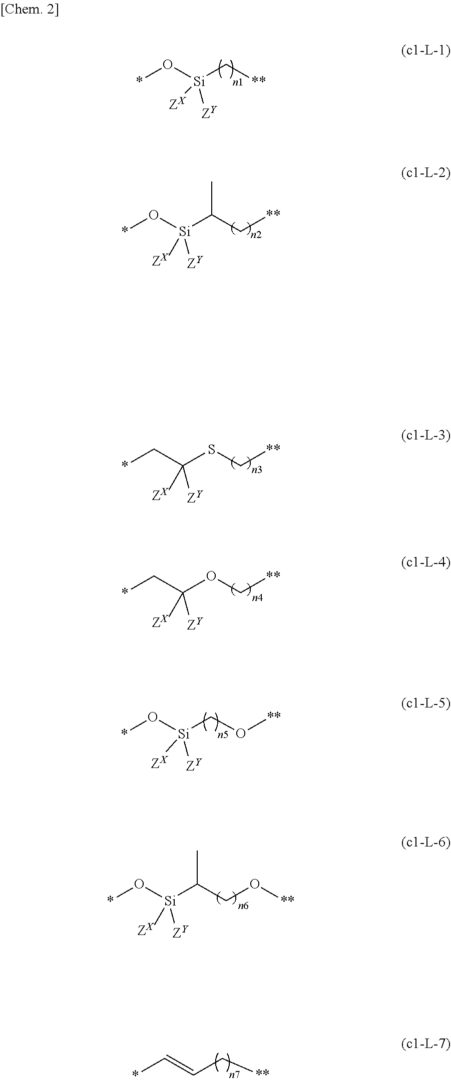

wherein Z^{X} and Z^{Y} each independently represent a hydrocarbon group having 1 or more and 6 or less carbon atoms or a hydrogen atom, n1 to n7 each independently represent an integer of 0 or more and 10 or less, * represents a bonding site to Si, ** represents a bonding site to any one of R¹ to R⁸,

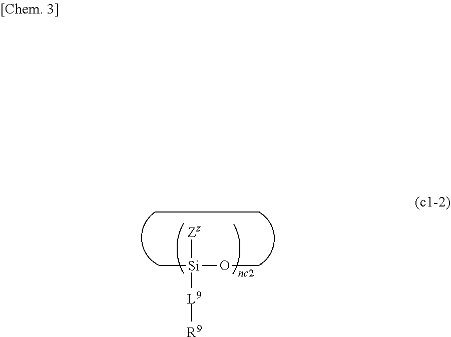

wherein R⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁹ represents an aromatic group having a methylol group or an alkoxymethyl group, or a nitrogen atom-containing group having a methylol group or an alkoxymethyl group, L⁹ each independently represent a divalent linking group represented by any one of the following formulas (c2-L-1) to (c2-L-6), nc2 represents an integer of 3 or more and 7 or less, Z^{Z} each independently represent a hydrocarbon group having 1 or more and 6 or less carbon atoms or a hydrogen atom,

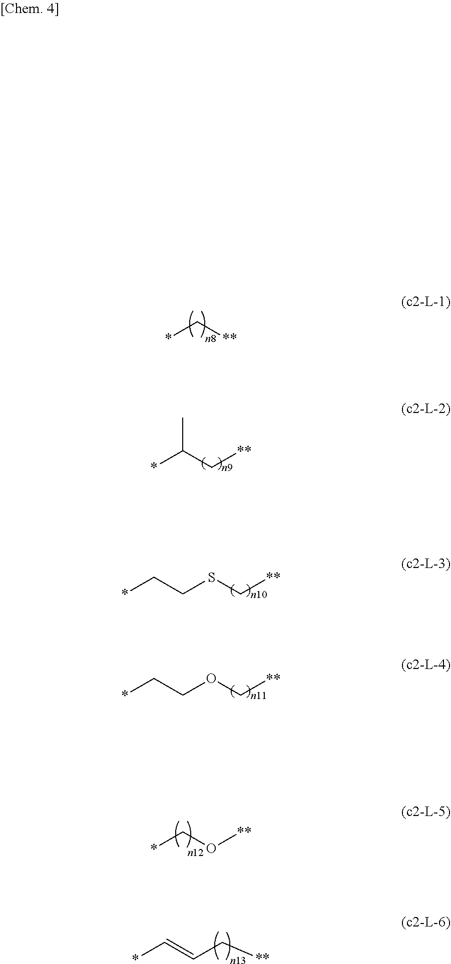

wherein n8 to n13 each independently represent an integer of 0 or more and 10 or less, * represents a bonding site to Si, ** represents a bonding site to R⁹,

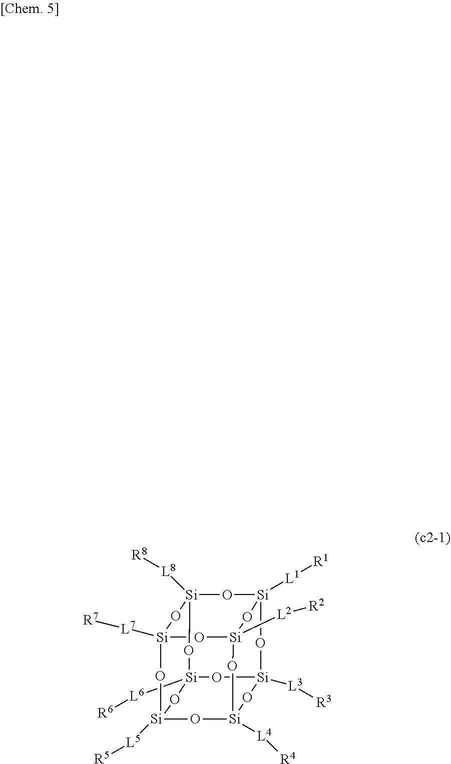

wherein R¹ to R⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R¹ to R⁸ represents an aromatic group having a methylol group or an alkoxymethyl group, or a nitrogen atom-containing group having a methylol group or an alkoxymethyl group, at least another one of R¹ to R⁸ represents an aromatic group having a phenolic hydroxy group, L¹ to L⁸ each independently represent a divalent linking group represented by any one of the formulas (c1-L-1) to (c1-L-7):

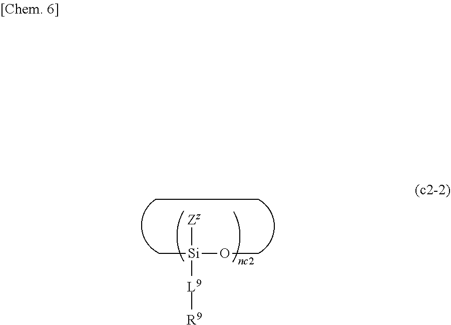

wherein R⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁹ represents an aromatic group having a methylol group or an alkoxymethyl group, or a nitrogen atom-containing group having a methylol group or an alkoxymethyl group, at least another one of R⁹ represents an aromatic group having a phenolic hydroxy group, L⁹ each independently represent a divalent linking group represented by any one of the above formulas (c2-L-1) to (c2-L-6), nc2 represents an integer of 3 or more and 7 or less, and Z^{Z} each independently represent a hydrocarbon group having 1 or more and 6 or less carbon atoms or a hydrogen atom.
   [4] The film-forming composition as described in any one of aspects [1] to [3], in which the silicon-containing polymer (A) contains a silicon-containing polymer (A0) having a constitutional unit represented by the following formula (a0-1):

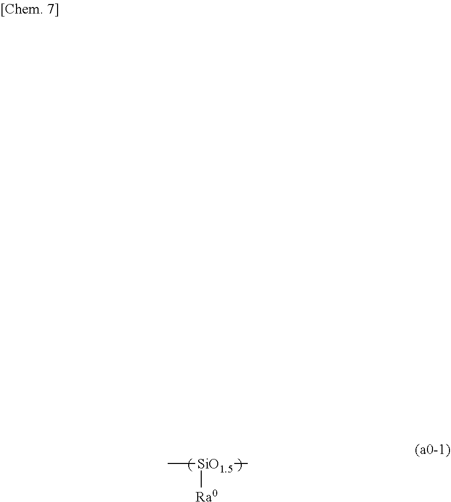

wherein Ra⁰ represents an organic group having 1 or more and 40 or less carbon atoms or a hydrogen atom.
   [5] The film-forming composition as described in aspect [4], in which the silicon-containing polymer (A0) has a constitutional unit represented by the following formula (a0-1-1)

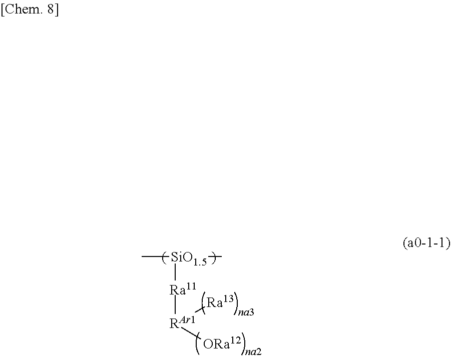

wherein R^{Ar1} represents an aromatic hydrocarbon group, Ra¹¹ represents a divalent linking group or a single bond, Ra¹² represents a hydrocarbon group having 1 or more and 6 or less carbon atoms or a hydrogen atom, Ra¹³ represents a hydrocarbon group having 1 or more and 6 or less carbon atoms or a hydrogen atom, na2 represents 1 or 2, and na3 represents an integer of 0 or more and 4 or less.
   [6] The film-forming composition as described in any one of aspects [1] to [5], in which the photoacid generating agent (B) contains an onium salt represented by the following formula (b0):

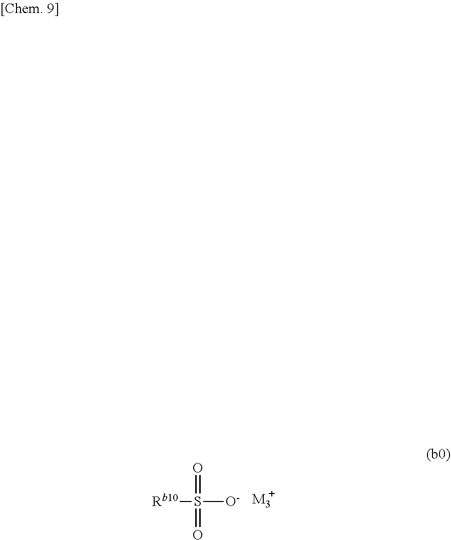

wherein R^{b10} represents an organic group having 1 or more and 40 or less carbon atoms, and M₃⁺ represents an onium cation.
   [7] The film-forming composition as described in any one of aspects [1] to [6], in which the base component (D) contains at least one selected from the group consisting of a compound represented by the following formula (d0-1) and a compound represented by the following formula (d0-2):

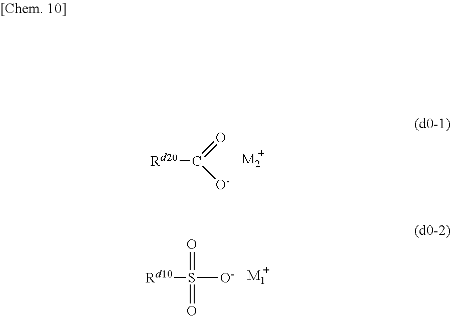

wherein R^{d20} represents an organic group having 1 or more and 40 or less carbon atoms, M₂⁺ represents an onium cation,
wherein R^{d10} represents an organic group having 1 or more and 40 or less carbon atoms, and M₁⁺ represents an onium cation.
   [8]A method for producing a patterned cured film, the method including: forming a coating film made of the film-forming composition according to any one of aspects [1] to [7] on a support;
exposing the coating film position-selectively; and
developing the exposed coating film to form a patterned cured film.
   [9] The method for producing a patterned cured film as described in aspect [8], in which the coating film is exposed to extreme ultraviolet rays (EUV).
   [10]A cage-type silsesquioxane represented by the following formula (c0-1):

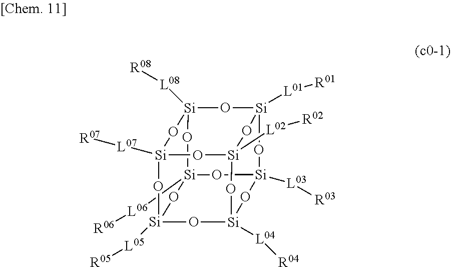

wherein R⁰¹ to R⁰⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁰¹ to R⁰⁸ represents an aromatic group having a methylol group or an alkoxymethyl group, or a nitrogen atom-containing group having a methylol group or an alkoxymethyl group, L⁰¹ to L^{0B} each independently represent a divalent linking group represented by any one of the following formulas (c0-L-1) to (c0-L-3) and (c0-L-5) to (c0-L-7):

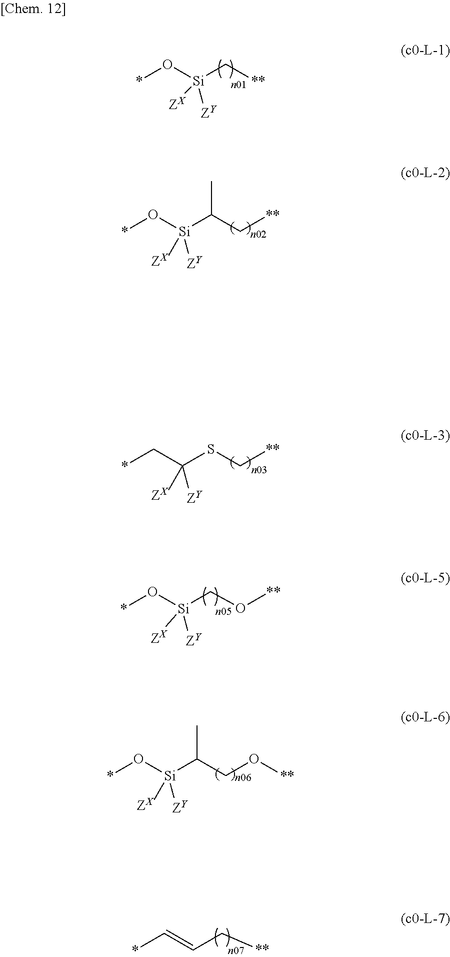

wherein Z^{X} and Z^{Y} each independently represent a hydrocarbon group having 1 to 6 carbon atoms or a hydrogen atom, n01 represents an integer of 0 or more, n02 represents an integer of 0 or more, n03 represents an integer of 0 or more, n05 represents an integer of 0 or more, n06 represents an integer of 0 or more, n07 represents an integer of 0 or more, when all R⁰¹ to R⁰⁸ represent an aromatic group having a methylol group, n01 represents an integer of 3 or more, and n02 represents an integer of 1 or more, * represents a bonding site to Si, and ** represents a bonding site to any one of R⁰¹ to R⁰⁸.
   [11]A cyclic siloxane represented by the following formula (c0-2):

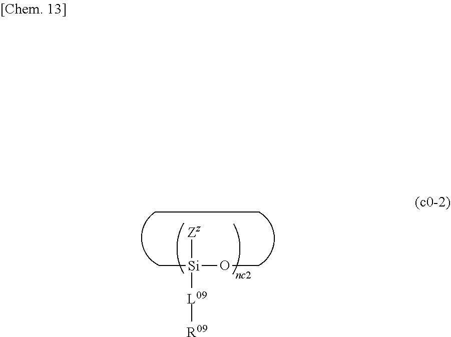

wherein R⁰⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁰⁹ represents an aromatic group having a methylol group or an alkoxymethyl group, or a nitrogen atom-containing group having a methylol group or an alkoxymethyl group, L⁰⁹ each independently represent a divalent linking group represented by any one of the following formulas (c0-L-8) to (c0-L-10), (c0-L-12), and (c0-L-13), nc2 represents an integer of 3 or more and 7 or less, Z^{Z} each independently represent a hydrocarbon group having 1 or more and 6 or less carbon atoms or a hydrogen atom,

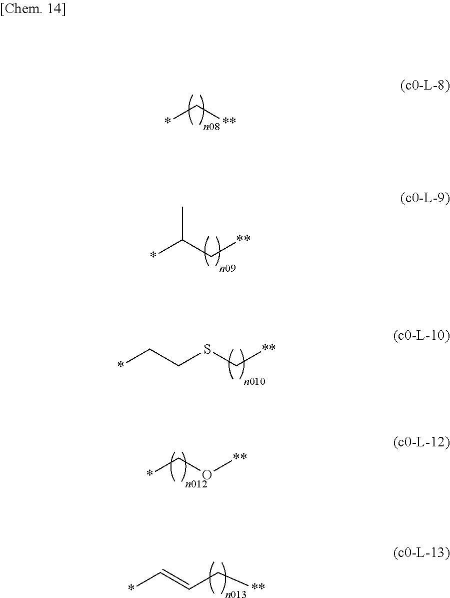

wherein n08 represents an integer of 0 or more, n09 represents an integer of 0 or more, n010 represents an integer of 0 or more, n012 represents an integer of 0 or more, n013 represents an integer of 0 or more, when all R⁰⁹ represent an aromatic group having a methylol group or an alkoxymethyl group, n08 represents an integer of 2 or more, and n012 represent an integer of 2 or more, * represents a bonding site to Si, and ** represents a bonding site to R⁰⁹.

According to the present invention, it is possible to provide a film-forming composition containing a silicon-containing compound and having an enhanced effect of reducing roughness of a pattern, a method for producing a patterned cured film using the film-forming composition, and a cage-type silsesquioxane and a cyclic siloxane used for the film-forming composition.

### DETAILED DESCRIPTION OF THE INVENTION

Hereinafter, embodiments of the present invention will be described in detail, but the present invention is not limited to the following embodiments, and can be implemented with appropriate modifications within the scope of the object of the present invention.

### <<Film-Forming Composition>>

A film-forming composition contains: a silicon-containing polymer (A) having a phenolic hydroxy group; a photoacid generating agent (B); a silicon-containing crosslinking agent (C1) having a methylol group and/or an alkoxymethyl group; and a base component (D) that controls diffusion of an acid generated upon exposure to light, or the photoacid generating agent (B); a silicon-containing crosslinking agent (C2) having a methylol group and/or an alkoxymethyl group and a phenolic hydroxy group; and the base component (D). Hereinafter, the film-forming composition containing the silicon-containing polymer (A), the photoacid generating agent (B), the silicon-containing crosslinking agent (C1), and the base component (D) is referred to as a first film-forming composition. The film-forming composition containing the photoacid generating agent (B), the silicon-containing crosslinking agent (C2), and the base component (D) is referred to as a second film-forming composition.

### <First Film-Forming Composition>

As described above, the first film-forming composition contains the silicon-containing polymer (A), the photoacid generating agent (B), the silicon-containing crosslinking agent (C1), and the base component (D). Hereinafter, essential components and other components of the first film-forming composition will be described.

### [Silicon-Containing Polymer (A)]

The first film-forming composition contains the silicon-containing polymer (A) having a phenolic hydroxy group (hereinafter also referred to as “component (A)”). The component (A) has a phenolic hydroxy group and a silicon atom in the same polymer. When the silicon-containing polymer (A) is used, the etching resistance of a resist film formed of a negative resist composition is particularly enhanced. In addition, the aromatic group having a phenolic hydroxy group in the silicon-containing polymer and the methylol group and/or alkoxymethyl group contained in the silicon-containing crosslinking agent (C1) are subjected to an action of the acid generated from the component (B) described below upon exposure to light to form a crosslinked structure. Accordingly, the molecular weight of the component increases. Further, the component (A) has a phenolic hydroxy group, and therefore, the component (A) is soluble in an alkaline developing solution and imparts alkaline developability to the negative resist composition.

The content of silicon atoms in the component (A) is preferably 5% or more and 50% or less, more preferably 10% or more and 40% or less, and still more preferably 15% or more and 30% or less with respect to the total amount of all atoms constituting the component (A).

The content of the silicon atoms in the component (A) can be calculated by the following formula.

Content (%) of silicon atoms={(number of silicon atoms present in silicon-containing polymer×atomic mass of silicon atoms)/(total atomic mass calculated by adding values obtained by multiplying the number of atoms constituting silicon-containing polymer by each atomic mass)}×100

For example, in the case of a polysiloxane having a repeating structure of a constitutional unit represented by —[Si(H)O_{3/2}]—, the content of the silicon atom is [(28×1)/{(28×1)+(16×1.5)+(1×1)}]×100≈52.8%.

The silicon-containing polymer (A) preferably contains a silicon-containing polymer (A0) having a constitutional unit represented by the following formula (a0-1).

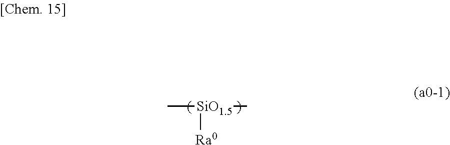

(In the formula (a0-1), Ra⁰ represents an organic group having 1 or more and 40 or less carbon atoms or a hydrogen atom.)

The organic group for Ra⁰ is preferably an aliphatic hydrocarbon group, an aromatic hydrocarbon group which may have a substituent, or a combination thereof.

The number of carbon atoms in the aliphatic hydrocarbon group for Ra⁰ is preferably 1 or more and 20 or less, more preferably 1 or more and 10 or less, and still more preferably 1 or more and 5 or less. The aliphatic hydrocarbon group for Ra⁰ is preferably a saturated aliphatic hydrocarbon group, and more preferably a linear aliphatic hydrocarbon group. The number of carbon atoms in the aromatic hydrocarbon group for Ra⁰ is preferably 6 or more and 20 or less, more preferably 6 or more and 15 or less, still more preferably 6 or more and 12 or less, and particularly preferably 6 or more and 10 or less. Examples of the aromatic ring contained in the aromatic group for Ra⁰ include a benzene ring and a naphthalene ring. Examples of the substituent which the aromatic hydrocarbon group for Ra⁰ may have include a hydroxy group, an alkyl group having 1 or more and 6 or less carbon atoms, and an alkoxy group having 1 or more and 6 or less carbon atoms.

The silicon-containing polymer (A0) preferably has a constitutional unit represented by the following formula (a0-1-1).

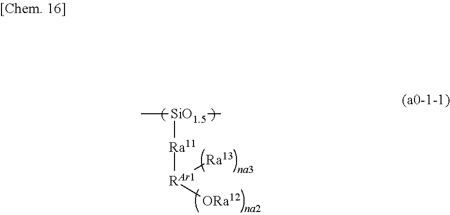

(In the formula (a0-1-1), R^{Ar1} represents an aromatic hydrocarbon group. Ra¹¹ represents a divalent linking group or a single bond. Ra¹² represents a hydrocarbon group having 1 or more and 6 or less carbon atoms or a hydrogen atom. Ra¹³ represents a hydrocarbon group having 1 or more and 6 or less carbon atoms or a hydrogen atom. na2 represents 1 or 2. na3 represents an integer of 0 or more and 4 or less.)

The number of carbon atoms in the aromatic hydrocarbon group for R^{Ar1} is preferably 6 or more and 20 or less, more preferably 6 or more and 15 or less, still more preferably 6 or more and 12 or less, and particularly preferably 6 or more and 10 or less. Examples of the aromatic hydrocarbon group for R^{Ar1} include groups obtained by removing one or more hydrogen atoms from a benzene ring or a naphthalene ring. Among them, a group obtained by removing one or more hydrogen atoms from a benzene ring is preferable.

The divalent linking group for Ra¹¹ is preferably an alkylene group, and more preferably a linear alkylene group. The number of carbon atoms in the alkylene group for Ra¹¹ is preferably 1 or more and 5 or less, and more preferably 1 or more and 3 or less. Examples of the alkylene group as Ra¹¹ include a methylene group, an ethane-1,2-diyl group, a propane-1,2-diyl group, a propane-1,3-diyl group, a butane-1,4-diyl group, and a pentane-1,5-diyl group. Among them, a methylene group, an ethane-1,2-diyl group, a propane-1,2-diyl group, and a propane-1,3-diyl group are preferable, a methylene group and an ethane-1,2-diyl group are more preferable, and a methylene group is still more preferable.

The hydrocarbon group for Ra¹² is preferably an aliphatic hydrocarbon group, and is more preferably an alkyl group. Examples of the alkyl group for Ra¹² include a methyl group, an ethyl group, an n-propyl group, an isopropyl group, a butyl group, an isobutyl group, a sec-butyl group, a tert-butyl group, an n-pentyl group, and an n-hexyl group. Ra¹² is preferably a hydrogen atom.

The hydrocarbon group for Ra¹³ is preferably an aliphatic hydrocarbon group, and more preferably an alkyl group. Examples of the alkyl group for Ra¹³ include a methyl group, an ethyl group, an n-propyl group, an isopropyl group, a butyl group, an isobutyl group, a sec-butyl group, a tert-butyl group, an n-pentyl group, and an n-hexyl group.

na2 is preferably 1. na3 is preferably 0 or 1, and more preferably 0.

One kind of the constitutional unit (a0-1-1) contained in the silicon-containing polymer (A0) may be used, or two or more kinds thereof may be used. When the silicon-containing polymer (A0) has the constitutional unit (a0-1-1), the proportion of the constitutional unit (a0-1-1) in the silicon-containing polymer (A0) is preferably 30 mol % or more, more preferably 40 mol % or more, still more preferably 50 mol % or more with respect to the total of all constitutional units constituting the silicon-containing polymer (A0). When the proportion of the constitutional unit (a0-1-1) is at least 30 mol %, a resist pattern having excellent lithography properties is easily formed. The proportion of the constitutional unit (a0-1-1) is preferably 90 mol % or less, more preferably 80 mol % or less, and still more preferably 70 mol % or less.

### (Other Constitutional Units)

The silicon-containing polymer (A0) may have other constitutional units. Examples of other constitutional units include a constitutional unit (a2) containing an alkyl group, a constitutional unit (a3) represented by the following formula (a3-1), and a constitutional unit (a4) represented by the following formula (a4-1).

### ⋅Constitutional Unit (a2)

The constitutional unit (a2) is a constitutional unit containing an alkyl group. Examples of the constitutional unit (a2) include constitutional units in which a main chain portion is a Si—O bond, and a side chain portion bonded to a Si atom of the main chain portion is an alkyl group. The properties of the resist film formed using the negative resist composition can be easily controlled when the constitutional unit (a2) is contained.

Preferable examples of the constitutional unit (a2) include a constitutional unit represented by the following formula (a2-1) and a constitutional unit represented by the following formula (a2-2).

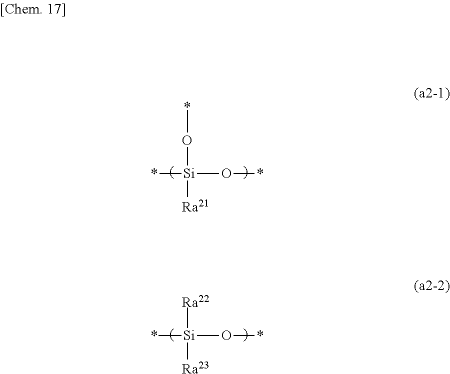

(In the formula, Ra²¹, Ra²², and Ra²³ each independently represent an alkyl group having 1 or more and 10 or less carbon atoms.)

The alkyl group for Ra²¹, Ra²², and Ra²³ may be linear, branched, or cyclic, and is preferably linear or branched. The number of carbon atoms in the alkyl group for Ra²¹, Ra²², and Ra²³ is preferably 1 or more and 5 or less, and more preferably 1 or more and 3 or less. Examples of the alkyl group for Ra²¹, Ra²², and Ra²³ include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, an n-decyl group, and a 2-ethylhexyl group. Among them, a methyl group, an ethyl group, an n-propyl group, an isopropyl group, an n-butyl group, an isobutyl group, a sec-butyl group, a tert-butyl group, and an n-pentyl group are preferable, a methyl group, an ethyl group, a propyl group, and an isopropyl group are more preferable, a methyl group and an ethyl group are still more preferable, and a methyl group is particularly preferable.

One kind of the constitutional unit (a2) contained in the silicon-containing polymer (A0) may be used, or two or more kinds thereof may be used. When the silicon-containing polymer (A0) contains the constitutional unit (a2), the proportion of the constitutional unit (a2) in the silicon-containing polymer (A0) is preferably 10 mol % or more and 70 mol % or less, more preferably 20 mol % or more and 60 mol % or less, and still more preferably 30 mol % or more and 50 mol % or less with respect to the total of all constitutional units constituting the silicon-containing polymer (A0). The proportion of the constitutional unit represented by the formula (a2-1) is preferably 10 mol % or more and 70 mol % or less, more preferably 20 mol % or more and 60 mol % or less, and still more preferably 30 mol % or more and 50 mol % or less, based on the total of all constitutional units constituting the silicon-containing polymer (A0). The proportion of the constitutional unit represented by the formula (a2-2) is preferably 10 mol % or more and 40 mol % or less, more preferably 10 mol % or more and 30 mol % or less, and still more preferably 15 mol % or more and 25 mol % or less with respect to the total of all the constitutional units constituting the silicon-containing polymer (A0). When the proportion of the constitutional unit (a2) is equal to or more than the lower limit value of the above-described preferable range, the etching resistance is easily improved. When the proportion of the constitutional unit (a2) is equal to or less than an upper limit value of the above-described preferable range, a resist pattern having good lithography properties is easily formed.

### ⋅Constitutional Unit (a3)

The constitutional unit (a3) is a constitutional unit represented by the following formula (a3-1). The constitutional unit (a3) is a constitutional unit useful for improving lithography properties. When the constitutional unit (a3) is introduced, the dissolution rate can be easily controlled.

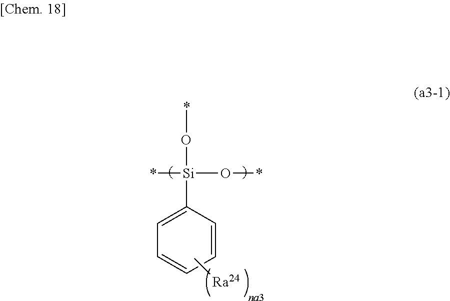

(In the formula, Ra²⁴ represents a hydrocarbon group having 1 or more and 6 or less carbon atoms, and na3 represents an integer of 0 or more and 5 or less.)

The hydrocarbon group for Ra²⁴ may be linear, branched or cyclic, and is preferably linear or branched. Further, the hydrocarbon group for Ra²⁴ may be a saturated hydrocarbon group or an unsaturated hydrocarbon group, and is preferably a saturated hydrocarbon group. The number of carbon atoms in the hydrocarbon group for Ra²⁴ is preferably 1 or more and 5 or less, and more preferably 1 or more and 3 or less. The hydrocarbon group for Ra²⁴ is preferably an alkyl group. Examples of the alkyl group include a methyl group, an ethyl group, a propyl group, an isopropyl group, an n-butyl group, an isobutyl group, a sec-butyl group, a tert-butyl group, an n-pentyl group, an isopentyl group, and a neopentyl group. Among them, a methyl group, an ethyl group, a propyl group, and an isopropyl group are preferable, a methyl group and an ethyl group are more preferable, and a methyl group is still more preferable. na3 is preferably an integer of 0 or more and 3 or less, more preferably 0 or 1, and still more preferably 0.

One kind of the constitutional unit (a3) contained in the silicon-containing polymer (A0) may be used, or two or more kinds thereof may be used. When the silicon-containing polymer (A0) contains the constitutional unit (a3), the proportion of the constitutional unit (a3) in the silicon-containing polymer (A0) is preferably 10 mol % or more and 70 mol % or less, more preferably 20 mol % or more and 60 mol % or less, and still more preferably 30 mol % or more and 50 mol % or less with respect to the total of all constitutional units constituting the silicon-containing polymer (A0).

### ⋅Constitutional Unit (a4)

The constitutional unit (a4) is a constitutional unit represented by the following formula (a4-1). The constitutional unit (a4) is a constitutional unit useful for improving lithography properties. When the constitutional unit (a4) is introduced, the dissolution rate can be easily controlled.

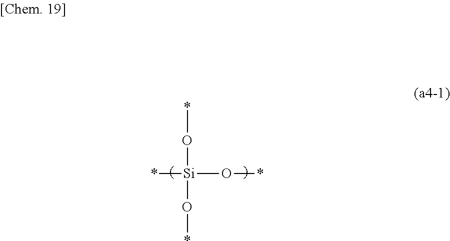 [SMILES: *O[Si](*)(O*)O*]

One kind of the constitutional unit (a4) contained in the silicon-containing polymer (A0) may be used, or two or more kinds thereof may be used. When the silicon-containing polymer (A0) contains the constitutional unit (a4), the proportion of the constitutional unit (a4) in the silicon-containing polymer (A0) is preferably 30 mol % or less, more preferably 5 mol % or more and 30 mol % or less, and still more preferably 10 mol % or more and 25 mol % or less with respect to the total of all constitutional units constituting the silicon-containing polymer (A0).

The silicon-containing polymer (A0) may have a constitutional unit containing at least one of an alkoxy group and a hydroxy group.

The component (A) is preferably a silicon-containing polymer (A0) having a repeating structure of a constitutional unit represented by the above formula (a0-1-1). Among them, preferable are a silicon-containing polymer having a repeating structure of a constitutional unit represented by the formula (a0-1-1); a silicon-containing polymer having a repeating structure of a constitutional unit represented by the formula (a0-1-1) and a constitutional unit represented by the formula (a2-1); a silicon-containing polymer having a repeating structure of a constitutional unit represented by the formula (a0-1-1) and a constitutional unit represented by the formula (a2-2); a silicon-containing polymer having a repeating structure of a constitutional unit represented by the formula (a0-1-1) and a constitutional unit represented by the formula (a3-1); a silicon-containing polymer having a repeating structure of a constitutional unit represented by the formula (a0-1-1), a constitutional unit represented by the formula (a2-1), and a constitutional unit represented by the formula (a3-1); a silicon-containing polymer having a repeating structure of a constitutional unit represented by the formula (a0-1-1), a constitutional unit represented by the formula (a2-2), and a constitutional unit represented by the formula (a3-1), and a silicon-containing polymer having a repeating structure of a constitutional unit represented by the formula (a0-1-1), a constitutional unit represented by the formula (a3-1), and a constitutional unit represented by the formula (a4-1), and more preferable are a silicon-containing polymer having a repeating structure of a constitutional unit represented by the formula (a0-1-1) and a constitutional unit represented by the formula (a2-1); and a silicon-containing polymer having a repeating structure of a constitutional unit represented by the formula (a0-1-1) and a constitutional unit represented by the formula (a3-1).

The mass average molecular weight (Mw) (polystyrene conversion reference by gel permeation chromatography (GPC)) of the component (A) is not particularly limited, and is, for example, 1000 or more, preferably 1000 or more and 10000 or less, more preferably 1500 or more and 7500 or less, and still more preferably 2000 or more and 5000 or less. When the Mw of the component (A) is equal to or less than the upper limit value of the above preferable range, solubility in an organic solvent is easily improved. On the other hand, when the Mw of the component (A) is equal to or more than the lower limit value of the above preferable range, the patterning properties of the resist film are easily improved, and the lithography properties of the formed resist pattern are easily improved.

One kind of the component (A) may be used, or two or more kinds thereof may be used. The content of the component (A) is preferably less than 5 mass %, more preferably 2 mass % or less, still more preferably 1 mass % or less, and particularly preferably 0.10 mass % or more and 1 mass % or less with respect to the total mass of the first film-forming composition. When the content of the component (A) is within the preferable range, a thin film is easily formed in pattern formation.

### [Photoacid Generating Agent (B)]

The film-forming composition contains the photoacid generating agent (B) (hereinafter, also referred to as the “component (B)”). The component (B) functions as an acid component that causes crosslinking between the component (A) described above and the component (C1) described below in the film-forming composition. As the component (B), there is no particular limitation, and any acid generation agent that has been proposed as an acid generator for use in chemically amplified resist compositions can be used. Examples of the acid generation agents include various acid generation agents such as onium salt-based acid generation agents such as iodonium salts and sulfonium salts; oxime sulfonate-based acid generation agents; diazomethane-based acid generation agents such as bisalkyl- or bisaryl sulfonyl diazomethanes and poly(bis-sulfonyl) diazomethanes; nitrobenzylsulfonate-based acid generation agents; iminosulfonate-based acid generation agents; and disulfone-based acid generation agents.

Preferable examples of the component (B) include onium salts represented by the following formula (b0) (hereafter, referred to as a “component (B0)”).

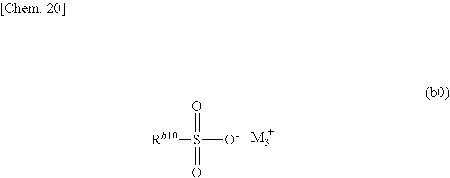

(In the formula (b0), R^{b10} represents an organic group having 1 or more and 40 or less carbon atoms. M₃⁺ represents an onium cation.)

Examples of the organic group for R^{b10} include a hydrocarbon group which may have a substituent, a divalent linking group containing an oxygen atom, and a combination thereof. The onium salt is preferably a sulfonate represented by the following formula (b0-1b).

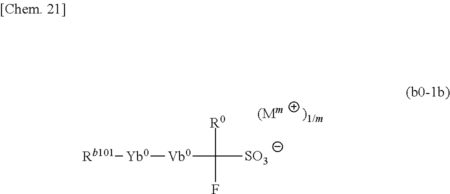

In the formula (b0-1b), R^{b101} represents a cyclic group which may have a substituent, a chain-like alkyl group which may have a substituent, or a chain-like alkenyl group which may have a substituent. Yb⁰ represents a divalent linking group or a single bond. Vb⁰ represents a single bond, an alkylene group, or a fluorinated alkylene group. R⁰ represents a hydrogen atom, a fluorinated alkyl group having 1 or more and 5 or less carbon atoms, or a fluorine atom. M^{m+} represents an m-valent onium cation. m represents an integer of 1 or more.)

### ⋅Regarding Anion Moiety

Cyclic Group which May have Substituent:

The cyclic group for R^{b101} is preferably a cyclic hydrocarbon group. The cyclic hydrocarbon group may be either an aromatic group or an aliphatic hydrocarbon group, and is preferably an aromatic group. The aliphatic hydrocarbon group may be either saturated or unsaturated, and is preferably saturated.

The number of carbon atoms in the aromatic group for R^{b101} is preferably 3 or more and 30 or less, more preferably 5 or more and 30 or less, still more preferably 5 or more and 20 or less, particularly preferably 6 or more and 15 or less, and most preferably 6 or more and 10 or less. Here, the number of carbon atoms does not include the number of carbon atoms in the substituent. Examples of the aromatic ring contained in the aromatic group for R^{b101} include a benzene ring, a fluorene ring, a naphthalene ring, an anthracene ring, a phenanthrene ring, a biphenyl ring, and an aromatic heterocycle obtained by substituting a portion of the carbon atoms constituting these aromatic rings with a heteroatom. Examples of the heteroatom in the aromatic heterocycle include an oxygen atom, a sulfur atom, and a nitrogen atom. Examples of the aromatic group for R^{b101} include a group obtained by removing one hydrogen atom from the above aromatic ring (an aryl group such as a phenyl group and a naphthyl group), and a group obtained by substituting one of hydrogen atoms of the above aromatic ring with an alkylene group (an arylalkyl group such as a benzyl group, a phenethyl group, a 1-naphthylmethyl group, a 2-naphthylmethyl group, a 1-naphthylethyl group, and a 2-naphthylethyl group). The number of carbon atoms in the alkylene group (alkyl chain in the arylalkyl group) is preferably 1 or more and 4 or less, more preferably 1 or more and 2 or less, and still more preferably 1.

Examples of the cyclic aliphatic hydrocarbon group for R^{b101} include an aliphatic hydrocarbon group containing a ring in a structure thereof. Examples of the aliphatic hydrocarbon group containing a ring in the structure thereof include an alicyclic hydrocarbon group (a group obtained by removing one hydrogen atoms from an aliphatic hydrocarbon ring), a group obtained by bonding an alicyclic hydrocarbon group to a terminal of a linear or branched aliphatic hydrocarbon group, and a group obtained by interposing an alicyclic hydrocarbon group in a linear or branched aliphatic hydrocarbon group. The number of carbon atoms in the above alicyclic hydrocarbon group is preferably 3 or more and 20 or less, and more preferably 3 or more and 12 or less. The above alicyclic hydrocarbon group may be either a polycyclic group or a monocyclic group. The monocyclic alicyclic hydrocarbon group is preferably a group obtained by removing one or more hydrogen atoms from a monocycloalkane. The monocycloalkane is preferably a monocycloalkane having 3 or more and 6 or less carbon atoms. Specific examples thereof include cyclopentane and cyclohexane. The polycyclic alicyclic hydrocarbon group is preferably a group obtained by removing one or more hydrogen atoms from a polycycloalkane. The polycycloalkane is preferably a polycycloalkane having 7 or more and 30 or less carbon atoms. Among them, a polycycloalkane having a crosslinked polycyclic skeleton, such as adamantane, norbornane, isobornane, tricyclodecane, and tetracyclododecane, and a polycycloalkane having a condensed polycyclic skeleton, such as a cyclic group having a steroid skeleton are preferable as the polycycloalkane.

Among them, the cyclic aliphatic hydrocarbon group for R^{b101} is preferably a group obtained by removing one or more hydrogen atoms from a monocycloalkane or a polycycloalkane, more preferably a group obtained by removing one hydrogen atom from a polycycloalkane, still more preferably an adamantyl group or a norbornyl group, and particularly preferably an adamantyl group.

The number of carbon atoms in the linear aliphatic hydrocarbon group which may be bonded to the alicyclic hydrocarbon group is preferably 1 or more and 10 or less, more preferably 1 or more and 6 or less, still more preferably 1 or more and 4 or less, and particularly preferably 1 or more and 3 or less. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)—]. The number of carbon atoms in the branched aliphatic hydrocarbon group which may be bonded to the alicyclic hydrocarbon group is preferably 2 or more and 10 or less, more preferably 3 or more and 6 or less, still more preferably 3 or 4, and most preferably 3. The branched aliphatic hydrocarbon group is preferably a branched alkylene group, and specific examples include alkyl alkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—, alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—, alkyl trimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. The alkyl group in the alkyl alkylene group is preferably a linear alkyl group having 1 or more and 5 or less carbon atoms.

Further, the cyclic hydrocarbon group for R^{b101} may contain a heteroatom, such as a heterocycle.

The cyclic hydrocarbon group for R^{b101} may be a condensed cyclic group including a condensed ring obtained by condensing an aliphatic hydrocarbon ring and an aromatic ring. Examples of the above condensed ring include a ring obtained by condensing one or more aromatic rings with a polycycloalkane having a crosslinked polycyclic skeleton. Specific examples of the above crosslinked cyclic polycycloalkane include bicycloalkanes such as bicyclo[2.2.1]heptane (norbornane) and bicyclo[2.2.2]octane. The above condensed cyclic group is preferably a group containing a condensed ring obtained by condensing two or three aromatic rings with a bicycloalkane, and more preferably a group containing a condensed ring obtained by condensing two or three aromatic rings with bicyclo[2.2.2]octane. Specific examples of the condensed cyclic group for R^{b101} include condensed cyclic groups represented by the following formulas (r-br-1) and (r-br-2). In the formula, * represents a bonding site bonded to Yb⁰ in the above formula (b0-1b).

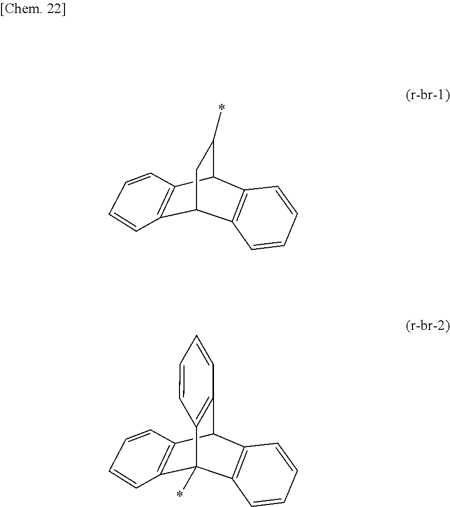 [SMILES: *C1CC2c3ccccc3C1c1ccccc12 ; *C12c3ccccc3C(c3ccccc31)c1ccccc12]

The cyclic group as R^{b101} may have a substituent. Examples of the substituent include an alkyl group, an alkoxy group, a halogen atom, a halogenated alkyl group, a hydroxy group, a carbonyl group, and a nitro group. From the viewpoint of increasing sensitivity, the substituent is preferably a halogen atom, more preferably an iodine atom or a bromine atom, and still more preferably an iodine atom. When an iodine atom is contained as a substituent, the number of iodine atoms bonded to the cyclic group is preferably 1 or more and 3 or less, and more preferably 2 or 3.

Chain-Like Alkyl Group which May have Substituent:

The chain-like alkyl group for R^{b101} may be either linear or branched. The number of carbon atoms in the linear alkyl group is preferably 1 or more and 20 or less, more preferably 1 or more and 15 or less, and still more preferably 1 or more and 10 or less. The number of carbon atoms in the branched alkyl group is preferably 3 or more and 20 or less, more preferably 3 or more and 15 or less, and still more preferably 3 or more and 10 or less. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group for R^{b101} may be either linear or branched. The number of carbon atoms in the chain-like alkenyl group is preferably 2 or more and 10 or less, more preferably 2 or more and 5 or less, still more preferably 2 or more and 4 or less, and particularly preferably 3. Examples of the linear alkenyl groups include a vinyl group, a propenyl group (an allyl group) and a butynyl group. Examples of the branched alkenyl groups include a 1-methylvinyl group, a 2-methylvinyl group, a 1-methylpropenyl group, and a 2-methylpropenyl group. Among the above examples, the chain-like alkenyl group is preferably a linear alkenyl group, more preferably a vinyl group or a propenyl group, and still more preferably a vinyl group.

The chain-like alkyl group or the chain-like alkenyl group for R^{b101} may have a substituent. Examples of the substituent include an alkoxy group, a halogen atom, a halogenated alkyl group, a hydroxy group, a carbonyl group, and a nitro group. From the viewpoint of increasing sensitivity, the substituent is preferably a halogen atom, more preferably an iodine atom or a bromine atom, and still more preferably an iodine atom. When an iodine atom is contained as the substituent, the number of iodine atoms bonded to the chain-like alkyl group or the chain-like alkenyl group is preferably 1 or more and 3 or less, and more preferably 2 or 3.

Among the above examples, R^{b101} is preferably a cyclic group having an iodine atom or a cyclic group having a bromine atom, more preferably a cyclic group having an iodine atom, still more preferably an aromatic hydrocarbon group having an iodine atom, and particularly preferably a phenyl group having an iodine atom, a naphthyl group having an iodine atom, or a group containing these. Preferable examples of R^{b101} include a group represented by the following formula (b0-r-1p) or a cyclic group to which a group represented by the following formula (b0-r-1p) is bonded.

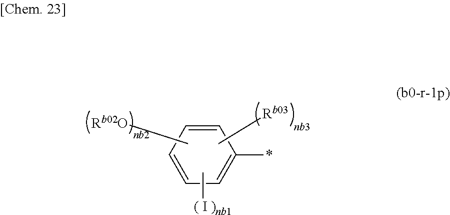

(In the formula, I represents an iodine atom. R^{b02} represents a hydrocarbon group having 1 or more and 6 or less carbon atoms or a hydrogen atom. R^{b03} represents a hydrocarbon group having 1 or more and 6 or less carbon atoms. nb1 represents an integer of 1 or more and 5 or less. nb2 represents an integer of 0 or more and 4 or less. nb3 represents an integer of 0 or more and 4 or less. This is 1≤nb1+nb2+nb3≤5. * represents a bonding site bonded to Yb⁰ in the above formula (b0-1b) or a bonding site to be bonded to a cyclic group.)

The number of carbon atoms in the hydrocarbon group for R^{b02} is preferably 1 or more and 5 or less. The hydrocarbon group for R^{b02} is preferably a methyl group, an ethyl group, a propyl group, or an isopropyl group, more preferably a methyl group or an ethyl group, and still more preferably a methyl group. R^{b02} is preferably a hydrogen atom. That is, —OR^{b02} is preferably a phenolic hydroxy group.

The number of carbon atoms in the hydrocarbon group for R^{b03} is preferably 1 or more and 5 or less. The hydrocarbon group for R^{b03} is preferably a methyl group, an ethyl group, a propyl group, or an isopropyl group, and more preferably a methyl group or an ethyl group. nb1 is preferably an integer of 1 or more and 3 or less, more preferably 2 or 3, and still more preferably 3. nb2 is preferably an integer of 0 or more and 2 or less, more preferably 0 or 1, and still more preferably 0. nb3 is preferably an integer of 0 or more and 2 or less, more preferably 0 or 1, and still more preferably 0.

The divalent linking group for Yb⁰ is preferably a divalent linking group containing an oxygen atom. When Yb⁰ represents a divalent linking group containing an oxygen atom, Yb⁰ may contain an atom other than an oxygen atom. Examples of the atom other than an oxygen atom include a carbon atom, a hydrogen atom, a sulfur atom, and a nitrogen atom. Examples of the divalent linking group containing an oxygen atom include: a non-hydrocarbon-based oxygen atom-containing linking group such as an oxygen atom (ether bond: —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking group and an alkylene group. A sulfonyl group (—SO₂—) may be further linked to this combination. Among the divalent linking groups containing an oxygen atom, an ester bond (—C(═O)—O—) or an oxycarbonyl group (—O—C(═O)—) is more preferable. Yb⁰ is preferably a divalent linking group, more preferably a divalent linking group containing an oxygen atom, and still more preferably an ester bond (—C(═O)—O—) or an oxycarbonyl group (—O—C(═O)—).

The number of carbon atoms in each of the alkylene group and the fluorinated alkylene group for Vb⁰ is preferably 1 or more and 4 or less, and more preferably 1 or more and 3 or less. Examples of the fluorinated alkylene group for Vb⁰ include groups obtained by substituting a portion or all of the hydrogen atoms in the alkylene group for Vb⁰ with a fluorine atom(s). Among them, Vb⁰ is preferably an alkylene group having 1 or more and 4 or less carbon atoms, a fluorinated alkylene group having 1 or more and 4 or less carbon atoms, or a single bond, more preferably a group obtained by substituting a portion of hydrogen atoms of an alkylene group having 1 or more and 3 or less carbon atoms with a fluorine atom(s) or a single bond(s), and still more preferably —CH(CF₃)— or —CH₂—.

R⁰ is preferably a fluorine atom or a perfluoroalkyl group having 1 or more and 5 or less carbon atoms, and more preferably a fluorine atom.

Specific examples of the anion moiety of the sulfonate represented by formula (b0-1b) are shown below.

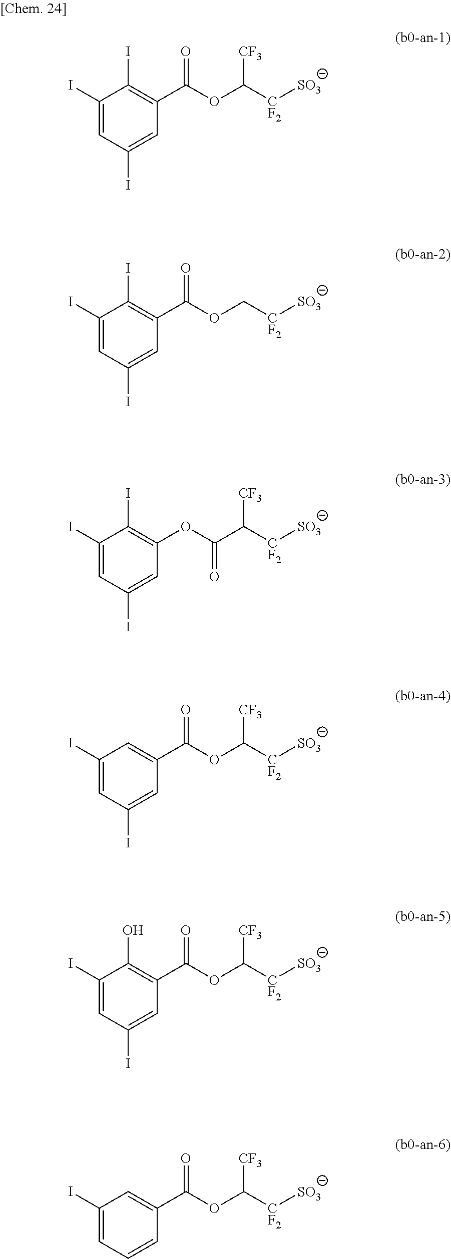

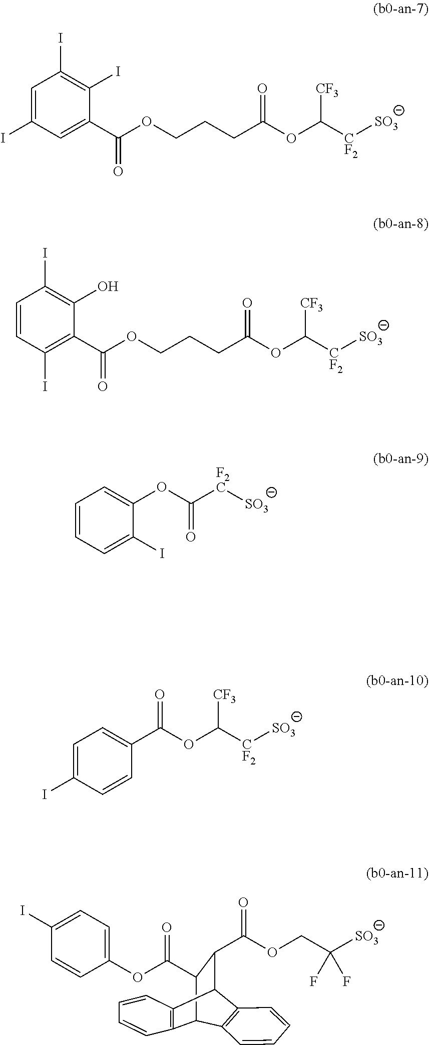

The anion moiety of the sulfonate represented by the formula (b0-1b) is preferably at least one selected from the group consisting of anions represented by the above formulas (b0-an-1) to (a0-an-11), and more preferably at least one selected from the group consisting of anions represented by the above formulas (a0-an-1) to (a0-an-6) and (a0-an-9) to (a0-an-11).

⋅Regarding Cation Moiety M^{m+} represents an m-valent onium cation, and preferably represents a sulfonium cation or an iodonium cation. m represents an integer of 1 or more. Examples of the onium cation for M^{m+} include organic cations represented by the following formulas (ca-1) to (ca-3).

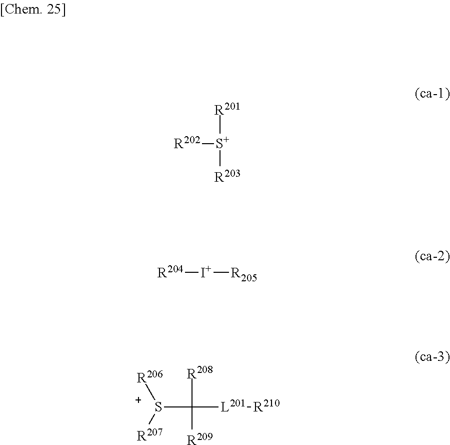

(In the formula, R²⁰¹ to R²⁰⁷ each independently represent an aryl group which may have a substituent, an alkyl group which may have a substituent, or an alkenyl group which may have a substituent. R²⁰¹ to R²⁰³ and R²⁰⁶ and R²⁰⁷ may be bonded to each other to form a ring with a sulfur atom in the formula. R²⁰⁸ and R²⁰⁹ each independently represent a hydrogen atom or an alkyl group having 1 or more carbon atoms and 5 or less carbon atoms. R²¹⁰ represents an aryl group which may have a substituent, an alkyl group which may have a substituent, an alkenyl group which may have a substituent, or a —SO₂— containing cyclic group which may have a substituent. L²⁰¹ represents —C(═O)— or —C(═O)—O—.)

Examples of the aryl group for R²⁰¹ to R²⁰?include an aryl group having 6 or more and 20 or less carbon atoms, and a phenyl group and a naphthyl group are preferable. The alkyl group for R²⁰¹ to R²⁰⁷ is preferably a chain-like or cyclic alkyl group having 1 or more and 30 or less carbon atoms. The number of carbon atoms in the alkenyl group for R²⁰¹ to R²⁰⁷ is preferably 2 to 10. Examples of the substituent which may be contained in R²⁰¹ to R²⁰⁷ and R²¹⁰ include an alkyl group, a halogen atom, a halogenated alkyl group, a carbonyl group, a cyano group, an amino group, and an aryl group, and groups respectively represented by the following formulas (ca-r-1) to (ca-r-7).

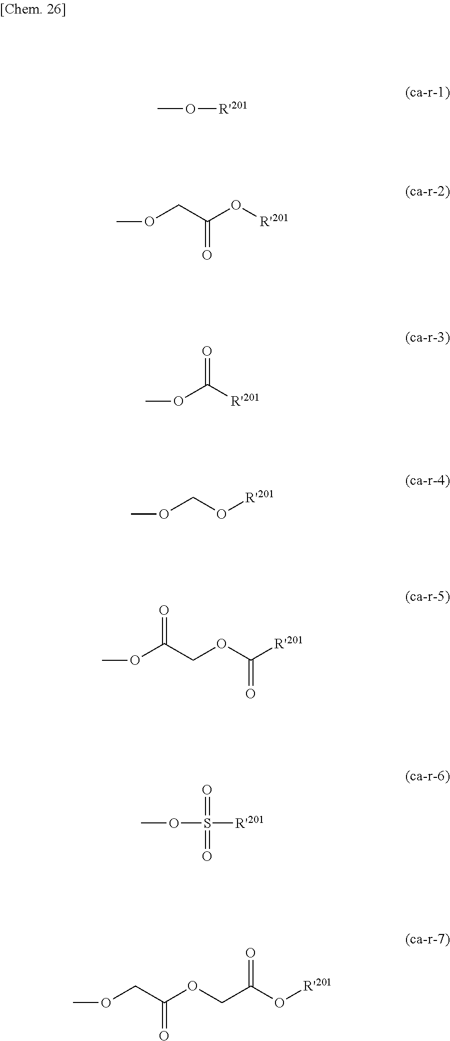

(In the formula, R′²⁰¹ independently represents a hydrogen atom, a cyclic group which may have a substituent, a chain-like alkyl group which may have a substituent, or a chain-like alkenyl group which may have a substituent.)
Cyclic Group which May have Substituent:

The cyclic group for R′²⁰¹ is preferably a cyclic hydrocarbon group. The cyclic hydrocarbon group may be either an aromatic hydrocarbon group or an aliphatic hydrocarbon group. The aliphatic hydrocarbon group may be either saturated or unsaturated, and is preferably saturated.

The number of carbon atoms in an aromatic hydrocarbon group for R′²⁰¹ is preferably 3 or more and 30 or less, more preferably 5 or more and 30 or less, still more preferably 5 or more and 20 or less, particularly preferably 6 or more and 15 or less, and most preferably 6 or more and 10 or less. Here, the number of carbon atoms does not include the number of carbon atoms in the substituent. Examples of an aromatic ring in the aromatic hydrocarbon group for R′²⁰¹ include a benzene ring, a fluorene ring, a naphthalene ring, an anthracene ring, a phenanthrene ring, a biphenyl ring, and an aromatic heterocycle obtained by substituting a portion of the carbon atoms constituting these aromatic rings with a heteroatom(s). Examples of the heteroatom in the aromatic heterocycle include an oxygen atom, a sulfur atom, and a nitrogen atom. Examples of the aromatic hydrocarbon group for R′²⁰¹ include a group obtained by removing one hydrogen atom from the above aromatic ring (an aryl group such as a phenyl group and a naphthyl group), and a group obtained by substituting one of hydrogen atoms of the above aromatic ring with an alkylene group (an arylalkyl group such as a benzyl group, a phenethyl group, a 1-naphthylmethyl group, a 2-naphthylmethyl group, a 1-naphthylethyl group, and a 2-naphthylethyl group). The number of carbon atoms in the alkylene group (alkyl chain in the arylalkyl group) is preferably 1 or more and 4 or less, more preferably 1 or 2, and particularly preferably 1.

Examples of the cyclic aliphatic hydrocarbon group for R′²⁰¹ include aliphatic hydrocarbon groups containing a ring in a structure thereof. Examples of the aliphatic hydrocarbon group containing a ring in the structure thereof include an alicyclic hydrocarbon group (a group obtained by removing one hydrogen atoms from an aliphatic hydrocarbon ring), a group obtained by bonding an alicyclic hydrocarbon group to a terminal of a linear or branched aliphatic hydrocarbon group, and a group obtained by interposing an alicyclic hydrocarbon group in a linear or branched aliphatic hydrocarbon group. The number of carbon atoms in the above alicyclic hydrocarbon group is preferably 3 or more and 20 or less, and more preferably 3 or more and 12 or less. The above alicyclic hydrocarbon group may be either a polycyclic group or a monocyclic group. The monocyclic alicyclic hydrocarbon group is preferably a group obtained by removing one or more hydrogen atoms from a monocycloalkane. The monocycloalkane is preferably a monocycloalkane having 3 or more and 6 or less carbon atoms. Specific examples thereof include cyclopentane and cyclohexane. The polycyclic alicyclic hydrocarbon group is preferably a group obtained by removing one or more hydrogen atoms from a polycycloalkane. The polycycloalkane is preferably a polycycloalkane having 7 or more and 30 or less carbon atoms. Among them, a polycycloalkane having a crosslinked polycyclic skeleton, such as adamantane, norbornane, isobornane, tricyclodecane, and tetracyclododecane, and a polycycloalkane having a condensed polycyclic skeleton, such as a cyclic group having a steroid skeleton are preferable as the polycycloalkane.

Among them, the cyclic aliphatic hydrocarbon group for R′²⁰¹ is preferably a group obtained by removing one or more hydrogen atoms from a monocycloalkane or a polycycloalkane, more preferably a group obtained by removing one hydrogen atom from a polycycloalkane, still more preferably an adamantyl group or a norbornyl group, and most preferably an adamantyl group.

The number of carbon atoms in the linear or branched aliphatic hydrocarbon group which may be bonded to the alicyclic hydrocarbon group is preferably 1 or more and 10 or less, more preferably 1 or more and 6 or less, still more preferably 1 or more and 4 or less, and particularly preferably 1 or more and 3 or less. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—]. The branched aliphatic hydrocarbon group is preferably a branched alkylene group, and specific examples include alkyl alkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—, alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—, alkyl trimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. The alkyl group in the alkyl alkylene group is preferably a linear alkyl group having 1 or more and 5 or less carbon atoms.

Further, the cyclic hydrocarbon group for R¹²⁰1 may contain a heteroatom, such as a heterocycle.

Examples of the substituent in the cyclic group represented by R′²⁰¹ include an alkyl group, an alkoxy group, a halogen atom, a halogenated alkyl group, a hydroxy group, a carbonyl group, and a nitro group. The alkyl group as the substituent is preferably an alkyl group having 1 or more and 5 or less carbon atoms, and more preferably a methyl group, an ethyl group, a propyl group, an n-butyl group, or a tert-butyl group. The alkoxy group as the substituent is preferably an alkoxy group having 1 or more and 5 or less carbon atoms, more preferably a methoxy group, an ethoxy group, an n-propoxy group, an iso-propoxy group, an n-butoxy group, or a tert-butoxy group, and still more preferably a methoxy group or an ethoxy group. The halogen atom as the substituent is preferably a fluorine atom. Examples of the halogenated alkyl group as the substituent include an alkyl group having 1 or more and 5 or less carbon atoms, for example, a group obtained by substituting a portion or all of hydrogen atoms of a methyl group, an ethyl group, a propyl group, an n-butyl group, a tert-butyl group, or the like with a halogen atom(s). The carbonyl group as the substituent is a group that substitutes a methylene group (—CH₂—) constituting the cyclic hydrocarbon group.

Chain-like alkyl group which may have substituent: The chain-like alkyl group as R′²⁰¹ may be either linear or branched. The number of carbon atoms in the linear alkyl group is preferably 1 or more and 20 or less, more preferably 1 or more and 15 or less, and still more preferably 1 or more and 10 or less. The number of carbon atoms in the branched alkyl group is preferably 3 or more and 20 or less, more preferably 3 or more and 15 or less, and still more preferably 3 or more and 10 or less. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R′²⁰¹ may be either linear or branched. The number of carbon atoms in the chain-like alkenyl group is preferably 2 or more and 10 or less, more preferably 2 or more and 5 or less, still more preferably 2 or more and 4 or less, and particularly preferably 3. Examples of the linear alkenyl groups include a vinyl group, a propenyl group (an allyl group) and a butynyl group. Examples of the branched alkenyl groups include a 1-methylvinyl group, a 2-methylvinyl group, a 1-methylpropenyl group, and a 2-methylpropenyl group. The chain-like alkenyl group is preferably a linear alkenyl group, more preferably a vinyl group or a propenyl group, and still more preferably a vinyl group.

Examples of the substituent in the chain-like alkyl group or alkenyl group for R′²⁰¹ include an alkoxy group, a halogen atom, a halogenated alkyl group, a hydroxy group, a carbonyl group, a nitro group, an amino group, and a cyclic group as the above R′²⁰¹.

Examples of the cyclic group which may have a substituent, the chain-like alkyl group which may have a substituent, and the chain-like alkenyl group which may have a substituent as R′²⁰¹ include an acid-dissociable group.

R′²⁰¹ is preferably a cyclic group which may have a substituent, and is more preferably a cyclic hydrocarbon group which may have a substituent. More specifically, for example, a phenyl group, a naphthyl group, or a group obtained by removing one or more hydrogen atoms from a polycycloalkane is preferable.

When R²⁰¹ to R²⁰³ or R²⁰⁶ and R²⁰⁷ are bonded to each other to form a ring with a sulfur atom in the formula, R²⁰¹ to R²⁰³ or R²⁰⁶ and R²⁰⁷ are bonded to each other via a heteroatom such as a sulfur atom, an oxygen atom, and a nitrogen atom, or a functional group such as a carbonyl group, —SO—, —SO₂—, —SO₃—, —COO—, —CONH—, or —N(R_{N})— (R_{N} represents an alkyl group having 1 or more and 5 or less carbon atoms). As the formed ring, one ring containing the sulfur atom in the formula in a ring skeleton thereof is preferably a 3- to 10-membered ring, and more preferably a 5- to 7-membered ring, including the sulfur atom. Specific examples of the formed ring include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 or more and 5 or less carbon atoms, and is preferably a hydrogen atom or an alkyl group having 1 or more and 3 or less carbon atoms. In the case of an alkyl group, R²⁰¹ and R²⁰⁹ may be bonded to each other to form a ring.

R²¹⁰ represents an aryl group which may have a substituent, an alkyl group which may have a substituent, an alkenyl group which may have a substituent, or a —SO₂-containing cyclic group which may have a substituent. Examples of the aryl group for R²¹⁰ include an aryl group having 6 or more and 20 or less carbon atoms. Among them, a phenyl group and a naphthyl group are preferable. The alkyl group for R²¹⁰ is preferably a chain-like or cyclic alkyl group having 1 or more and 30 or less carbon atoms. The number of carbon atoms in the alkenyl group for R²¹⁰ is preferably 2 or more and 10 or less. The —SO₂-containing cyclic group, which may have a substituent, for R²¹⁰, a “—SO₂— containing polycyclic group” is preferable.

Preferable examples of the cation represented by the formula (ca-1) include cations represented by the following chemical formulas.

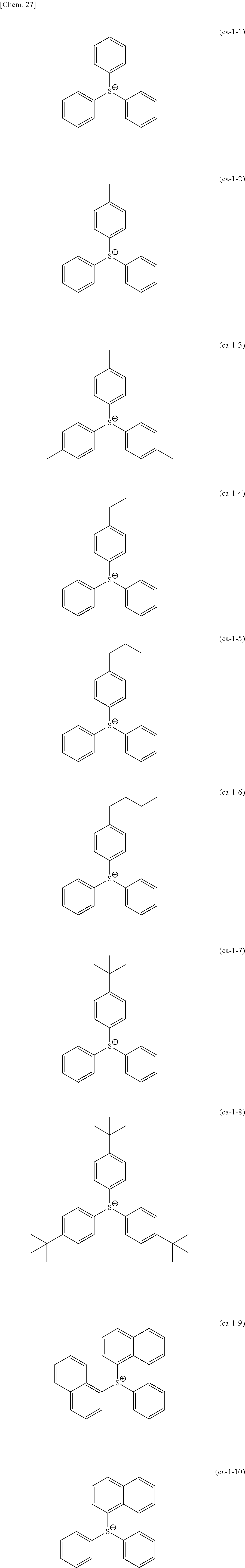

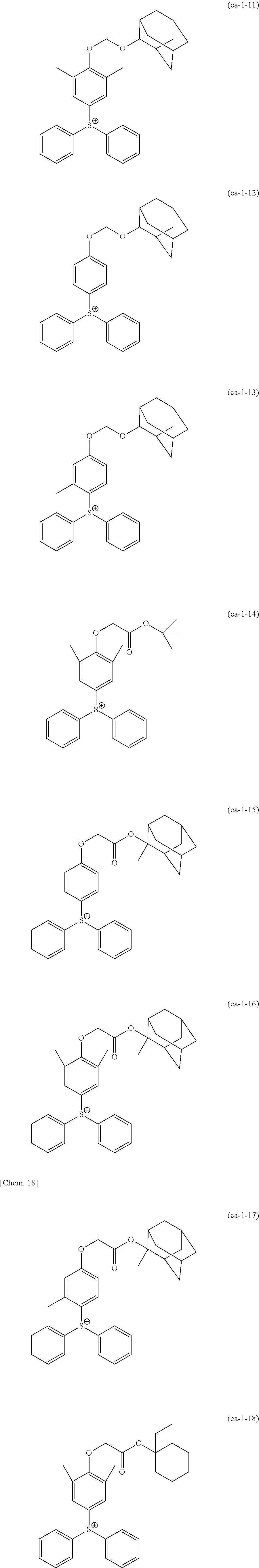

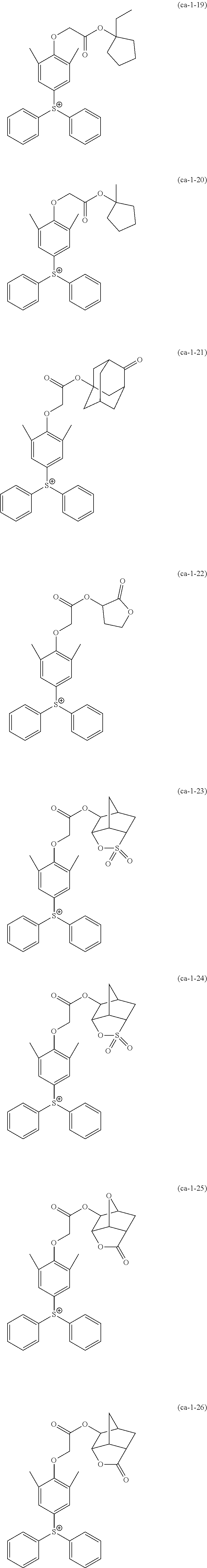

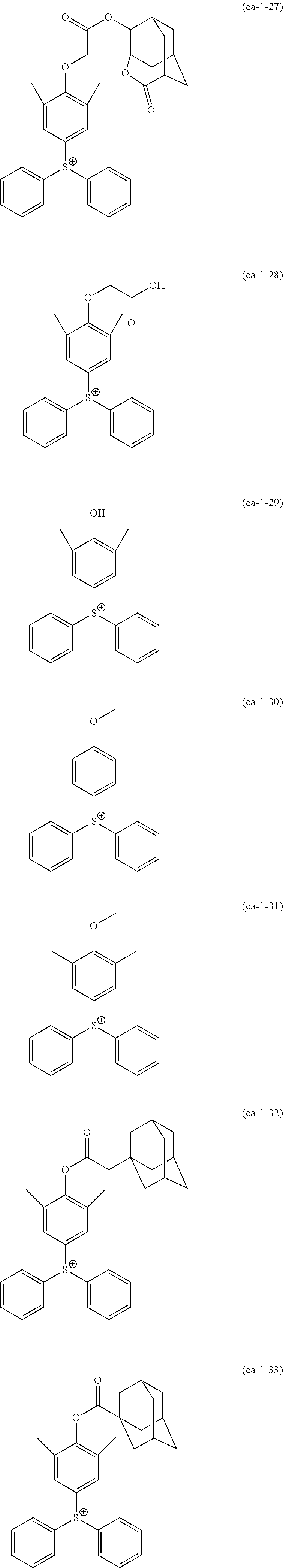

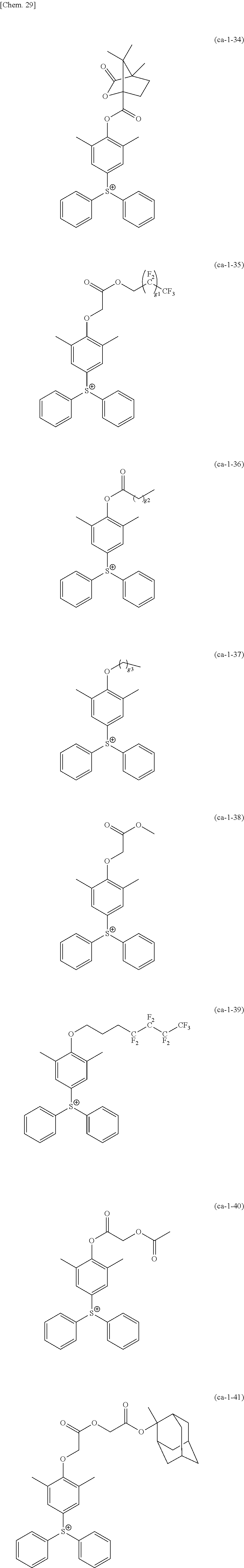

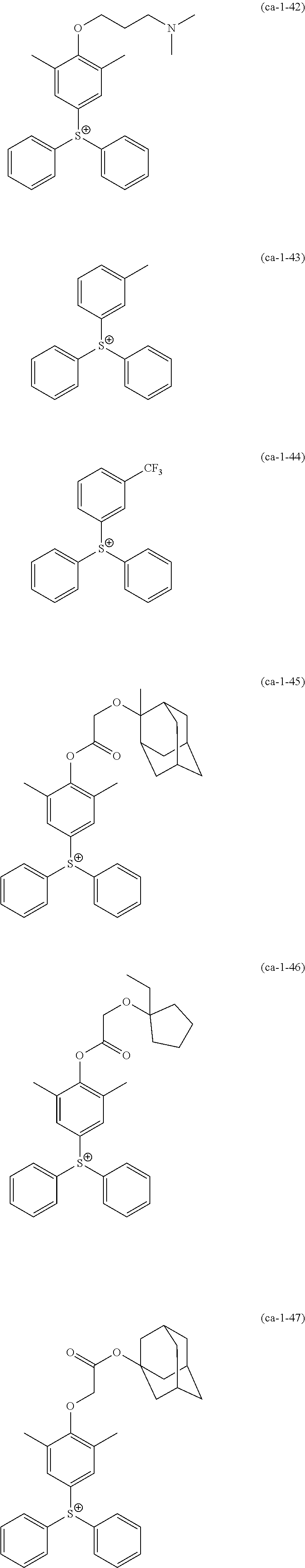 [SMILES: Cc1cc([S+](c2ccccc2)c2ccccc2)cc(C)c1OCCCN(C)C ; Cc1cccc([S+](c2ccccc2)c2ccccc2)c1 ; FC(F)(F)c1cccc([S+](c2ccccc2)c2ccccc2)c1 ; Cc1cc([S+](c2ccccc2)c2ccccc2)cc(C)c1OC(=O)COC1(C)C2CC3CC(C2)CC1C3 ; CCC1(OCC(=O)Oc2c(C)cc([S+](c3ccccc3)c3ccccc3)cc2C)CCCC1 ; Cc1cc([S+](c2ccccc2)c2ccccc2)cc(C)c1OCC(=O)OC12CC3CC(CC(C3)C1)C2]

(In the formula, g1, g2, and g3 each represent a repeating number, g1 represents an integer of 1 or more and 5 or less, g2 represents an integer of 0 or more and 20 or less, and g3 represents an integer of 0 or more and 20 or less.)

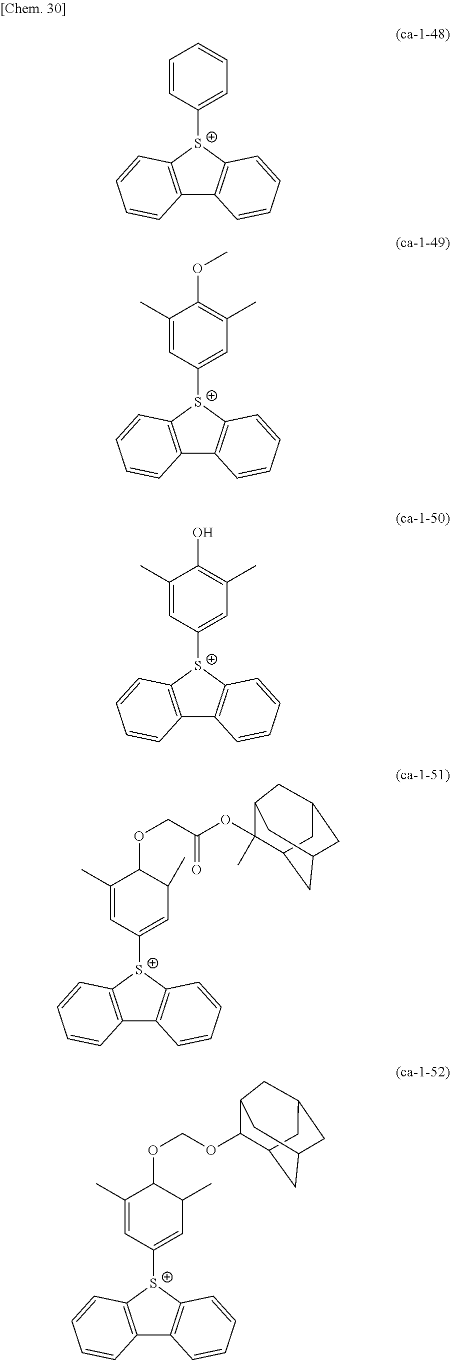 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; CC1=CC([s+]2c3ccccc3c3ccccc32)=CC(C)C1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

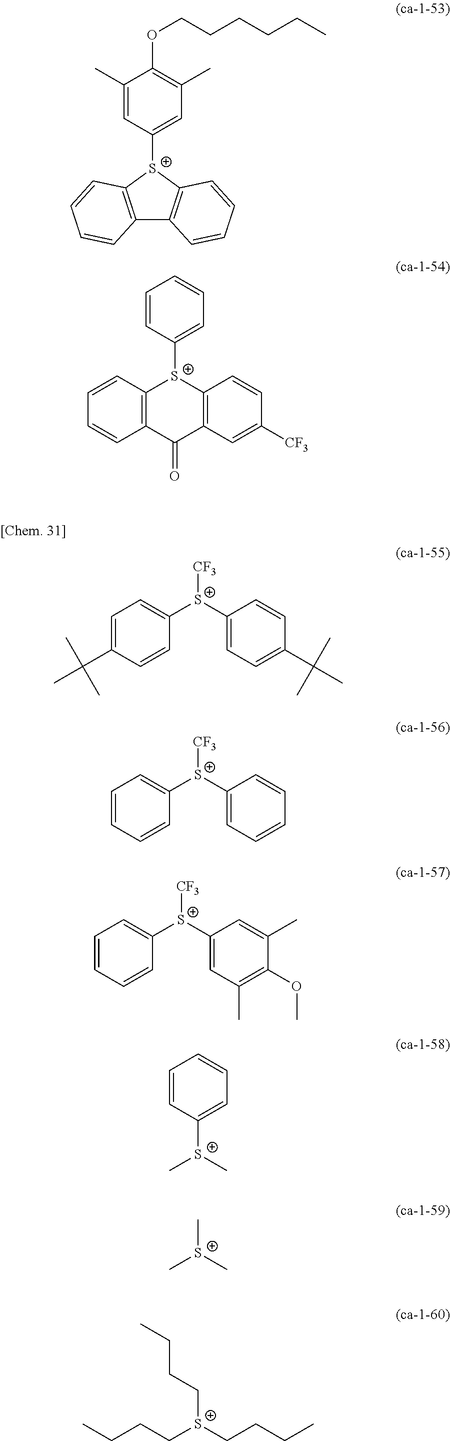

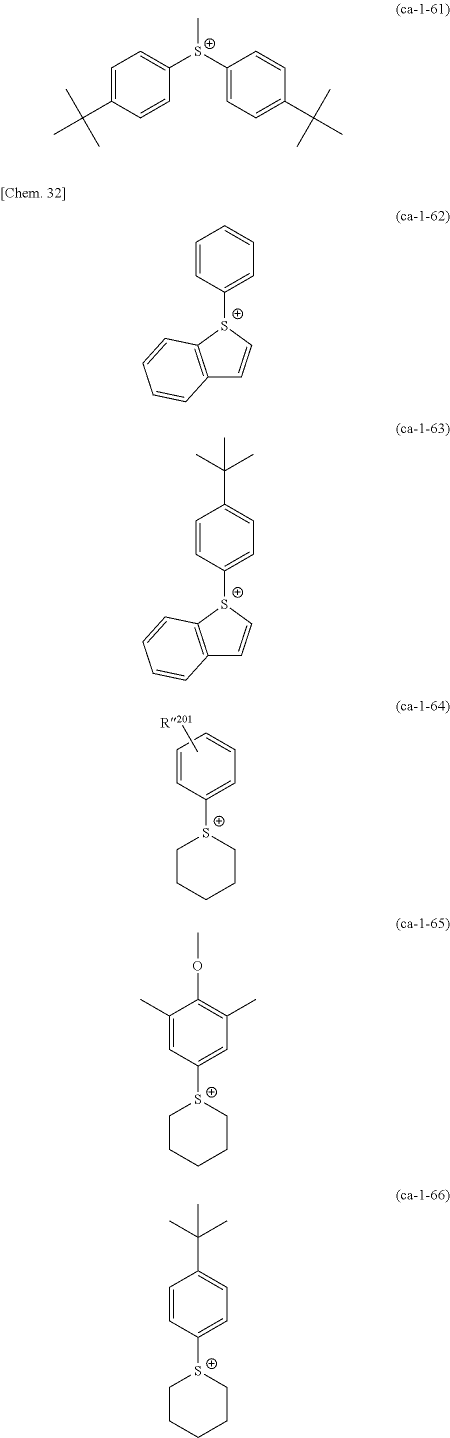

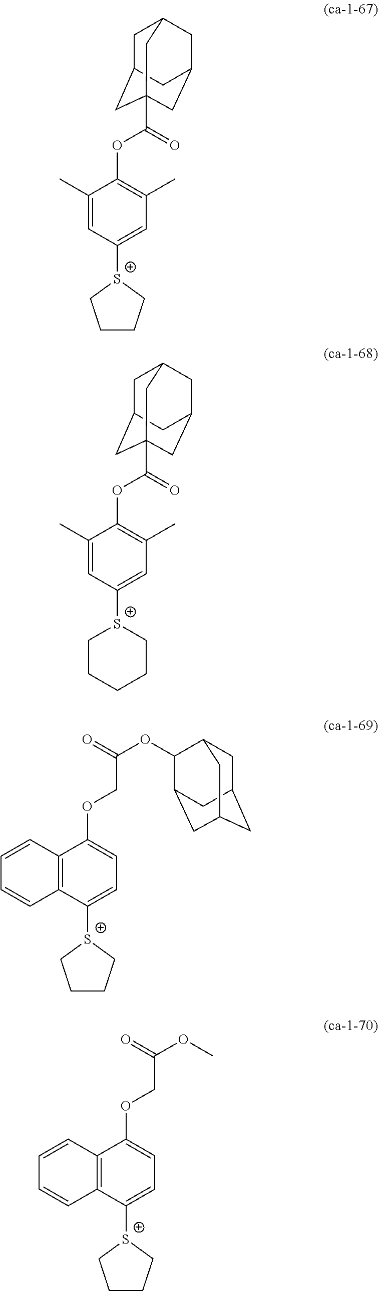 [SMILES: Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3 ; COC(=O)COc1ccc([S+]2CCCC2)c2ccccc12]

(In the formula, R″²⁰¹ represents a hydrogen atom or a substituent, and the substituent is the same as the group exemplified as the substituent which may be contained in R²⁰¹ to R²⁰⁷ and R²¹⁰ to R²¹².)

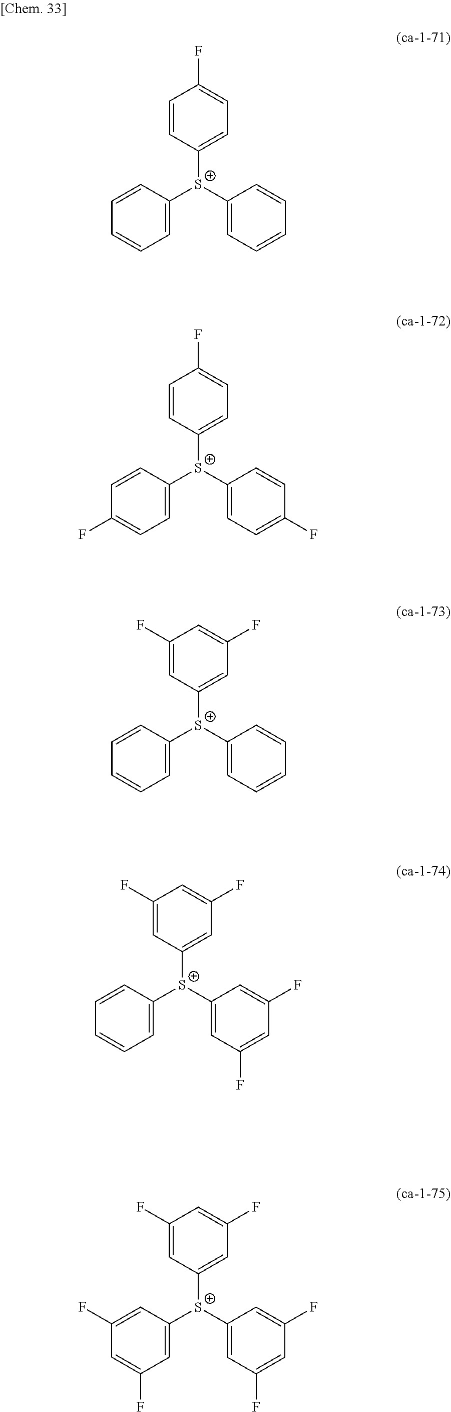 [SMILES: Fc1ccc([S+](c2ccccc2)c2ccccc2)cc1 ; Fc1ccc([S+](c2ccc(F)cc2)c2ccc(F)cc2)cc1 ; Fc1cc(F)cc([S+](c2ccccc2)c2ccccc2)c1 ; Fc1cc(F)cc([S+](c2ccccc2)c2cc(F)cc(F)c2)c1 ; Fc1cc(F)cc([S+](c2cc(F)cc(F)c2)c2cc(F)cc(F)c2)c1]

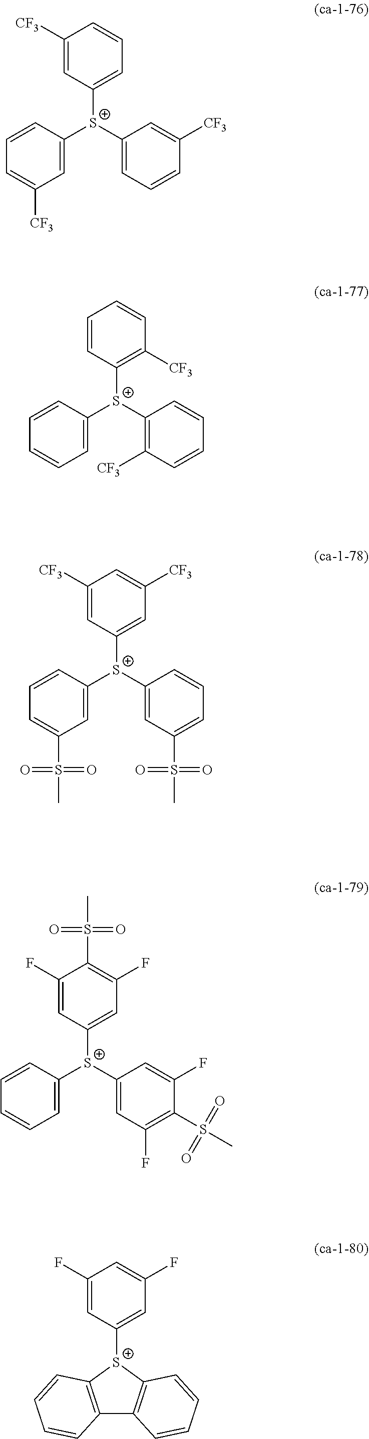

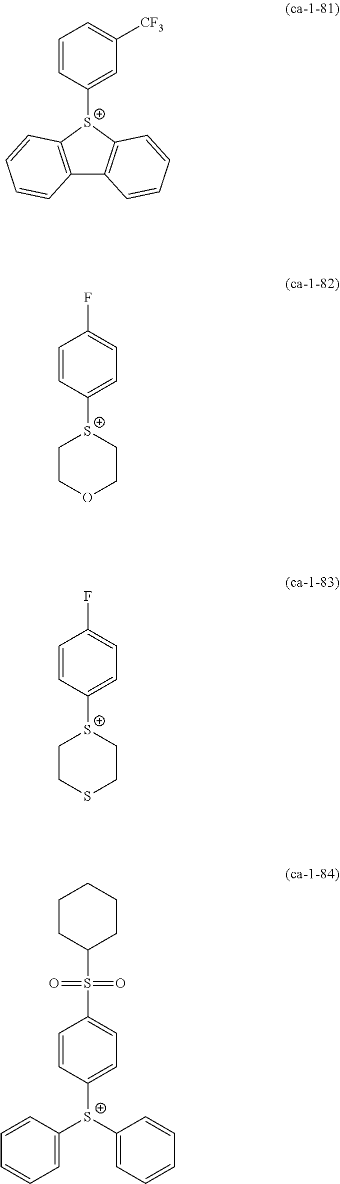

Specific examples of preferable cations represented by the formula (ca-2) include a diphenyliodonium cation and a bis(4-tert-butylphenyl)iodonium cation.

Specific examples of preferable cations represented by the formula (ca-3) include cations represented by the following formulas (ca-3-1) to (ca-3-6).

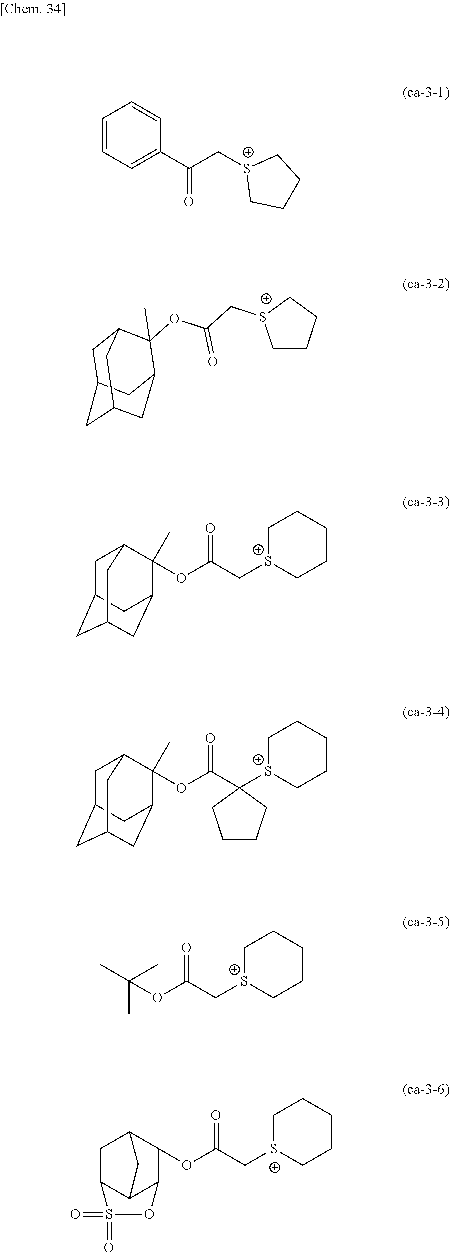 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

As the onium cation represented by M^{m}+, at least one selected from the group consisting of cations represented by the above formulas (ca-1) to (ca-3) is preferable, and among them, a cation represented by the above formula (ca-1) is more preferable, and a cation represented by the following formula (b0-ca) is still more preferable.

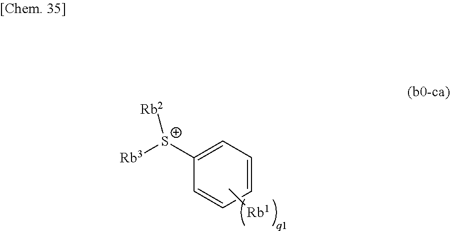

(In the formula, Rb¹ represents a fluorinated alkyl group or a fluorine atom. q1 represents an integer of 1 or more and 5 or less. Rb² and Rb³ each independently represent an aryl group which may have a substituent, an alkyl group which may have a substituent, or an alkenyl group which may have a substituent. Rb² and Rb³ may be bonded to each other to form a ring together with the sulfur atom in the formula. Rb² or Rb³ may form a condensed ring together with the sulfur atom and the benzene ring in the formula.)

The fluorinated alkyl group for Rb¹ is preferably a linear or branched fluorinated alkyl group having 1 or more and 5 or less carbon atoms, more preferably a linear fluorinated alkyl group having 1 or more and 5 or less carbon atoms, and still more preferably a trifluoromethyl group. q1 is preferably an integer of 1 or more and 4 or less, and more preferably 2 or 3. Rb¹ is preferably bonded to the ortho position or the meta position of the benzene ring from the viewpoint of photodecomposition efficiency. Rb² and Rb³ are the same as R²⁰¹ to R²⁰³ in the formula (ca-1).

In particular, from the viewpoint of achieving high sensitivity, the preferable cation represented by the formula (ca-1) is preferably a cation having an electron-withdrawing group such as a fluorine atom, a fluorinated alkyl group, and a sulfonyl group as a substituent, and more preferably, for example, a cation selected from the group consisting of cations represented by the above formulas (ca-1-44), (ca-1-71) to (ca-1-77), (ca-1-80), and (ca-1-81).

Specific preferable examples of onium salts (component (B0)) represented by the formula (b0) are shown below.

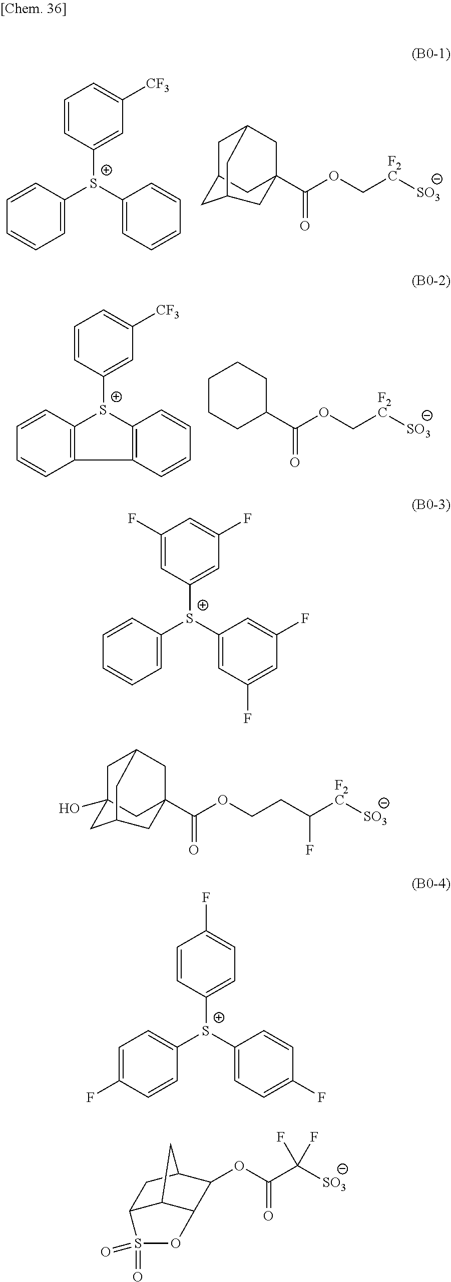

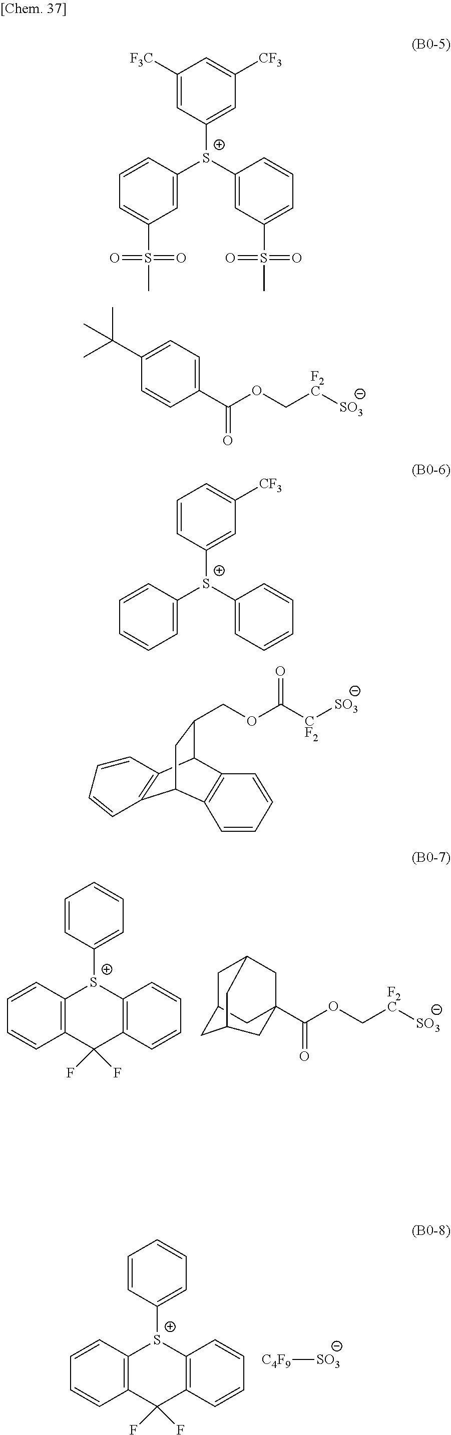

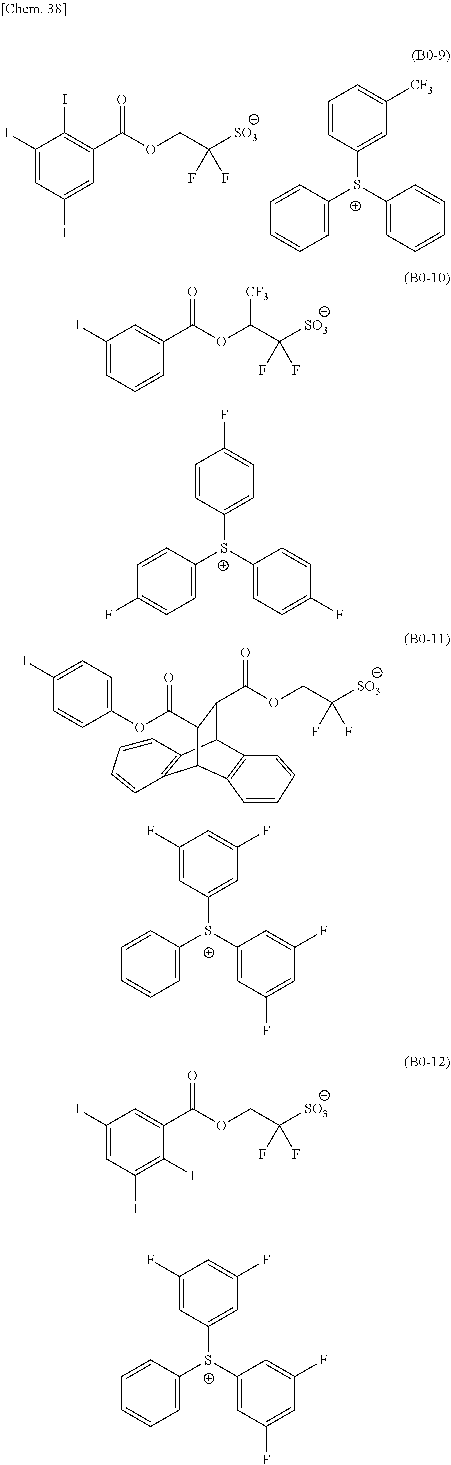

The component (B0) is preferably a compound selected from the group consisting of compounds represented by any one of the above formulas (BC-1) to (BC-12), and more preferably a compound represented by any one of the formulas (B0-11) to (B0-12).

### (Cage-Type Silsesquioxane (B1))

The film-forming composition may contain a cage-type silsesquioxane (B1) (hereinafter, also referred to as the “component (B1)”) as the component (B). The cage-type silsesquioxane (B1) has an ionic group decomposable upon exposure to light to generate an acid. The cage-type silsesquioxane (B1) preferably has a complete cage-type structure.

The content of the silicon atom in the component (B1) is preferably 5% or more and 45% or less, more preferably 10% or more and 35% or less, and still more preferably 10% or more and 25% or less with respect to the total amount of all atoms constituting the component (B1). A method for calculating the content of silicon atoms in the component (B1) is the same as the method for calculating the content of silicon atoms in the component (A).

The ionic group decomposable upon exposure to light to generate an acid is not particularly limited, and examples thereof include ionic groups in onium salt-based acid generation agents such as iodonium salts and sulfonium salts, which have been proposed as acid generation agents for chemically amplified resist compositions.

The ionic group decomposable upon exposure to light to generate an acid is preferably a group represented by the following formula (b9).

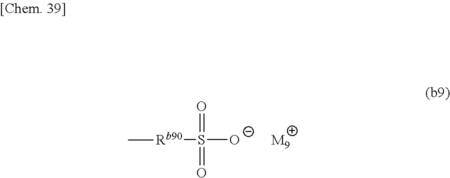

(In the formula (b9), R^{b90} represents a divalent organic group having 1 or more and 40 or less carbon atoms. M₉⁺ represents a sulfonium cation or an iodonium cation.)

Examples of the organic group for R^{b90} include a hydrocarbon group which may have a substituent, a divalent linking group containing an oxygen atom, and a combination thereof.

The group represented by the formula (b9) is preferably a group represented by the following formula (b9-1).

—R^{b91}—Yb⁹-Vb⁹-SO₃⁻M₉⁺ (b9-1)

(In the formula, R^{b91} represents a cyclic group which may have a substituent, a chain-like alkylene group which may have a substituent, a chain-like alkenylene group which may have a substituent, or a single bond. Yb⁹ represents a divalent linking group or a single bond. Vb⁹ represents an alkylene group, a fluorinated alkylene group, or a cyclic group which may have a substituent. M₉⁺ represents a sulfonium cation or an iodonium cation.)

### ⋅Regarding Anion Moiety

R^{b91} is preferably a cyclic group which may have a substituent or a single bond, and more preferably a single bond.

The cyclic group for R^{b91} is preferably a cyclic hydrocarbon group. The cyclic hydrocarbon group may be either an aromatic hydrocarbon group or an aliphatic hydrocarbon group, and is preferably an aromatic hydrocarbon group. The aliphatic hydrocarbon group may be either saturated or unsaturated, and is preferably saturated.

The number of carbon atoms in the aromatic hydrocarbon group for R^{b91} is preferably 3 or more and 30 or less, more preferably 5 or more and 30 or less, still more preferably 5 or more and 20 or less, particularly preferably 6 or more and 15 or less, and most preferably 6 or more and 10 or less. Here, the number of carbon atoms does not include the number of carbon atoms in the substituent.

Examples of the aromatic ring contained in the aromatic hydrocarbon group for R^{b91} include a benzene ring, a fluorene ring, a naphthalene ring, an anthracene ring, a phenanthrene ring, a biphenyl ring, and an aromatic heterocycle obtained by substituting a portion of the carbon atoms constituting these aromatic rings with a heteroatom(s). Examples of the heteroatom in the aromatic heterocycle include an oxygen atom, a sulfur atom, and a nitrogen atom. Examples of the aromatic hydrocarbon group for R^{b91} include a group obtained by removing two hydrogen atoms from the above aromatic ring (an arylene group, such as a phenylene group and a naphthylene group). Among them, a phenylene group is preferable.

Examples of the cyclic aliphatic hydrocarbon group for R^{b91} include an aliphatic hydrocarbon group containing a ring in a structure thereof. Examples of the aliphatic hydrocarbon group containing a ring in the structure thereof include an alicyclic hydrocarbon group (a group obtained by removing two hydrogen atoms from an aliphatic hydrocarbon ring), a group obtained by bonding an alicyclic hydrocarbon group to a terminal of a linear or branched aliphatic hydrocarbon group, and a group obtained by interposing an alicyclic hydrocarbon group in a linear or branched aliphatic hydrocarbon group. The number of carbon atoms in the above alicyclic hydrocarbon group is preferably 3 or more and 20 or less, and more preferably 3 or more and 12 or less. The above alicyclic hydrocarbon group may be either a polycyclic group or a monocyclic group. The monocyclic alicyclic hydrocarbon group is preferably a group obtained by removing two or more hydrogen atoms from a monocycloalkane. The monocycloalkane is preferably a monocycloalkane having 3 or more and 6 or less carbon atoms. Specific examples thereof include cyclopentane and cyclohexane. The polycyclic alicyclic hydrocarbon group is preferably a group obtained by removing two or more hydrogen atoms from a polycycloalkane. The polycycloalkane is preferably a polycycloalkane having 7 or more and 30 or less carbon atoms. Among them, a polycycloalkane having a crosslinked polycyclic skeleton, such as adamantane, norbornane, isobornane, tricyclodecane, and tetracyclododecane, and a polycycloalkane having a condensed polycyclic skeleton, such as a cyclic group having a steroid skeleton are preferable as the polycycloalkane.

Among them, the cyclic aliphatic hydrocarbon group for R^{b91} is preferably a group obtained by removing two or more hydrogen atoms from a monocycloalkane or a polycycloalkane, more preferably a group obtained by removing two hydrogen atoms from a polycycloalkane, still more preferably a group obtained by removing two hydrogen atoms from adamantane or norbornane, and most preferably a group obtained by removing two hydrogen atoms from adamantane.

The number of carbon atoms in the linear aliphatic hydrocarbon group which may be bonded to the alicyclic hydrocarbon group is preferably 1 or more and 10 or less, more preferably 1 or more and 6 or less, still more preferably 1 or more and 4 or less, and particularly preferably 1 or more and 3 or less. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—]. The number of carbon atoms in the branched aliphatic hydrocarbon group which may be bonded to the alicyclic hydrocarbon group is preferably 2 or more and 10 or less, more preferably 3 or more and 6 or less, still more preferably 3 or 4, and particularly preferably 3. The branched aliphatic hydrocarbon group is preferably a branched alkylene group, and specific examples include alkyl alkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—, alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—, alkyl trimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. The alkyl group in the alkyl alkylene group is preferably a linear alkyl group having 1 or more and 5 or less carbon atoms.

Further, the cyclic hydrocarbon group for R^{b91} may contain a heteroatom, such as a heterocycle.

The cyclic hydrocarbon group as R^{b91} may be a condensed cyclic group including a condensed ring obtained by condensing an aliphatic hydrocarbon ring and an aromatic ring. Examples of the above condensed ring include a ring obtained by condensing one or more aromatic rings with a polycycloalkane having a crosslinked polycyclic skeleton. Specific examples of the above crosslinked cyclic polycycloalkane include bicycloalkanes such as bicyclo[2.2.1]heptane (norbornane) and bicyclo[2.2.2]octane. The above condensed cyclic group is preferably a group containing a condensed ring obtained by condensing two or three aromatic rings with a bicycloalkane, and more preferably a group containing a condensed ring obtained by condensing two or three aromatic rings with bicyclo[2.2.2]octane.

The cyclic group as R^{b91} may have a substituent. Examples of the substituent include an alkyl group, an alkoxy group, a halogen atom, a halogenated alkyl group, a hydroxy group, a carbonyl group, and a nitro group. From the viewpoint of increasing sensitivity, the substituent is preferably a halogen atom, more preferably an iodine atom or a bromine atom, and still more preferably an iodine atom. When an iodine atom is contained as a substituent, the number of iodine atoms bonded to the cyclic group is preferably 1 or more and 3 or less, and more preferably 1 or 2.

The chain-like alkylene group for R^{b91} may be either linear or branched. The number of carbon atoms in the linear alkylene group is preferably 1 or more and 20 or less, more preferably 1 or more and 15 or less, and still more preferably 1 or more and 10 or less. The number of carbon atoms in the branched alkylene group is preferably 3 or more and 20 or less, more preferably 3 or more and 15 or less, and still more preferably 3 or more and 10 or less.

The chain-like alkenylene group for R^{b91} may be linear or branched. The number of carbon atoms in the chain-like alkenylene group is preferably 2 or more and 10 or less, more preferably 2 or more and 5 or less, still more preferably 2 or more and 4 or less, and particularly preferably 3.

The chain-like alkylene group or chain-like alkenylene group for R^{b91} may have a substituent. Examples of the substituent include an alkoxy group, a halogen atom, a halogenated alkyl group, a hydroxy group, a carbonyl group, and a nitro group. From the viewpoint of increasing sensitivity, the substituent is preferably a halogen atom, more preferably an iodine atom or a bromine atom, and still more preferably an iodine atom. When an iodine atom is contained as a substituent, the number of iodine atoms bonded to the chain-like alkylene group or the chain-like alkenylene group is preferably 1 or more and 3 or less, and more preferably 1 or 2.

Preferable examples of R^{b91} include a group represented by the following formula (b9-r-1p) or a cyclic group to which a group represented by the following formula (b9-r-1p) is bonded.

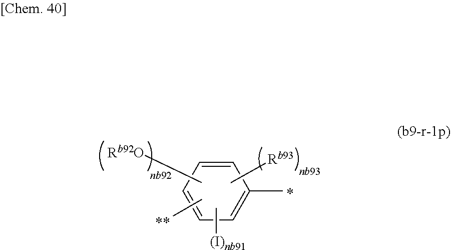

(In the formula, I represents an iodine atom. R^{b92} represents a hydrocarbon group having 1 or more and 6 or less carbon atoms or a hydrogen atom. R^{b93} represents a hydrocarbon group having 1 or more and 6 or less carbon atoms. nb91 represents an integer of 1 or more and 4 or less. nb92 represents an integer of 0 or more and 3 or less. nb93 represents an integer of 0 or more and 3 or less. 1≤nb91+nb92+nb93≤4. * represents a bonding site bonded to Yb⁹ in the above formula (b9-1) or a bonding site bonded to a cyclic group. ** represents a bonding site other than *.)

The number of carbon atoms in the hydrocarbon group for R^{b92} is preferably 1 or more and 5 or less. The hydrocarbon group for R^{b92} is preferably a methyl group, an ethyl group, a propyl group, or an isopropyl group, more preferably a methyl group or an ethyl group, and still more preferably a methyl group. R^{b92} is preferably a hydrogen atom. That is, —OR^{b92} is preferably a phenolic hydroxy group.

The number of carbon atoms in the hydrocarbon group for R^{b93} is preferably 1 or more and 5 or less. The hydrocarbon group for R^{b93} is preferably a methyl group, an ethyl group, a propyl group, or an isopropyl group, and more preferably a methyl group or an ethyl group. nb91 is preferably 1 or 2, and more preferably 1. nb92 is preferably 0 or 1, and more preferably 0. nb93 is preferably 0 or 1, and more preferably 0.

The divalent linking group for Yb⁹ is preferably a divalent linking group containing an oxygen atom. When Yb⁹ is a divalent linking group containing an oxygen atom, Yb⁹ may contain an atom other than an oxygen atom. Examples of the atom other than an oxygen atom include a carbon atom, a hydrogen atom, a sulfur atom, and a nitrogen atom. Examples of the divalent linking group containing an oxygen atom include: a non-hydrocarbon-based oxygen atom-containing linking group such as an oxygen atom (ether bond: —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking group and an alkylene group. A sulfonyl group (—SO₂—) may be further linked to this combination. Among the divalent linking groups containing an oxygen atom, an ester bond (—C(═O)—O—) or an oxycarbonyl group (—O—C(═O)—) is more preferable. Yb⁹ is preferably a divalent linking group containing an oxygen atom or a single bond, more preferably an ester bond (—C(═O)—O—), an oxycarbonyl group (—O—C(═O)—), or a single bond, and still more preferably a single bond.

The number of carbon atoms in each of the alkylene group and the fluorinated alkylene group for Vb⁹ is preferably 1 or more and 5 or less, and more preferably 1 or more and 3 or less.

The alkylene group for Vb⁹ is preferably a linear or branched alkylene group, and more preferably a linear alkylene group. The alkylene group for Vb⁹ is preferably a methylene group, an ethane-1,2-diyl group, or a propane-1,3-diyl group, and more preferably an ethane-1,2-diyl group. Examples of the fluorinated alkylene group for Vb⁹ include groups obtained by substituting a portion or all of the hydrogen atoms in the alkylene group as Vb⁹ with a fluorine atom(s). The fluorinated alkylene group for Vb⁹ is preferably —CH₂CF₂—, —CHFCF₂—, or —CH₂CH₂CF₂—.

The cyclic group for Vb⁹ is preferably an aromatic hydrocarbon group. The number of carbon atoms in the aromatic hydrocarbon group for Vb⁹ is preferably 3 or more and 30 or less, more preferably 6 or more and 15 or less, and still more preferably 6 or more and 10 or less. Here, the number of carbon atoms does not include the number of carbon atoms in the substituent. Examples of the aromatic hydrocarbon group for Vb⁹ include a phenylene group and a naphthylene group. Examples of the substituent which may be contained by the aromatic hydrocarbon group for Vb⁹ include an alkoxy group, a halogen atom, a halogenated alkyl group, a hydroxy group, a carbonyl group, and a nitro group. From the viewpoint of higher sensitivity, the substituent is preferably a halogen atom, and more preferably a fluorine atom.

Specific preferable examples of anion moieties of the group represented by the formula (b9-1) are shown below. Among them, the anion moiety represented by (b-R1-2) or (b-R1-5) is preferable.

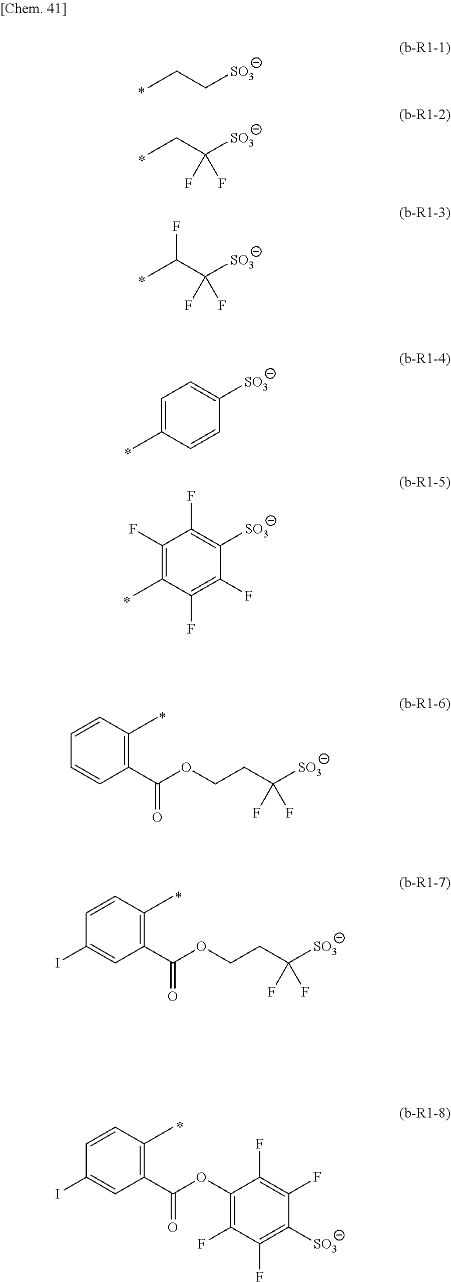

### ⋅Regarding Cation Moiety

Examples of the sulfonium cation or iodonium cation for M₉⁺ include organic cations represented by the above formulas (ca-1) to (ca-3).

The component (B1) may have an aromatic group having a phenolic hydroxy group, in addition to the ionic group decomposable upon exposure to light to generate an acid.

Examples of the aromatic group that is the aromatic group having a phenolic hydroxy group include hydrocarbon groups having at least one aromatic ring. The aromatic ring may be monocyclic or polycyclic. The number of carbon atoms in the aromatic ring is preferably 5 or more and 30 or less, more preferably 5 or more and 20 or less, still more preferably 6 or more and 15 or less, and particularly preferably 6 or more and 12 or less. Here, the number of carbon atoms does not include the number of carbon atoms in the substituent. Specific examples of the aromatic ring include a benzene ring, a naphthalene ring, an anthracene ring, and a phenanthrene ring. Among them, a benzene ring and a naphthalene ring are preferable, and a benzene ring is more preferable. Examples of the aromatic group include a group obtained by removing one hydrogen atom from the above aromatic ring (aryl group: for example, a phenyl group or a naphthyl group); and a group obtained by removing one hydrogen atom from an aromatic compound having two or more aromatic rings (for example, biphenyl or fluorene).

The number of phenolic hydroxy groups contained in the aromatic group is preferably 1, 2, or 3, more preferably 1 or 2, and particularly preferably 1, per aromatic group.

In the aromatic group, the hydrogen atom bonded to the above aromatic ring may be substituted with a substituent other than a phenolic hydroxy group. Examples of the substituent include an alkyl group, a halogenated alkyl group, and a halogen atom. Examples of the alkyl group as the substituent include an alkyl group having 1 or more and 5 or less carbon atoms, and the alkyl group may be linear or branched. Examples of the halogenated alkyl group as the substituent include a group obtained by substituting a portion or all hydrogen atoms of an alkyl group having 1 or more and 5 or less carbon atoms with a halogen atom(s). The halogen atom as the substituent is preferably a fluorine atom.

Specific preferable examples of the aromatic group having a phenolic hydroxy group are shown below. Among them, a group represented by (b-R2-1) or (b-R2-4) is preferable.

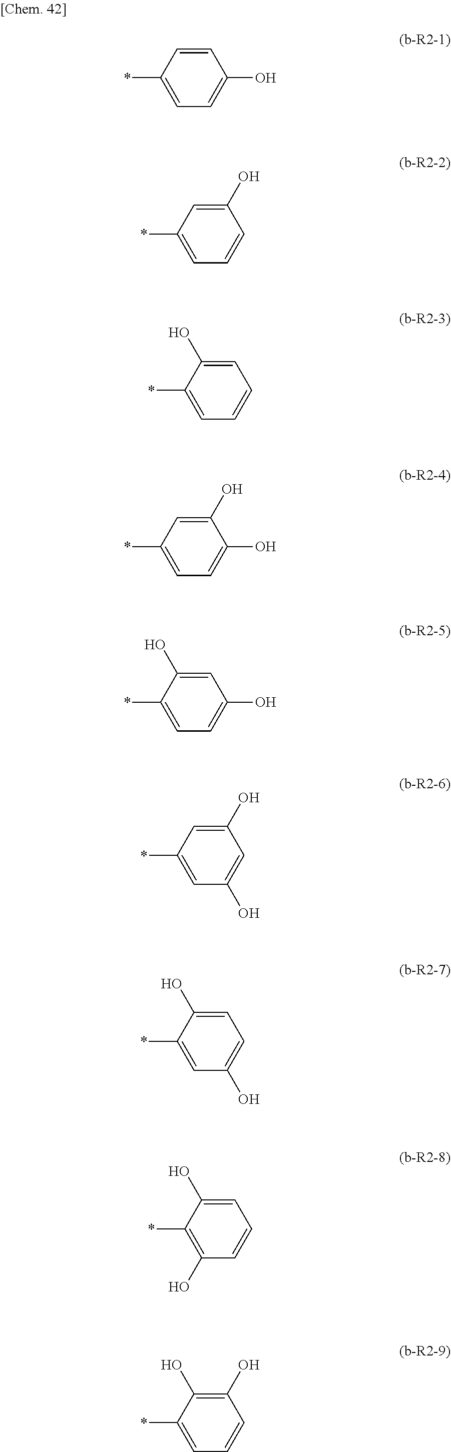

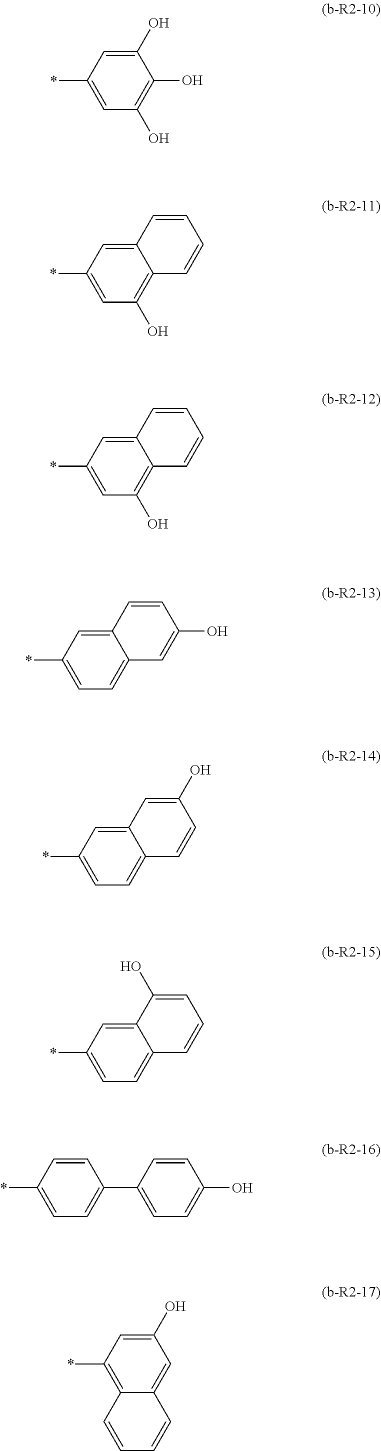

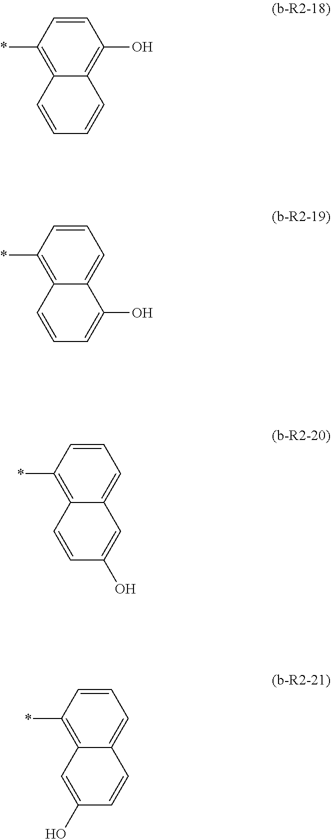 [SMILES: *c1ccc(O)c2ccccc12 ; *c1cccc2c(O)cccc12 ; *c1cccc2cc(O)ccc12 ; *c1cccc2ccc(O)cc12]

The cage-type silsesquioxane (B1) is preferably a cage-type silsesquioxane represented by the following formula (b11).

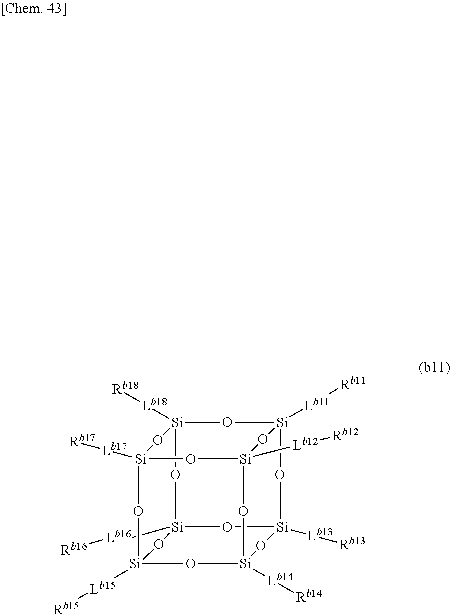

(In the formula (b11), R^{b11} to R^{b18} each independently represent an organic group having 1 or more and 40 or less carbon atoms, or a hydrogen atom. At least one of R^{b11} to R^{b18} represents an ionic group decomposable upon exposure to light to generate an acid. L^{b11} to L^{b18} each independently represent a divalent linking group having 1 or more and 40 or less carbon atoms and containing at least one selected from the group consisting of an oxygen atom, a nitrogen atom, a sulfur atom, and a silicon atom.)

The organic group for R^{b11} to R^{b18} is preferably an ionic group decomposable upon exposure to light to generate an acid, an aromatic group having a phenolic hydroxy group, or a hydrocarbon group having 1 or more and 10 or less carbon atoms.

At least another one of R^{b11} to R^{b18} is preferably an aromatic group having a phenolic hydroxy group.

Among R^{b11} to R^{b18}, the number of ionic groups that are decomposable upon exposure to light to generate an acid is preferably 1 or more and 3 or less, more preferably 1 or more and 2 or less, and still more preferably 1. Among R^{b11} to R^{b18}, the number of aromatic groups having a phenolic hydroxy group is preferably 1 or more and 7 or less, more preferably 6 or more and 7 or less, and still more preferably 7.

The ionic group to generate an acid upon exposure to light and the aromatic group having a phenolic hydroxy group are as described above.

The hydrocarbon group having 1 or more and 10 or less carbon atoms for R^{b11} to R^{b18} may be linear, branched, or cyclic, and is preferably linear or branched. The hydrocarbon group herein may be a saturated hydrocarbon group or an unsaturated hydrocarbon group, and is preferably a saturated hydrocarbon group. The number of carbon atoms in the hydrocarbon group herein is preferably 1 or more and 6 or less, more preferably 1 or more and 5 or less, and still more preferably 1 or more and 3 or less. Among them, a methyl group, an ethyl group, a propyl group, and an isopropyl group are more preferable, a methyl group and an ethyl group are still more preferable, and a methyl group is particularly preferable.

The number of carbon atoms in the divalent linking group as L^{b11} to L^{b18} is preferably 1 or more and 30 or less, more preferably 1 or more and 20 or less, still more preferably 1 or more and 10 or less, and particularly preferably 1 or more and 6 or less.

The divalent linking group as L^{b11} to L^{b18} preferably contains at least one selected from the group consisting of an oxygen atom, a sulfur atom, and a silicon atom, more preferably contains at least two selected from the group consisting of an oxygen atom, a sulfur atom, and a silicon atom, and still more preferably contains an oxygen atom and a silicon atom.

The divalent linking group as L^{b11} to L^{b18} is preferably a divalent linking group represented by any one of the following formulas (a1-L-1) to (a1-L-8).

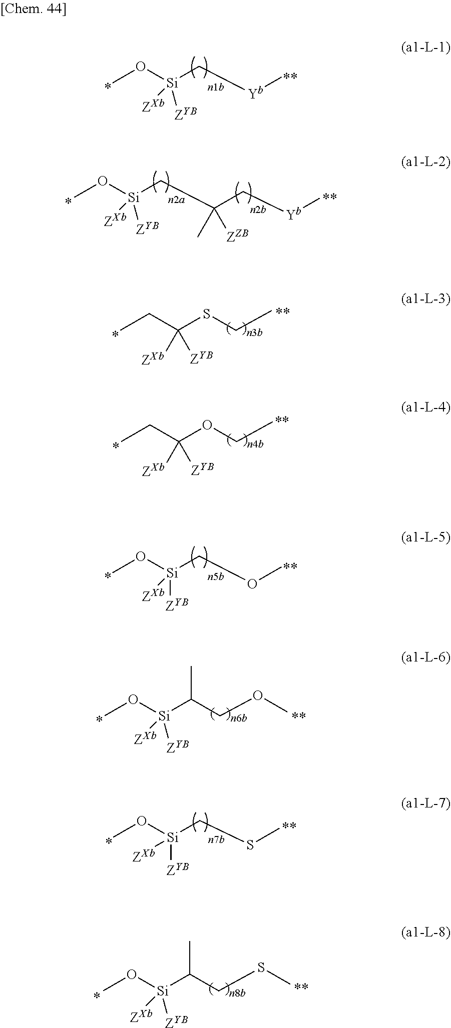

(In the formulas (a1-L-1) to (a1-L-8), Z^{Xb}, Z^{Yb}, and Z^{Zb} each independently represent a hydrocarbon group having 1 or more and 6 or less carbon atoms or a hydrogen atom. n1b to n8b and n2a each independently represent an integer of 0 or more and 10 or less. * represents a bonding site to Si. Y^{b} represents a divalent linking group or a single bond. The number of carbon atoms ** represents a bonding site to any one of R^{b11} to R^{b18}.)

The hydrocarbon group having 1 or more and 6 or less carbon atoms as Z^{Xb}, Z^{Yb}, and Z^{Zb} may be linear, branched, or cyclic, and is preferably linear or branched. The hydrocarbon group as Z^{Xb}, Z^{Yb}, and Z^{Zb} may be a saturated hydrocarbon group or an unsaturated hydrocarbon group, and is preferably a saturated hydrocarbon group. The number of carbon atoms in the hydrocarbon group as Z^{Xb}, Z^{Yb}, and Z^{Zb} is preferably 1 or more and 5 or less, and more preferably 1 or more and 3 or less. The hydrocarbon group as Z^{Xb} and Z^{Yb} is preferably a methyl group, an ethyl group, a propyl group, or an isopropyl group, more preferably a methyl group or an ethyl group, and still more preferably a methyl group.

In the formulas (a1-L-1) and (a1-L-2), Z^{Xb} and Z^{Yb} are each preferably a hydrocarbon group having 1 or more and 6 or less carbon atoms, more preferably both are a hydrocarbon group having 1 or more and 6 or less carbon atoms, still more preferably both are a hydrocarbon group having 1 or more and 3 or less carbon atoms, and particularly preferably both are a methyl group. Z^{Zb} is preferably a hydrocarbon group having 1 or more and 6 or less carbon atoms or a single bond, more preferably a hydrocarbon group having 1 or more and 3 or less carbon atoms or a single bond, still more preferably a methyl group or a single bond, and particularly preferably a single bond. In the formula (a1-L-3), Z^{Xb} and Z^{Yb} are each preferably a hydrogen atom, and more preferably both are a hydrogen atom. In the formula (a1-L-4), Z^{Xb} and Z^{Yb} are each preferably a hydrogen atom, and more preferably both are a hydrogen atom. In the formulas (a1-L-5) to (a1-L-6), Z^{Xb} and Z^{Yb} are each preferably a hydrocarbon group having 1 or more and 6 or less carbon atoms, more preferably both are a hydrocarbon group having 1 or more and 6 or less carbon atoms, still more preferably both are a hydrocarbon group having 1 or more and 3 or less carbon atoms, and particularly preferably both are a methyl group. In the formulas (a1-L-7) to (a1-L-8), Z^{Xb} and Z^{Yb} are each preferably a hydrocarbon group having 1 or more and 6 or less carbon atoms, more preferably both are a hydrocarbon group having 1 or more and 6 or less carbon atoms, still more preferably both are a hydrocarbon group having 1 or more and 3 or less carbon atoms, and particularly preferably both are a methyl group.

In the formula (a1-L-1), nib is preferably an integer of 0 or more and 7 or less, more preferably an integer of 2 or more and 5 or less, and still more preferably 2 or 3. In the formula (a1-L-2), n2b is preferably an integer of 0 or more and 5 or less, more preferably an integer of 0 or more and 3 or less, and still more preferably 0 or 1. n2a is preferably an integer of 0 or more and 5 or less, more preferably an integer of 0 or more and 3 or less, and still more preferably 0 or 1. In the formula (a1-L-3), n3b is preferably an integer of 0 or more and 5 or less, more preferably an integer of 0 or more and 3 or less, and still more preferably 0 or 1. In the formula (a1-L-4), n4b is preferably an integer of 0 or more and 5 or less, more preferably an integer of 0 or more and 3 or less, and still more preferably 1. In the formula (a1-L-5), n5b is preferably an integer of 0 or more and 8 or less, more preferably an integer of 2 or more and 5 or less, and still more preferably 2 or 3. In the formula (a1-L-6), n6b is preferably an integer of 0 or more and 6 or less, more preferably an integer of 0 or more and 3 or less, and still more preferably 0 or 1. In the formula (a1-L-7), n7b is preferably an integer of 0 or more and 8 or less, more preferably an integer of 2 or more and 5 or less, and still more preferably 2 or 3. In the formula (a1-L-8), n8b is preferably an integer of 0 or more and 6 or less, more preferably an integer of 0 or more and 3 or less, and still more preferably 0 or 1.

The divalent linking group for Y^{b} is preferably a divalent linking group containing an oxygen atom. When Y^{b} is a divalent linking group containing an oxygen atom, Y may contain an atom other than an oxygen atom. Examples of the atom other than an oxygen atom include a carbon atom, a hydrogen atom, a sulfur atom, and a nitrogen atom. Examples of the divalent linking group containing an oxygen atom include: a non-hydrocarbon-based oxygen atom-containing linking group such as an oxygen atom (ether bond: —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking group and an alkylene group. A sulfonyl group (—SO₂—) may be further linked to this combination. Among the divalent linking groups containing an oxygen atom, an ester bond (—C(═O)—O—) or an oxycarbonyl group (—O—C(═O)—) is more preferable. Y^{b} is preferably a divalent linking group containing an oxygen atom or a single bond, and is more preferably an ester bond (—C(═O)—O—), an oxycarbonyl group (—O—C(═O)—), or a single bond.

Specific preferable examples of L^{b11} to L^{b18} are shown below. ** represents a bonding site to Si. * represents a bonding site to any one of R^{b11} to R^{b18}. Among them, groups represented by (b-L1-2) to (b-L1-9) and (b-L1-33) are preferable.

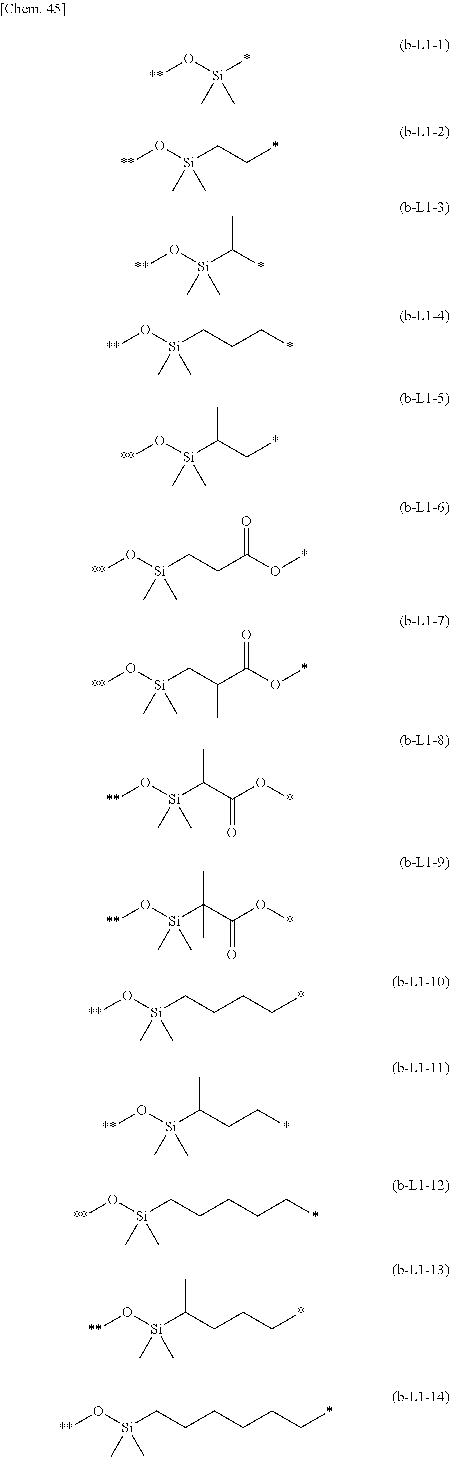

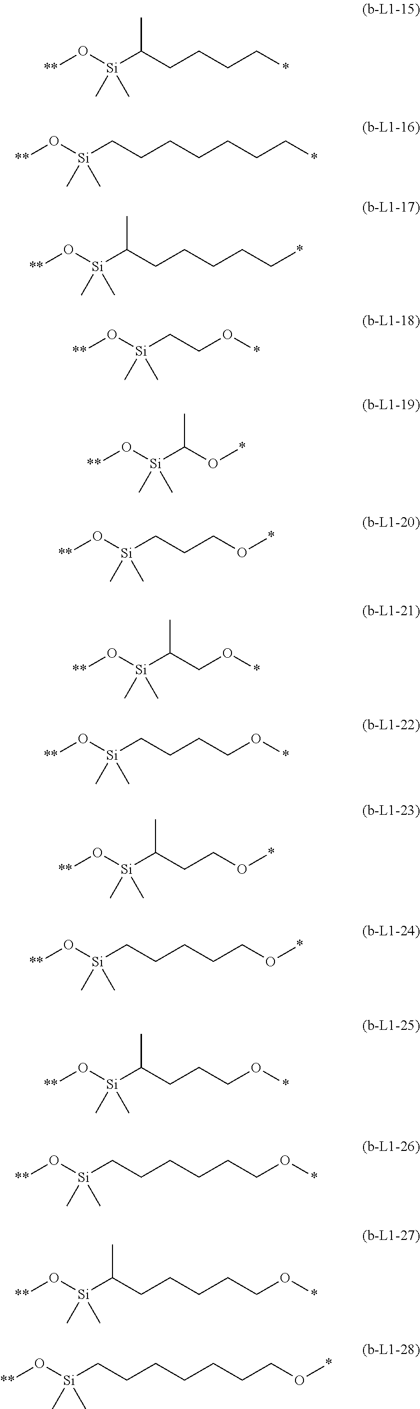

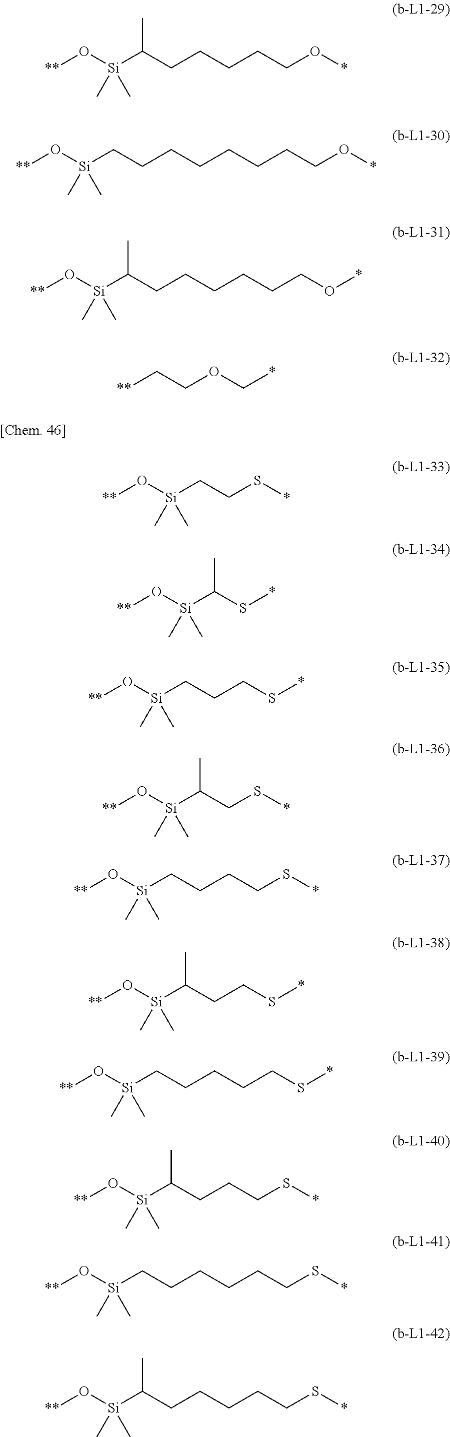

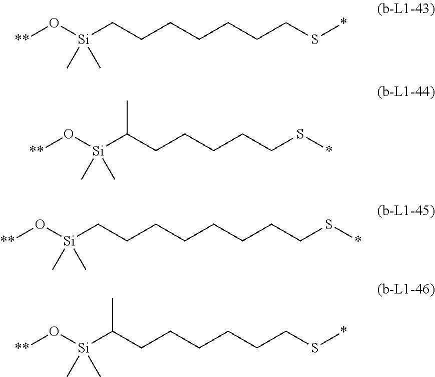

L^{b11} to L^{b18} are preferably a divalent linking group selected from the group consisting of groups respectively represented by the above formulas (a1-L-1), (a1-L-2), and (a1-L-7).

The weight average molecular weight (Mw) (polystyrene conversion reference by gel permeation chromatography (GPC)) of the cage-type silsesquioxane (B1) is not particularly limited, and is preferably 1000 or more and 5000 or less, more preferably 1200 or more and 4000 or less, and still more preferably 1500 or more and 3500 or less. When the Mw of the cage-type silsesquioxane (B1) is equal to or less than the preferable upper limit value of this range, sufficient solubility in a solvent is obtained, and when the Mw of the cage-type silsesquioxane (B1) is equal to or more than the preferable lower limit value of this range, dry etching resistance is enhanced, and a cross-sectional shape of a resist pattern is good. The dispersity (Mw/Mn) of the cage-type silsesquioxane (B1) is not particularly limited, and is preferably 1.00 or more and 1.40 or less, more preferably 1.00 or more and 1.30 or less, and still more preferably 1.00 or more and 1.20 or less. Note that Mn represents a number average molecular weight.

The component (B1) can be produced using a known production method. For example, the cage-type silsesquioxane represented by (b11) can be produced by causing a reaction of the following raw material (X) and the following raw material (Y) and appropriately performing a deprotection reaction as in Synthesis Examples (1) to (7) described below.

Raw material (X): octasilsesquioxane having a cage-type structure in which a functional group capable of reacting with the raw material (Y) is bonded to silicon (Si) at each vertex. Examples of the functional group capable of reacting with the raw material (Y) include a dimethylsilyloxy group and a vinyl group.

Raw material (Y): a raw material having an “ionic group decomposable upon exposure to light to generate an acid” or a part thereof. Examples of the raw material include 1,1-difluoro-2-(methacryloyloxy)ethanesulfonic acid benzyltrimethylammonium salt and 4-ethenyl-2,3,5,6-tetrafluorobenzenesulfonic acid.

One kind of the component (B) may be used alone, or two or more kinds thereof may be used in combination. The content of the component (B) (in particular, the component (B0)) is preferably 10 parts by mass or more and 50 parts by mass or less, more preferably 20 parts by mass or more and 45 parts by mass or less, and still more preferably 25 parts by mass or more and 40 parts by mass or less with respect to 100 parts by mass of the component (A). When the content of the component (B) is equal to or more than the lower limit value of the above preferable range, lithography properties such as sensitivity, resolution performance, and line width roughness (LWR) reduction property are easily improved in the formation of a resist pattern. On the other hand, when the content is equal to or less than the upper limit value of the preferable range, a uniform solution is easily obtained when the components of the film-forming composition are dissolved in an organic solvent, and the storage stability as a composition is more easily enhanced.

### [Silicon-Containing Crosslinking Agent (C1)]

The first film-forming composition contains a silicon-containing crosslinking agent (C1) (hereinafter, also referred to as “component (C1)”) as the crosslinking agent (C). The silicon-containing crosslinking agent (C1) has a methylol group and/or an alkoxymethyl group.

The content of the silicon atom in the component (C1) is preferably 5% or more and 45% or less, more preferably 8% or more and 35% or less, and still more preferably 10% or more and 25% or less with respect to the total amount of all atoms constituting the component (C1). The method for calculating the content of silicon atoms in the component (C1) is the same as the method for calculating the content of silicon atoms in the component (A).

The methylol group and/or alkoxymethyl group contained in the component (C1) are/is preferably bonded to an aromatic group or a nitrogen atom. Accordingly, the action of a crosslinking agent is easily exhibited.

The component (C1) may have a phenolic hydroxy group in addition to a methylol group and/or an alkoxymethyl group.

The silicon-containing crosslinking agent (C1) is preferably siloxane, and more preferably cage-type silsesquioxane and cyclic siloxane.

The silicon-containing crosslinking agent (C1) preferably contains at least one selected from the group consisting of a cage-type silsesquioxane (C1-1) represented by the following formula (c1-1) and a cyclic siloxane (C1-2) represented by the following formula (c1-2).

### (Cage-Type Silsesquioxane (C1-1))

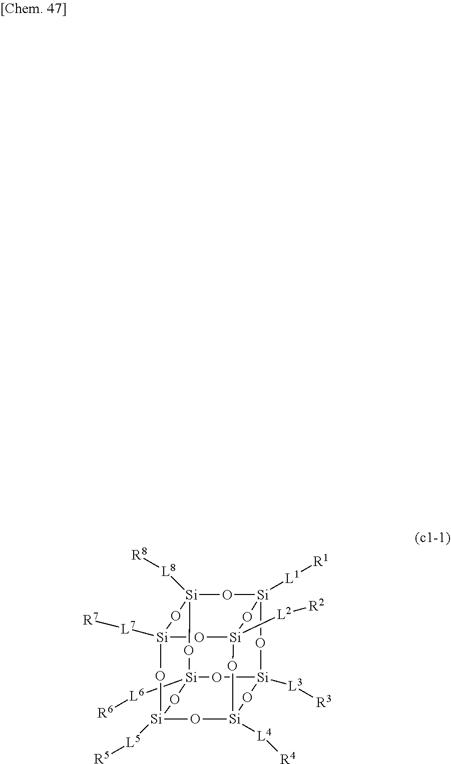

(In the formula (c1-1), R¹ to R⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R¹ to R⁸ represents an aromatic group having a methylol group or an alkoxymethyl group, or a nitrogen atom-containing group having a methylol group or an alkoxymethyl group. L¹ to L⁸ each independently represent a divalent linking group represented by any one of the following formulas (c1-L-1) to (c1-L-7).)

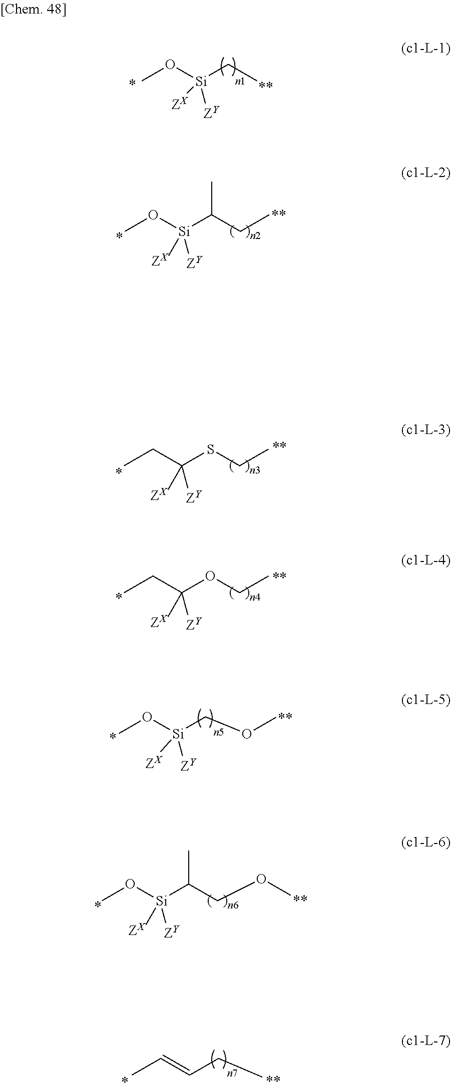

(In the formulas (c1-L-1) to (c1-L-7), Z^{X} and Z each independently represent a hydrocarbon group having 1 or more and 6 or less carbon atoms or a hydrogen atom. n1 to n7 each independently represent an integer of 0 or more and 10 or less. * represents a bonding site to Si. ** represents a bonding site to any one of R¹ to R⁸.)

Each of R¹ to R⁸ is preferably an aromatic group having a methylol group or an alkoxymethyl group, a nitrogen atom-containing group having a methylol group or an alkoxymethyl group, or an aromatic group having a phenolic hydroxy group, more preferably an aromatic group having a methylol group or an alkoxymethyl group, or an aromatic group having a phenolic hydroxy group, and still more preferably an aromatic group having a methylol group or an alkoxymethyl group.

At least another one of R¹ to R⁸ may be an aromatic group having a phenolic hydroxy group.

Among R¹ to R⁸, the number of aromatic groups having a methylol group or an alkoxymethyl group is preferably 1 or more, more preferably 3 or more, still more preferably 5 or more, particularly preferably 7 or more, and may be 8. The number of aromatic groups having a methylol group or an alkoxymethyl group may be, for example, 7 or less, 5 or less, 3 or less, or 1 or less. Among R¹ to R⁸, the number of nitrogen atom-containing groups having a methylol group or an alkoxymethyl group is preferably 1 or more, more preferably 3 or more, still more preferably 5 or more, particularly preferably 7 or more, and may be 8. The number of aromatic groups having a methylol group or an alkoxymethyl group may be, for example, 7 or less, 5 or less, 3 or less, or 1 or less. Among R¹ to R⁸, the total number of aromatic groups having a methylol group or an alkoxymethyl group and nitrogen-containing groups having a methylol group or an alkoxymethyl group is preferably 3 or more, more preferably 5 or more, still more preferably 7 or more, and may be 8. The total number may be, for example, 7 or less, 5 or less, 3 or less, or 1. Among R¹ to R⁸, the number of aromatic groups having a phenolic hydroxy group may be, for example, 1 or more, 3 or more, 5 or more, or 7 or more, and may be 7 or less, 5 or less, 3 or less, or 1 or less.

The aromatic group having a methylol group or an alkoxymethyl group for R¹ to R⁸ is preferably an aromatic group obtained by substituting a hydrogen atom bonded to an aromatic ring with a methylol group or an alkoxymethyl group. Examples of the aromatic group for R¹ to R⁸ include hydrocarbon groups having at least one aromatic ring. The aromatic ring may be monocyclic or polycyclic. The number of carbon atoms in the aromatic ring is preferably 5 or more and 30 or less, more preferably 5 or more and 20 or less, still more preferably 6 or more and 15 or less, and particularly preferably 6 or more and 12 or less. Here, the number of carbon atoms does not include the number of carbon atoms in the substituent. Specific examples of the aromatic ring include a benzene ring, a naphthalene ring, an anthracene ring, and a phenanthrene ring. Among them, a benzene ring and a naphthalene ring are preferable, and a benzene ring is more preferable. Examples of the aromatic group include a group obtained by removing one hydrogen atom from the above aromatic ring (aryl group: for example, a phenyl group or a naphthyl group); and a group obtained by removing one hydrogen atom from an aromatic compound having two or more aromatic rings (for example, biphenyl or fluorene).

The number of methylol groups and alkoxymethyl groups contained in the aromatic groups for R¹ to R⁸ is preferably 1 or more and 3 or less, more preferably 1 or 2, and still more preferably 1, per aromatic group.

In the aromatic group for R¹ to R⁸, the hydrogen atom bonded to the above aromatic ring may be substituted with a substituent other than a methylol group and an alkoxymethyl group. Examples of the substituent include an alkyl group, a halogenated alkyl group, and a halogen atom. Examples of the alkyl group as the substituent include an alkyl group having 1 or more and 5 or less carbon atoms. The alkyl group may be linear or branched. Examples of the halogenated alkyl group as the substituent include a group obtained by substituting a portion or all hydrogen atoms of an alkyl group having 1 or more and 5 or less carbon atoms with a halogen atom(s). The halogen atom as the substituent is preferably a fluorine atom.

Specific preferable examples of the aromatic group having a methylol group or an alkoxymethyl group are shown below. Among them, the group represented by the formula (c1-R1-1) is preferable.

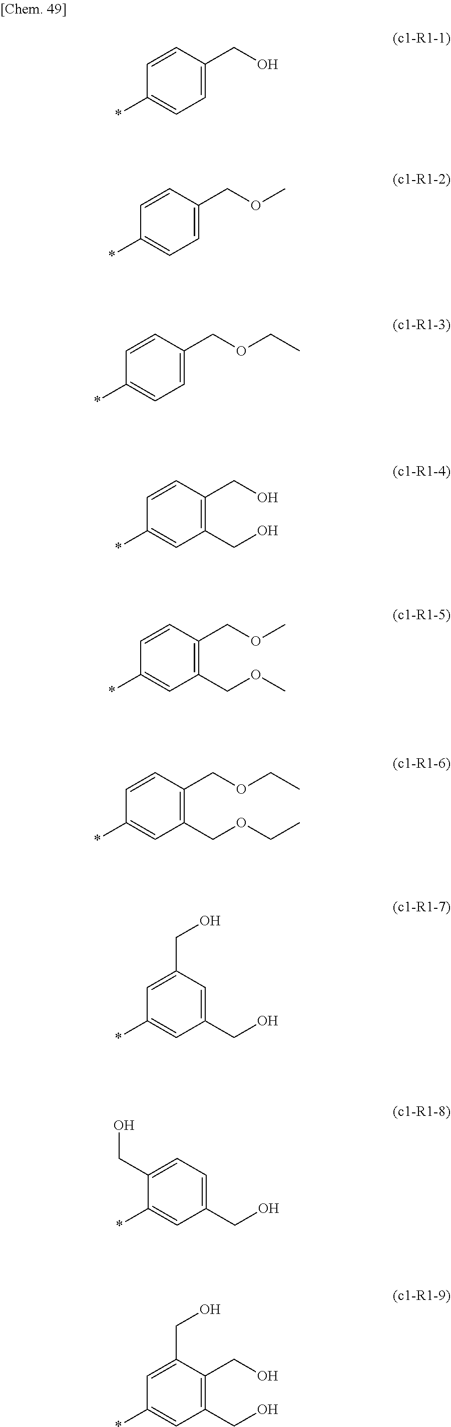

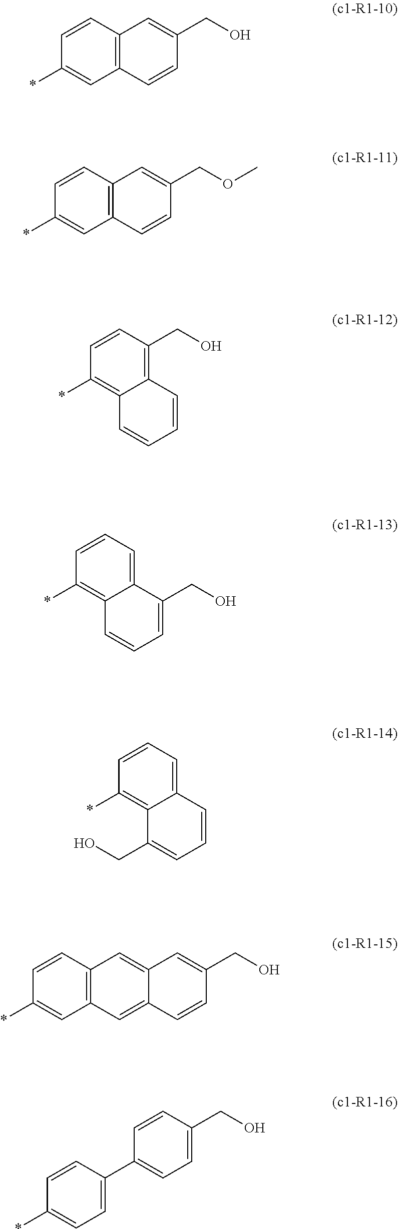

The nitrogen atom-containing group having a methylol group or an alkoxymethyl group for R¹ to R⁸ is preferably a nitrogen atom-containing heterocyclic group obtained by substituting the N-position with a methylol group or an alkoxymethyl group.

The number of carbon atoms in the nitrogen atom-containing heterocyclic group for R¹ to R⁸ is preferably 3 or more and 20 or less, more preferably 4 or more and 15 or less, and still more preferably 4 or more and 10 or less. Here, the number of carbon atoms does not include the number of carbon atoms in the substituent. Examples of the nitrogen atom-containing heterocyclic group include groups formed of succinimide, cyclohexyldicarboimide, and the like.

Specific preferable examples of the nitrogen atom-containing group having a methylol group or an alkoxymethyl group are shown below.

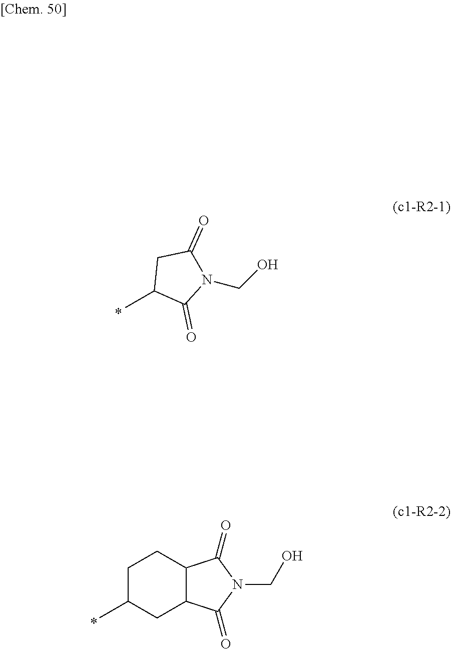

Examples of the aromatic group having a phenolic hydroxy group for R¹ to R⁸ include hydrocarbon groups having at least one aromatic ring. The aromatic ring may be monocyclic or polycyclic. The number of carbon atoms in the aromatic ring is preferably 5 or more and 30 or less, more preferably 5 or more and 20 or less, still more preferably 6 or more and 15 or less, and particularly preferably 6 or more and 12 or less. Here, the number of carbon atoms does not include the number of carbon atoms in the substituent. Specific examples of the aromatic ring include a benzene ring, a naphthalene ring, an anthracene ring, and a phenanthrene ring. Among them, a benzene ring and a naphthalene ring are preferable, and a benzene ring is more preferable. Examples of the aromatic group include a group obtained by removing one hydrogen atom from the above aromatic ring (aryl group: for example, a phenyl group or a naphthyl group); and a group obtained by removing one hydrogen atom from an aromatic compound having two or more aromatic rings (for example, biphenyl or fluorene).

The number of phenolic hydroxy groups contained in the aromatic group as R¹ to R⁸ is preferably 1, 2, or 3, more preferably 1 or 2, and particularly preferably 1, per aromatic group.

In the aromatic group, the hydrogen atom bonded to the above aromatic ring may be substituted with a substituent other than a phenolic hydroxy group. Examples of the substituent include an alkyl group, a halogenated alkyl group, and a halogen atom. Examples of the alkyl group as the substituent include an alkyl group having 1 or more and 5 or less carbon atoms, and the alkyl group may be linear or branched. Examples of the halogenated alkyl group as the substituent include a group obtained by substituting a portion or all hydrogen atoms of an alkyl group having 1 or more and 5 or less carbon atoms with a halogen atom(s). The halogen atom as the substituent is preferably a fluorine atom.

Specific preferable examples of the aromatic group having a phenolic hydroxy group are shown below. Among them, a group represented by (c1-R3-1) or (c1-R3-4) is preferable.

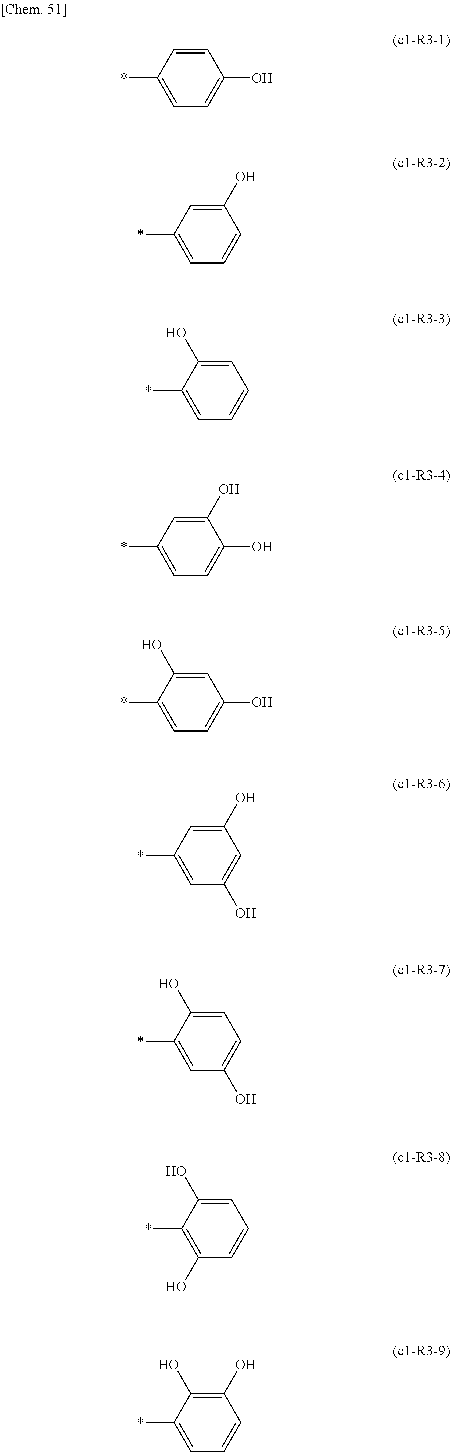

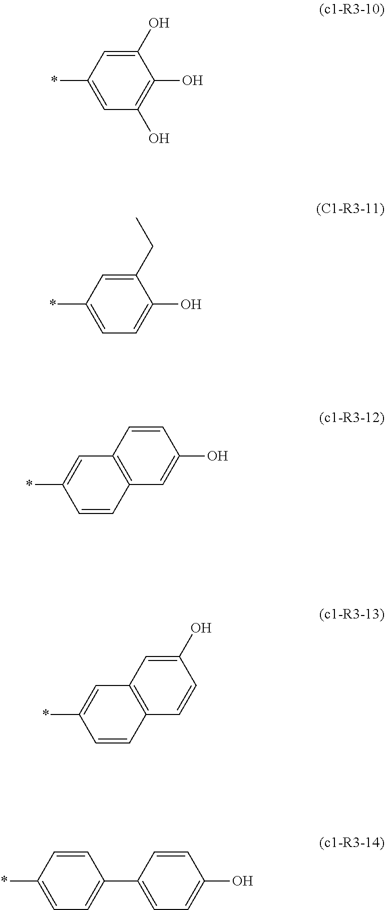

The hydrocarbon group having 1 or more and 10 or less carbon atoms for R¹ to R⁸ may be linear, branched, or cyclic, and is preferably linear or branched. The hydrocarbon group herein may be a saturated hydrocarbon group or an unsaturated hydrocarbon group, and is preferably a saturated hydrocarbon group. The number of carbon atoms in the hydrocarbon group herein is preferably 1 or more and 6 or less, more preferably 1 or more and 5 or less, and still more preferably 1 or more and 3 or less. Among them, a methyl group, an ethyl group, a propyl group, and an isopropyl group are preferable, a methyl group and an ethyl group are more preferable, and a methyl group is still more preferable.

The hydrocarbon group having 1 or more and 6 or less carbon atoms for Z^{X} and Z^{Y} may be linear, branched, or cyclic, and is preferably linear or branched. The hydrocarbon group for Z^{X} and Z^{Y} may be a saturated hydrocarbon group or an unsaturated hydrocarbon group, and is preferably a saturated hydrocarbon group. The number of carbon atoms in the hydrocarbon group for Z^{X} and Z^{Y} is preferably 1 or more and 5 or less, and more preferably 1 or more and 3 or less. The hydrocarbon group for Z^{X} and Z^{Y} is preferably a methyl group, an ethyl group, a propyl group, or an isopropyl group, more preferably a methyl group or an ethyl group, and still more preferably a methyl group.

In the formula (c1-L-1), the formula (c1-L-2), the formula (c1-L-5), and the formula (c1-L-6), Z^{X} and Z^{Y} are each preferably a hydrocarbon group having 1 or more and 6 or less carbon atoms, more preferably both are a hydrocarbon group having 1 or more and 6 or less carbon atoms, still more preferably both are a hydrocarbon group having 1 or more and 3 or less carbon atoms, and particularly preferably both are a methyl group. In the formulas (c1-L-3) and (c1-L-4), Z^{X} and Z^{Y} are each preferably a hydrogen atom, and more preferably both are a hydrogen atom.

In the formula (c1-L-1), n1 is preferably an integer of 0 or more and 7 or less, more preferably an integer of 2 or more and 5 or less, and still more preferably 2 or 3. In the formula (c1-L-2), n2 is preferably an integer of 0 or more and 5 or less, more preferably an integer of 0 or more and 3 or less, and still more preferably 0 or 1. In the formula (c1-L-3), n3 is preferably an integer of 0 or more and 5 or less, and more preferably an integer of 0 or more and 3 or less. In the formula (c1-L-4), n4 is preferably an integer of 0 or more and 5 or less, and more preferably an integer of 0 or more and 3 or less. In the formula (c1-L-5), n5 is preferably an integer of 0 or more and 8 or less. In the formula (c1-L-6), n6 is preferably an integer of 0 or more and 6 or less. In the formula (c1-L-7), n7 is preferably an integer of 0 or more and 8 or less.

Specific preferable examples of L¹ to L⁸ are shown below. * represents a bonding site to Si. ** represents a bonding site to any one of R¹ to R⁸. Among them, a group represented by (c1-L1-1) or (c1-L1-3) is preferable.

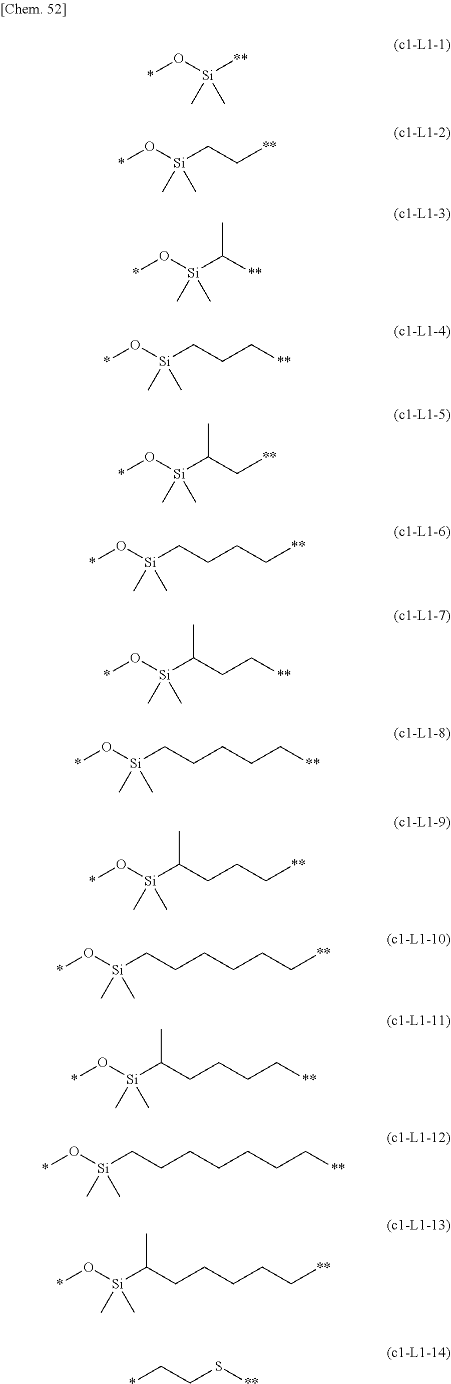

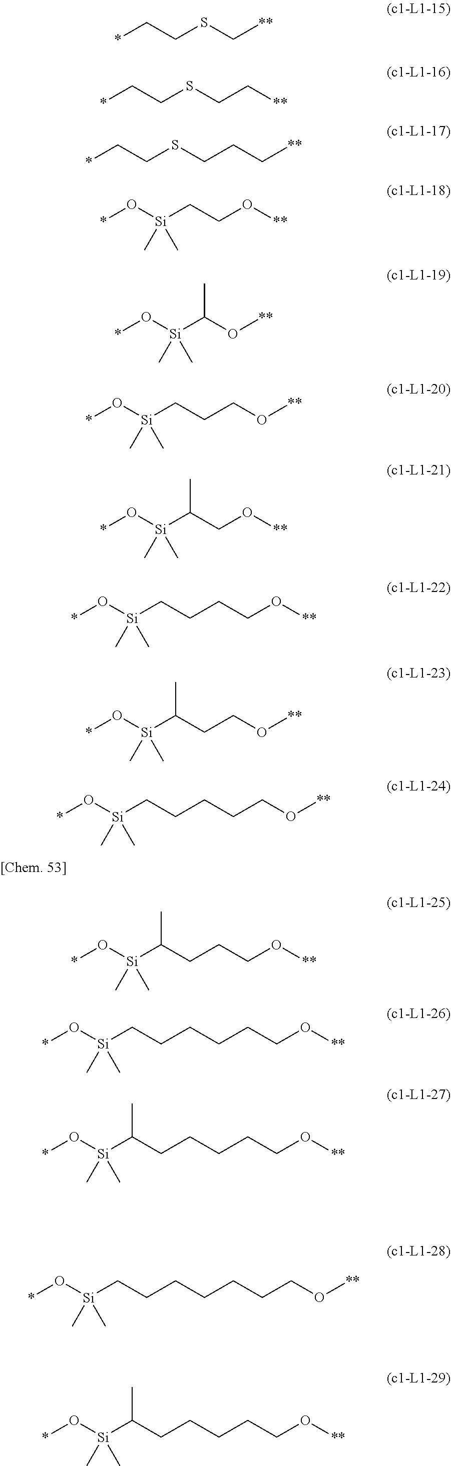

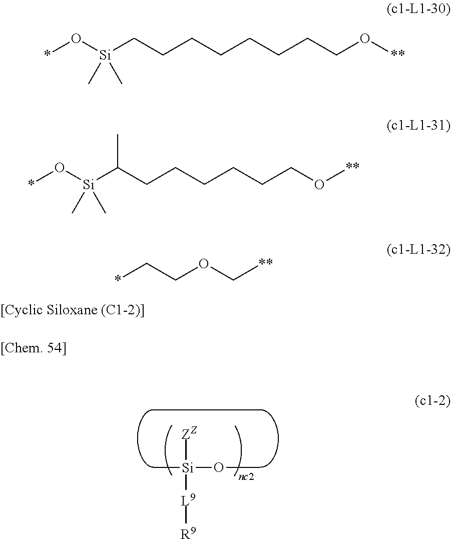

(In the formula (c1-2), R⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R⁹ represents an aromatic group having a methylol group or an alkoxymethyl group, or a nitrogen atom-containing group having a methylol group or an alkoxymethyl group. L⁹ each independently represent a divalent linking group represented by any one of the following formulas (c2-L-1) to (c2-L-6). nc2 represents an integer of 3 or more and 7 or less. Z^{Z} each independently represent a hydrocarbon group having 1 or more and 6 or less carbon atoms or a hydrogen atom.

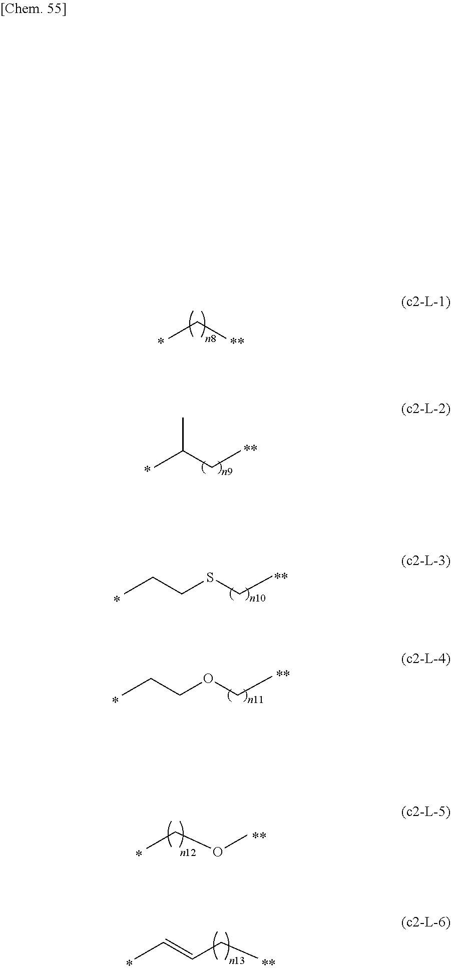

(In the formulas (c2-L-1) to (c2-L-6), n8 to n13 each independently represent an integer of 0 or more and 10 or less. * represents a bonding site to Si. ** represents a bonding site to R⁹.)

nc2 is preferably an integer of 3 or more and 5 or less, and more preferably 4.

R⁹ is preferably an aromatic group having a methylol group or an alkoxymethyl group, a nitrogen atom-containing group having a methylol group or an alkoxymethyl group, or an aromatic group having a phenolic hydroxy group, more preferably an aromatic group having a methylol group or an alkoxymethyl group, or an aromatic group having a phenolic hydroxy group, and still more preferably an aromatic group having a methylol group or an alkoxymethyl group.

At least another one of R⁹ may be an aromatic group having a phenolic hydroxy group.

Among R⁹, the number of aromatic groups having a methylol group or an alkoxymethyl group is preferably 1 or more, more preferably 3 or more, and still more preferably 4 or more. The number of aromatic groups having a methylol group or an alkoxymethyl group may be, for example, 7 or less, 5 or less, 3 or less, or 1 or less. Among R⁹, the number of nitrogen atom-containing groups having a methylol group or an alkoxymethyl group is preferably 1 or more, more preferably 3 or more, and still more preferably 4 or more. The number of aromatic groups having a methylol group or an alkoxymethyl group may be, for example, 7 or less, 5 or less, 3 or less, or 1 or less. Among R⁹, the total number of the aromatic group having a methylol group or an alkoxymethyl group and the nitrogen atom-containing group having a methylol group or an alkoxymethyl group is preferably 2 or more, and more preferably 4 or more. The total number may be, for example, 7 or less, 5 or less, 3 or less, or 1. Among R⁹, the number of aromatic groups having a phenolic hydroxy group may be, for example, 1 or more, 3 or more, and 6 or less, 4 or less, 2 or less, or 1 or less.

The aromatic group having a methylol group or an alkoxymethyl group, the nitrogen atom-containing group having a methylol group or an alkoxymethyl group, the aromatic group having a phenolic hydroxy group, and the hydrocarbon group having 1 or more and 10 or less carbon atoms for R⁹ are the same as those for R¹ to R⁸.

In the formula (c2-L-1), n8 is preferably an integer of 0 or more and 7 or less, more preferably an integer of 2 or more and 5 or less, and still more preferably 2 or 3. In the formula (c2-L-2), n9 is preferably an integer of 0 or more and 5 or less, more preferably an integer of 0 or more and 3 or less, and still more preferably 0 or 1. In the formula (c2-L-3), n10 is preferably an integer of 0 or more and 5 or less, and more preferably an integer of 0 or more and 3 or less. In the formula (c2-L-4), n11 is preferably an integer of 0 or more and 5 or less, and more preferably an integer of 0 or more and 3 or less. In the formula (c2-L-5), n12 is preferably an integer of 0 or more and 5 or less, and more preferably an integer of 2 or more and 5 or less. In the formula (c2-L-6), n13 is preferably an integer of 0 or more and 5 or less, and more preferably an integer of 0 or more and 3 or less.

Specific preferable examples of L⁹ are shown below. * represents a bonding site to Si. ** represents a bonding site to R⁹. Among them, a group represented by (c2-L1-1) or (c2-L1-2) is preferable.

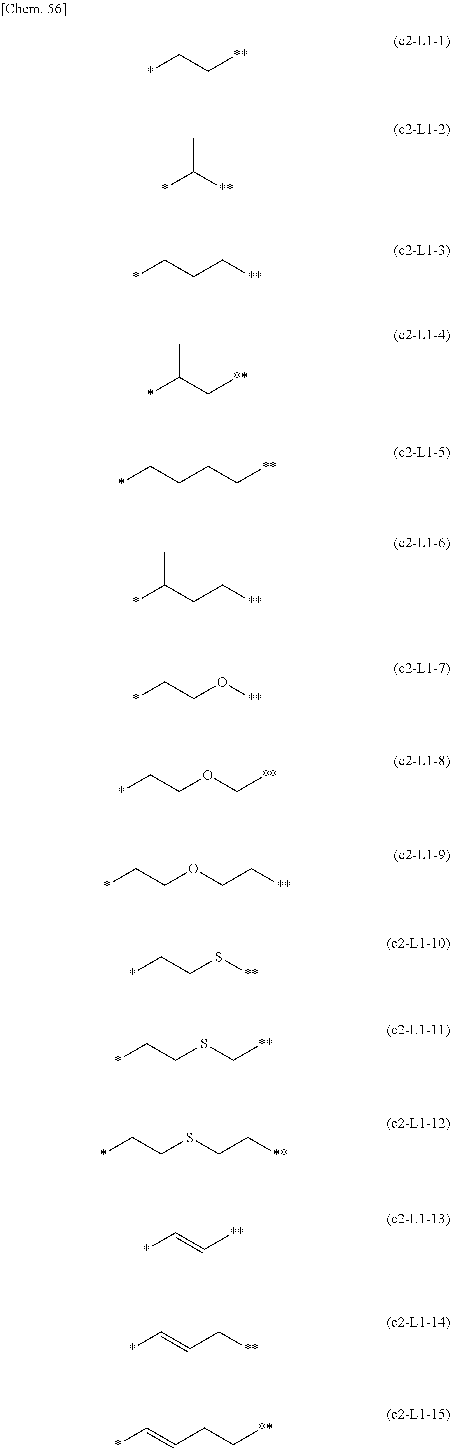

Z^{Z} is preferably a hydrocarbon group having 1 or more and 6 or less carbon atoms, more preferably a hydrocarbon group having 1 or more and 3 or less carbon atoms, and still more preferably a methyl group.

The weight average molecular weight (Mw) (polystyrene conversion reference by gel permeation chromatography (GPC)) of the component (C1) is not particularly limited, and is preferably 300 or more and 5000 or less, more preferably 400 or more and 3000 or less, and still more preferably 500 or more and 2000 or less. When the Mw of the component (C1) is equal to or less than the preferable upper limit value of this range, sufficient solubility in a solvent is obtained, and when the Mw of the component (C1) is equal to or more than the preferable lower limit value of this range, dry etching resistance is enhanced, and a cross-sectional shape of a resist pattern is good. The dispersity (Mw/Mn) of the component (C1) is not particularly limited, and is preferably 1.00 or more and 1.40 or less, more preferably 1.00 or more and 1.30 or less, and still more preferably 1.00 or more and 1.20 or less. Note that Mn represents a number average molecular weight.

The content of the component (C1) is preferably less than 5 mass %, more preferably 2 mass % or less, still more preferably 1 mass % or less, particularly preferably 0.01 mass % or more and 1 mass % or less, and most preferably 0.01 mass % or more and 0.5 mass % or less with respect to the total mass of the first film-forming composition. In the first film-forming composition, the content of the component (C1) is preferably 1 part by mass or more and 50 parts by mass or less, more preferably 3 parts by mass or more and 30 parts by mass or less, still more preferably 5 parts by mass or more and 20 parts by mass or less, and particularly preferably 5 parts by mass or more and 15 parts by mass or less with respect to 100 parts by mass of the component (A). When the content of the component (C1) is within the above preferable range, it is effective in reducing the film thickness in pattern formation.

The component (C1) can be produced using a known production method. For example, the cage-type silsesquioxane represented by the formula (c1-1) can be produced by causing a reaction of the following raw material (X) and the following raw material (Y) and appropriately performing a deprotection reaction as in Synthesis Examples (1) to (4) described below.

Raw material (X): octasilsesquioxane having a cage-type structure in which a functional group capable of reacting with the raw material (Y) is bonded to silicon (Si) at each vertex. Examples of the functional group capable of reacting with the raw material (Y) include a dimethylsilyloxy group and a vinyl group.

Raw material (Y): a raw material having an “ionic group decomposable upon exposure to light to generate an acid” or a part thereof. Examples of the raw material include (4-vinylphenyl)methanol, (4-allylphenyl)methanol, and 1-ethenyl-4-(methoxymethyl)benzene.

### [Base Component (D)]

The film-forming composition contains the base component (D) (hereafter, also referred to as “component (D)”) which controls diffusion of the acid generated upon exposure to light. The component (D) acts as a quencher (acid diffusion control agent) which traps an acid generated in the film-forming composition upon exposure to light. Accordingly, a fine pattern having an excellent shape is easily formed particularly as a “negative resist composition for an alkaline development process”. Examples of the component (D) include a photodegradable base (D0) (hereafter, referred to as a “component (D0)”) that is decomposable upon exposure to light and loses acid diffusion controllability, and a nitrogen-containing organic compound (D2) (hereafter, referred to as a “component (D2)”) which does not fall under the category of the component (D0). Among them, a photodegradable base (component (D0)) is preferable because it is easy to improve all of the properties of increasing the sensitivity, reducing the roughness, and preventing the occurrence of coating defects.

### ⋅Regarding Photodegradable Base (Component (D0))

The component (D0) is not particularly limited as long as it is a base that is decomposable upon exposure to light and loses acid diffusion controllability, and preferably contains at least one onium salt selected from the group consisting of a compound represented by the following formula (d0-1) (hereinafter, also referred to as a “component (d0-1)”) and a compound represented by the formula (d0-2) (hereinafter, also referred to as a “component (d0-2)”). The components (d0-1) and (d0-2) are decomposed and lose the acid diffusion controllability (basicity) at exposed portions of the resist film, so that the components (d0-1) and (d0-2) do not act as a quencher, whereas the components (d0-1) and (d0-2) act as a quencher at unexposed portions of the resist film.

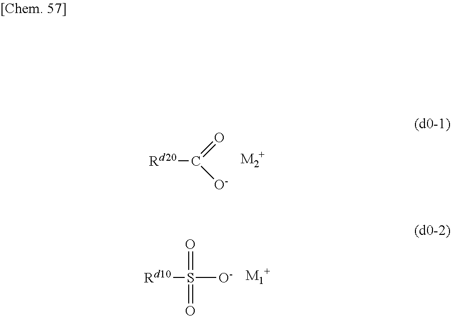

(In the formula (d0-1), R^{d20} represents an organic group having 1 or more and 40 or less carbon atoms. M₂⁺ represents an onium cation. In the formula (d0-2), R^{d10} represents an organic group having 1 or more and 40 or less carbon atoms. M₁⁺ represents an onium cation.)
⋅⋅Regarding Component (d0-1)

In the formula (d0-1), examples of the organic group having 1 or more and 40 or less carbon atoms for R^{d20} include a hydrocarbon group which may have a substituent, a divalent linking group containing an oxygen atom, and a combination thereof. The onium salt is preferably a carboxylate represented by the following formula (d0-1d).

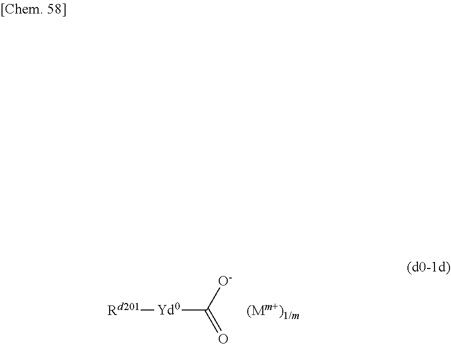

(In the formula, R^{d201} represents a cyclic group which may have a substituent, a chain-like alkyl group which may have a substituent, or a chain-like alkenyl group which may have a substituent. Yd⁰ represents a divalent linking group or a single bond. M^{m+} represents an m-valent onium cation. m represents an integer of 1 or more.)

R^{d201} represents a cyclic group which may have a substituent, a chain-like alkyl group which may have a substituent, or a chain-like alkenyl group which may have a substituent, and examples thereof include the same groups as those exemplified in the description of R^{b101} in the formula (b0-1b). Among them, R^{d201} is preferably a cyclic group having a hydroxy group, a cyclic group having an iodine atom, or a cyclic group having a bromine atom, more preferably an aromatic hydrocarbon group having a hydroxy group, and still more preferably a phenyl group having a hydroxy group or a naphthyl group having a hydroxy group.

In the formula (d0-1d), preferable examples of the divalent linking group for Yd⁰ include a divalent linking group containing an oxygen atom. When Yd⁰ represents a divalent linking group containing an oxygen atom, Yd⁰ may contain an atom other than an oxygen atom. Examples of the atom other than an oxygen atom include a carbon atom, a hydrogen atom, a sulfur atom, and a nitrogen atom. Examples of the divalent linking group containing an oxygen atom include: a non-hydrocarbon-based oxygen atom-containing linking group such as an oxygen atom (ether bond: —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); a combination of the non-hydrocarbon-based oxygen atom-containing linking group and an alkylene group; and a combination of the non-hydrocarbon-based oxygen atom-containing linking group and an arylene group. A sulfonyl group (—SO₂—) may be further linked to this combination. Examples of the above arylene group include a phenylene group and a naphthylene group. The above arylene group may have a substituent such as a halogen atom. Among them, Yd⁰ is preferably a single bond, a combination of the non-hydrocarbon-based oxygen atom-containing linking group and an alkylene group, or a combination of the non-hydrocarbon-based oxygen atom-containing linking group and an arylene group, and more preferably a single bond.

Specific preferable examples of the anion moiety of the carboxylate represented by the formula (d0-1d) are shown below.

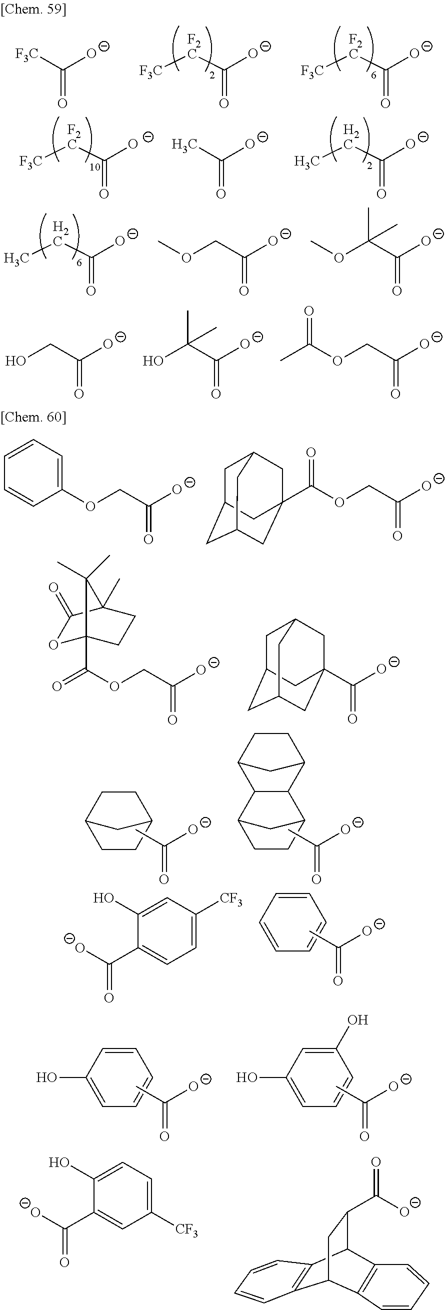

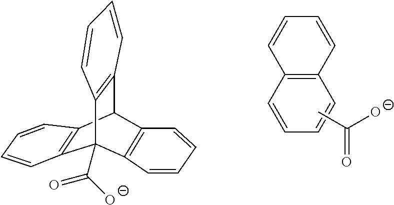

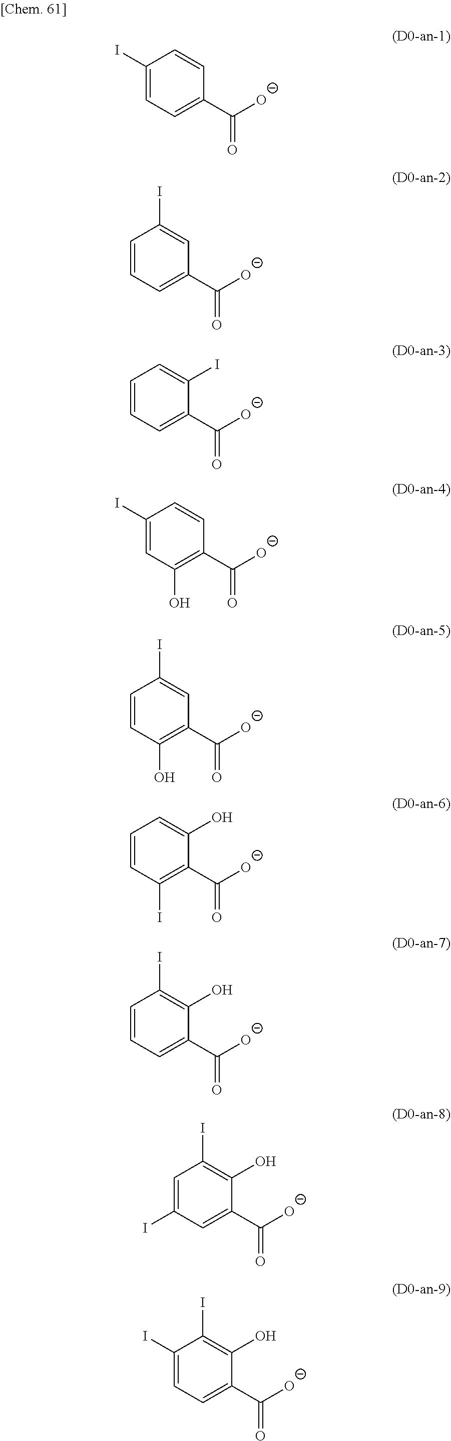

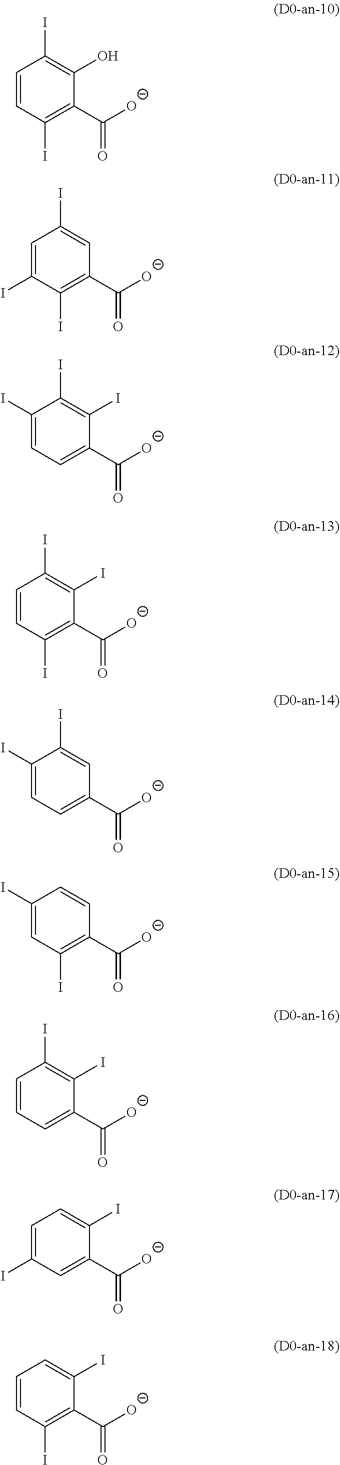

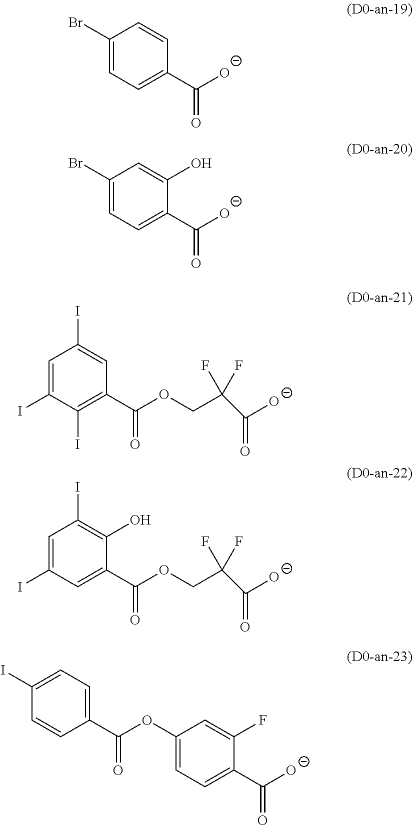 [SMILES: O=C([O-])c1ccc(Br)cc1 ; O=C([O-])c1ccc(Br)cc1O ; O=C(OCC(F)(F)C(=O)[O-])c1cc(I)cc(I)c1I ; O=C(OCC(F)(F)C(=O)[O-])c1cc(I)cc(I)c1O ; O=C(Oc1ccc(C(=O)[O-])c(F)c1)c1ccc(I)cc1]

M₂⁺ represents an onium cation, and among them, a sulfonium cation or an iodonium cation is preferable. Preferable examples of M₂⁺ include the same cations as those represented by the formulas (ca-1) to (ca-3), and M₂⁺ is more preferably a cation represented by the formula (ca-1), and still more preferably cations respectively represented by the formulas (ca-1-1) to (ca-1-84). Among them, a cation represented by the formula (b0-ca) is particularly preferable. One kind of the component (d0-1) may be used alone, or two or more kinds thereof may be used in combination.

⋅⋅Regarding Component (d0-2)

Examples of the organic group having 1 or more and 40 or less carbon atoms for R^{d10} include a hydrocarbon group which may have a substituent, a divalent linking group containing an oxygen atom, and a combination thereof. Examples of the organic group for R^{d10} include a cyclic group which may have a substituent, a chain-like alkyl group which may have a substituent, or a chain-like alkenyl group which may have a substituent, and the same groups as those exemplified in the description of R^{b101} in the formula (b0-1b) can be mentioned. Among them, R^{d10} is preferably a chain-like alkyl group having an iodine atom or an aliphatic cyclic group having an iodine atom. The number of carbon atoms in the chain-like alkyl group is preferably 1 or more and 10 or less, and more preferably 3 or more and 10 or less. The aliphatic cyclic group is more preferably a group obtained by removing one or more hydrogen atoms from adamantane, norbornane, isobornane, tricyclodecane, tetracyclododecane, or the like (which may have a substituent) or a group obtained by removing one or more hydrogen atoms from camphor or the like. A fluorine atom is not bonded to the carbon atom adjacent to the S atom in R^{d10} (not substituted with fluorine). Accordingly, the anion moiety of the sulfonate represented by the general formula (d0-2) becomes an appropriately weak acid anion, and the quenching ability is improved.

The hydrocarbon group for R^{d10} may have a substituent, and examples of the substituent include the same groups as the substituents which may be contained in the hydrocarbon group (an aromatic hydrocarbon group, an aliphatic cyclic group, a chain-like alkyl group, or a chain-like alkenyl group) for R^{b101} in the formula (b0-1b).

Specific preferable examples of the anion moiety of the sulfonate represented by the formula (d0-2) are shown below.

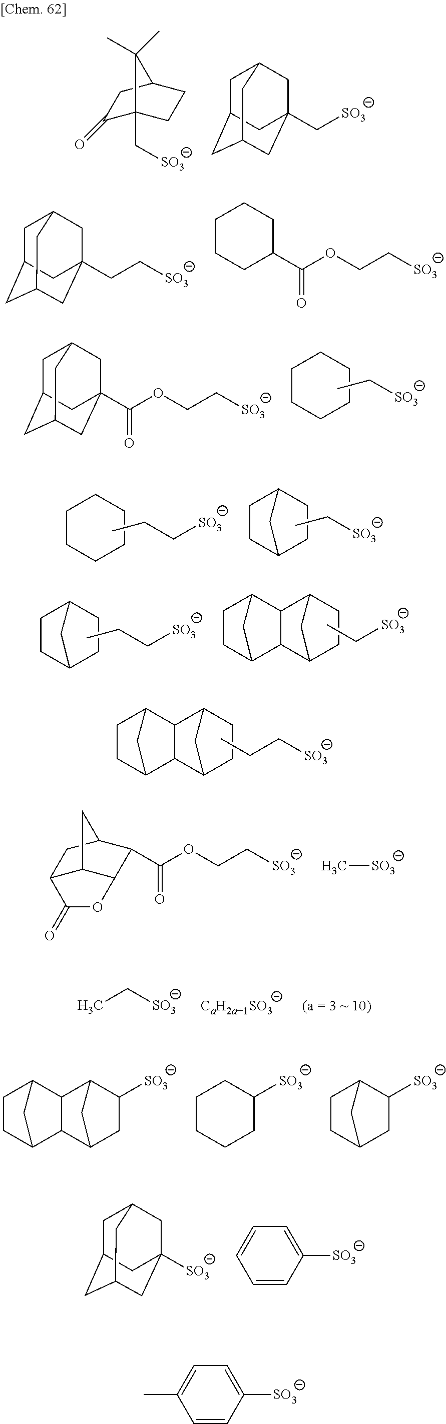

M₁⁺ is preferably a sulfonium cation or an iodonium cation. Preferable examples of M₁⁺ include the same cations as those respectively represented by the formulas (ca-1) to (ca-3), and M₁⁺ is more preferably a cation represented by the formula (ca-1), and still more preferably cations respectively represented by the formulas (ca-1-1) to (ca-1-84). Among them, a cation represented by the formula (b0-ca) is particularly preferable. One kind of the component (d0-2) may be used alone, or two or more kinds thereof may be used in combination.

As the component (D0), only any one kind of the components (d0-1) and (d0-2) may be used, or two or more kinds thereof may be used in combination. When the first film-forming composition contains the component (D0), the content of the component (D0) is appropriately set according to the molar ratio with respect to the component (B), and is, for example, preferably 5 parts by mass or more and 60 parts by mass or less, more preferably 10 parts by mass or more and 50 parts by mass or less, and still more preferably 20 parts by mass or more and 45 parts by mass or less with respect to 100 parts by mass of the component (A).

The component (D0) preferably contains the component (d0-1). The content of the component (d0-1) in the entire component (D0) is preferably 50 mass % or more, more preferably 70 mass % or more, and still more preferably 90 mass % or more. The component (D0) may only contain the component (d0-1).

### ⋅Nitrogen-Containing Organic Compound (Component (D2))

The component (D) may contain the nitrogen-containing organic compound component (component (D2)) which does not fall under the category of the component (D0). The component (D2) is not particularly limited as long as it acts as an acid diffusion control agent and does not fall under the category of the component (D0), and any of the known compounds may be used. Among them, aliphatic amines are preferable, and secondary aliphatic amines and tertiary aliphatic amines are more preferable. The aliphatic amines are an amine having one or more aliphatic groups, and the aliphatic group preferably has 1 or more and 12 or less carbon atoms. Examples of the aliphatic amines include amines obtained by substituting at least one hydrogen atom of ammonia NH₃ with an alkyl group or a hydroxyalkyl group having 12 or less carbon atoms (i.e., alkylamines or alkylalcoholamines), and cyclic amines. Specific examples of alkylamines and alkylalcoholamines include: monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among them, trialkylamines having 6 or more and 30 or less carbon atoms are more preferable, and tri-n-pentylamine or tri-n-octylamine is particularly preferable.

Examples of the cyclic amine include heterocyclic compounds containing a nitrogen atom as a heteroatom. The heterocyclic compound may be a monocyclic amine (aliphatic monocyclic amine) or a polycyclic amine (aliphatic polycyclic amine). Specific examples of the aliphatic monocyclic amine include piperidine and piperazine. The aliphatic polycyclic amine preferably has 6 or more and 10 or less carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tr{2-(1-ethoxyethoxy)ethyl}amine, tris{2-(1-ethoxypropoxy)ethyl}amine, tris[2-{2-(2-hydroxyethoxy)ethoxy}ethyl]amine, triethanolamine triacetate, and triethanolamine triacetate is preferable.

Further, an aromatic amine may be used as the component (D2). Examples of the aromatic amine include 4-dimethylaminopyridine, pyrrole, indole, pyrazole, imidazole or derivatives thereof, tribenzylamine, 2,6-diisopropylaniline, N-tert-butoxycarbonylpyrrolidine, 2,6-di-tert-butylpyridine, and 2,6-di-tert-butylpyridine.

One kind of the component (D2) may be used alone, or two or more kinds thereof may be used in combination. When the film-forming composition contains the component (D2), the content of the component (D2) in the film-forming composition is generally within a range of 0.01 parts by mass or more and 5 parts by mass or less with respect to 100 parts by mass of the component (A). Within the above range, the resist pattern shape, and post exposure delay stability are improved.

### [Other Components]

The film-forming composition may further contain other components in addition to the component (A), the component (B), the component (C1), and the component (D) described above. As the other components, known components commonly blended in a film-forming composition using a silicon-containing compound as a base component can be used. Examples of such other components include another crosslinking agent (C3), organic carboxylic acids, fluorine additive components, and organic solvent components.

### (Another Crosslinking Agent (C3))

The film-forming composition may contain a crosslinking agent (C3) other than the component (C1) as the crosslinking agent (C). Examples of the component (C3) include melamine-based crosslinking agents, urea-based crosslinking agents, alkylene urea-based crosslinking agents, glycoluril-based crosslinking agents, phenol-based crosslinking agents, and epoxy-based crosslinking agents. In the following description, the term “lower” means that the number of carbon atoms is 1 or more and 5 or less.

Examples of melamine-based crosslinking agents include compounds obtained by causing a reaction of melamine and formaldehyde to substitute a hydrogen atom of an amino group with a hydroxymethyl group, and compounds obtained by causing a reaction of melamine, formaldehyde, and a lower alcohol to substitute a hydrogen atom of an amino group with a lower alkoxymethyl group. Specific examples thereof include hexamethoxymethylmelamine, hexaethoxymethylmelamine, hexapropoxymethylmelamine and hexabutoxybutylmelamine. Among them, hexamethoxymethylmelamine is preferable.

Examples of the urea-based crosslinking agents include compounds obtained by causing a reaction of urea and formaldehyde to substitute a hydrogen atom of an amino group with a hydroxymethyl group, and compounds obtained by causing a reaction of urea, formaldehyde, and a lower alcohol to substitute a hydrogen atom of an amino group with a lower alkoxymethyl group. Specific examples thereof include bismethoxymethylurea, bisethoxymethylurea, bispropoxymethylurea, and bisbutoxymethylurea. Among them, bismethoxymethylurea is preferable.

Examples of the alkylene urea-based crosslinking agents include a compound represented by the following formula (CA-1).

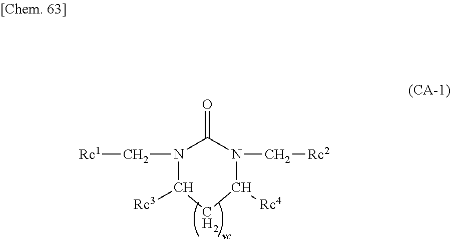

(In the formula (CA-1), Rc¹ and Rc² each independently represent a hydroxy group or a lower alkoxy group. Rc³ and Rc⁴ each independently represent a hydrogen atom, a hydroxy group, or a lower alkoxy group. vc represents an integer of 0 or more and 2 or less.)

When Rc¹ and Rc² are lower alkoxy groups, Rc¹ and Rc² are preferably alkoxy groups having 1 or more and 4 or less carbon atoms, and may be linear or branched. Rc¹ and Rc² may be the same as or different from each other, and are more preferably the same as each other. When Rc³ and Rc⁴ are lower alkoxy groups, Rc³ and Rc⁴ are preferably alkoxy groups having 1 or more and 4 or less carbon atoms, and may be linear or branched. Rc³ and Rc⁴ may be the same as or different from each other, and are more preferably the same as each other. vc is preferably 0 or 1. The alkylene urea-based crosslinking agent is particularly preferably a compound in which vc is 0 (ethylene urea-based crosslinking agent) and/or a compound in which vc is 1 (propylene urea-based crosslinking agent).

The compound represented by the formula (CA-1) can be obtained by subjecting alkylene urea and formalin to a condensation reaction, or by causing a reaction of this product and a lower alcohol.

Specific examples of the alkylene urea-based crosslinking agent include: ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl)-4,5-dihydroxy-2-imidazolidinone, and 1,3-di(methoxymethyl)-4,5-dimethoxy-2-imidazolidinone.

Examples of the glycoluril-based crosslinking agents include glycoluril derivatives obtained by substituting the N-position with one or both of a hydroxyalkyl group and an alkoxyalkyl group having 1 or more and 4 or less carbon atoms. The glycoluril derivative can be obtained by subjecting glycoluril and formalin to a condensation reaction, or by causing a reaction of this product and a lower alcohol. Specific examples of glycoluril-based crosslinking agents include mono-, di-, tri- and/or tetrahydroxymethylated glycoluril; mono-, di-, tri- and/or tetramethoxymethylated glycoluril; mono-, di-, tri- and/or tetraethoxymethylated glycoluril; mono-, di-, tri- and/or tetrapropoxymethylated glycoluril; and mono-, di-, tri- and/or tetrabutoxymethylated glycoluril.

The phenol-based crosslinking agent is not particularly limited as long as it is a compound having a plurality of phenol nucleus structures in the same molecule, and can be freely selected and used. The crosslinking reactivity is improved when a plurality of phenol nucleus structures are contained. The number of phenol nucleus structures is preferably 2 or more and 5 or less, more preferably 2 or more and 4 or less, and still more preferably 2 or 3.

Specific preferable examples of the glycoluril-based crosslinking agents or the phenol-based crosslinking agents are shown below.

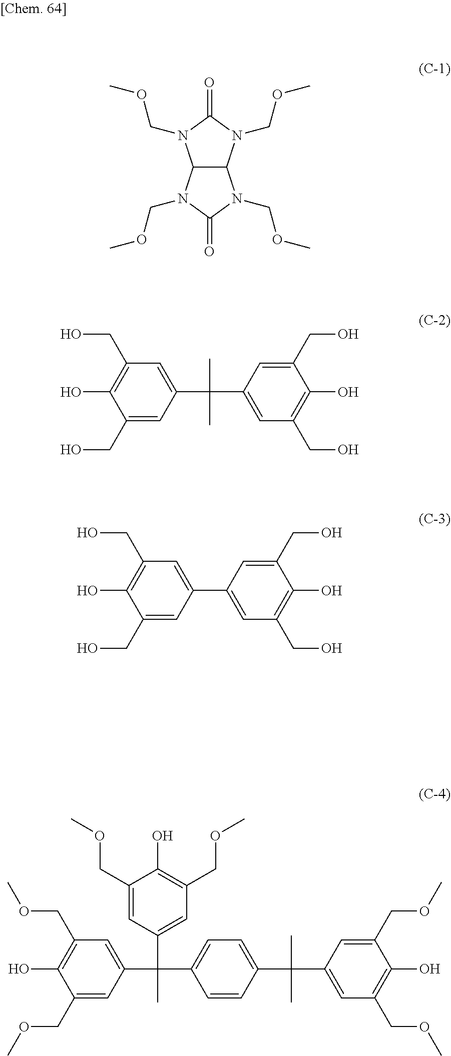

The epoxy-based crosslinking agent is not particularly limited as long as it is a crosslinking agent having an epoxy group, and can be freely selected and used. Among them, a crosslinking agent having two or more epoxy groups is preferable. The crosslinking reactivity is improved when two or more epoxy groups are contained. The number of epoxy groups is preferably 2 or more, more preferably 2 or more and 4 or less, and most preferably 2. Specific preferable examples of the epoxy-based crosslinking agent are shown below.

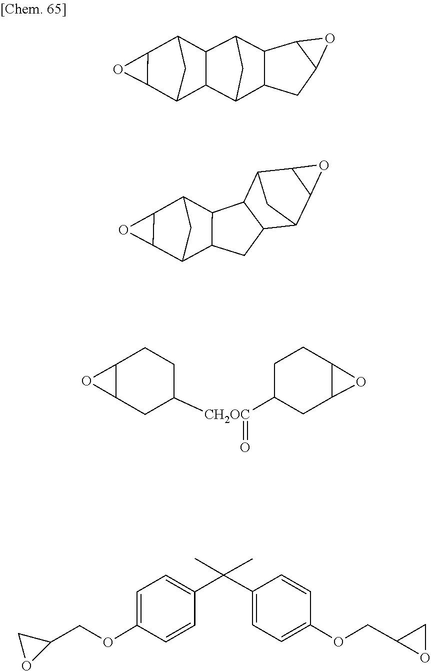

Among them, the component (C3) is preferably a compound having an alkylol group such as a methylol group or an alkoxyalkyl group such as a methoxymethyl group, more preferably a crosslinking agent selected from the group consisting of a glycoluril-based crosslinking agent and a phenol-based crosslinking agent, and still more preferably a glycoluril-based crosslinking agent.

(At Least One Compound (E) Selected from Group Consisting of Organic Carboxylic Acids, Phosphorus Oxoacids, and Derivatives Thereof)

In the film-forming composition, for the purpose of preventing any deterioration in sensitivity, and improving the resist pattern shape and the post coating delay stability and post exposure delay stability, at least one compound (E) (hereafter referred to as “component (E)”) selected from the group consisting of organic carboxylic acids, phosphorus oxoacids, and derivative thereof can be contained as an optional component. Specific examples of the organic carboxylic acids include acetic acid, malonic acid, citric acid, malic acid, succinic acid, benzoic acid, and salicylic acid, and among them, salicylic acid is preferable. Examples of the phosphorus oxoacids include phosphoric acid, phosphonic acid, and phosphinic acid, and among them, phosphonic acid is particularly preferable.

One kind of the component (E) may be used alone, or two or more kinds thereof may be used in combination. When the first film-forming composition contains the component (E), the content of the component (E) is preferably 0.1 parts by mass or more and 10 parts by mass or less, and more preferably 1 part by mass or more and 5 parts by mass or less with respect to 100 parts by mass of the component (A). Within the above range, the temporal stability of the film-forming composition is improved.

### (Fluorine Additive Component (F))

The film-forming composition may contain a fluorine additive component (hereinafter, referred to as “component (F)”) as a hydrophobic resin. The component (F) is used for imparting water repellency to the resist film, and when the component (F) is used as a resin other than the component (A), lithography properties can be improved. As the component (F), for example, a fluorine-containing polymer compound described in Japanese Unexamined Patent Application, Publication No. 2010-002870, Japanese Unexamined Patent Application, Publication No. 2010-032994, Japanese Unexamined Patent Application, Publication No. 2010-277043, Japanese Unexamined Patent Application, Publication No. 2011-13569, or Japanese Unexamined Patent Application, Publication No. 2011-128226 can be used. More specific examples of the component (F) include polymers having a constitutional unit (f1) represented by the following formula (f1-1). The polymer is preferably a polymer (homopolymer) consisting of only a constitutional unit (f1) represented by the following formula (f1-1), a copolymer of the constitutional unit (f1) and a constitutional unit (a101) containing an acid decomposable group that exhibits increased polarity by an action of an acid, or a copolymer of the constitutional unit (f1), a constitutional unit derived from acrylic acid or methacrylic acid, and the constitutional unit (a101), and more preferably a copolymer of the constitutional unit (f1) and the constitutional unit (a101). Here, the constitutional unit (a101) copolymerized with the constitutional unit (f1) is preferably a constitutional unit derived from 1-ethyl-1-cyclooctyl(meth)acrylate or a constitutional unit derived from 1-methyl-1-adamantyl(meth)acrylate, and more preferably a constitutional unit derived from 1-ethyl-1-cyclooctyl(meth)acrylate.

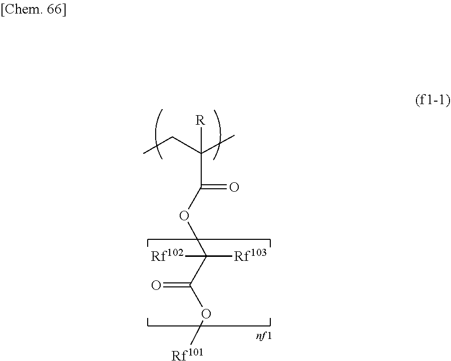

(In the formula, R is as defined above, Rf¹⁰² and Rf¹⁰³ each independently represent a hydrogen atom, a halogen atom, an alkyl group having 1 or more and 5 or less carbon atoms, or a halogenated alkyl group having 1 or more and 5 or less carbon atoms, and Rf¹⁰² and Rf¹⁰³ may be the same as or different from each other. nf¹ represents an integer of 0 or more and 5 or less, and Rf¹⁰¹ represents an organic group containing a fluorine atom.)

In the formula (f1-1), examples of R bonded to the carbon atom at the α-position include an alkyl group having 1 or more and 5 or less carbon atoms, a halogenated alkyl group having 1 or more and 5 or less carbon atoms, and a hydrogen atom. R is preferably a hydrogen atom or a methyl group. In the formula (f1-1), the halogen atom for Rf¹⁰² and Rf¹⁰³ is preferably a fluorine atom. The alkyl group having 1 or more and 5 or less carbon atoms for Rf¹⁰² and Rf¹⁰³ is preferably a methyl group or an ethyl group. Specific examples of the halogenated alkyl group having 1 or more and 5 or less carbon atoms for Rf¹⁰² and Rf¹⁰³ include groups obtained by substituting a portion or all of hydrogen atoms in an alkyl group having 1 or more and 5 or less carbon atoms with a halogen atom(s). The halogen atom is preferably a fluorine atom. Among them, Rf¹⁰² and Rf¹⁰³ are preferably a hydrogen atom, a fluorine atom, or an alkyl group having 1 or more and 5 or less carbon atoms, more preferably a hydrogen atom, a fluorine atom, a methyl group, or an ethyl group, and still more preferably a hydrogen atom. In the formula (f1-1), nf¹ represents an integer of 0 or more and 5 or less, and is preferably an integer of 0 or more and 3 or less, and more preferably 1 or 2.

In the formula (f1-1), Rf¹⁰¹ represents an organic group containing a fluorine atom, and is preferably a hydrocarbon group containing a fluorine atom. The hydrocarbon group containing a fluorine atom may be linear, branched, or cyclic, and the number of carbon atoms is preferably 1 or more and 20 or less, more preferably 1 or more and 15 or less, and particularly preferably 1 or more and 10 or less. In the hydrocarbon group containing a fluorine atom, preferably 25% or more of hydrogen atoms in the hydrocarbon group are fluorinated, more preferably 50% or more of the hydrogen atoms are fluorinated, and particularly preferably 60% or more of the hydrogen atoms are fluorinated in terms of enhancing the hydrophobicity of the resist film during immersion exposure. Among them, Rf¹⁰¹ is more preferably a fluorinated hydrocarbon group having 1 or more and 6 or less carbon atoms, and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight average molecular weight (Mw) (polystyrene conversion reference by gel permeation chromatography (GPC)) of the component (F) is preferably 1000 or more and 50000 or less, more preferably 5000 or more and 40000 or less, and most preferably 10000 or more and 30000 or less. When the weight average molecular weight (Mw) of the component (F) is equal to or less than the upper limit value of this range, sufficient solubility in resist solvents for use as a resist is obtained, and when the weight average molecular weight (Mw) of the component (F) is equal to or more than the lower limit value of this range, the water repellency of the resist film is good. The dispersity (Mw/Mn) of the component (F) is preferably 1.0 or more and 5.0 or less, more preferably 1.0 or more and 3.0 or less, and most preferably 1.0 or more and 2.5 or less.

One kind of the component (F) may be used alone, or two or more kinds thereof may be used in combination. When the first film-forming composition contains the component (F), the content of the component (F) is preferably 0.5 parts by mass or more and 10 parts by mass or less, and more preferably 1 part by mass or more and 10 parts by mass or less with respect to 100 parts by mass of the component (A).

### (Organic Solvent Component (S))

The film-forming composition can be produced by dissolving the resist materials in an organic solvent component (hereafter, referred to as “component (S)”). In the film-forming composition, one type of the component (S) may be used alone, or two or more types thereof may be used as a mixed solvent. Among them, propylene glycol monomethyl ether acetate (PGMEA), propylene glycol monomethyl ether, γ-butyrolactone, ethyl lactate (EL), and cyclohexanone are preferable.

The amount of the component (S) used is not particularly limited, and is appropriately set according to the thickness of a coating film at a concentration at which the component (S) can be applied to a substrate or the like. The solid content concentration of the film-forming composition is preferably within a range of 0.1 mass % or more and 10 mass % or less, more preferably 0.2 mass % or more and 5 mass % or less, and still more preferably 0.3 mass % or more and 2 mass % or less from the viewpoint of coatability on a substrate or the like.

### <Second Film-Forming Composition>

As described above, the second film-forming composition contains the photoacid generating agent (B), the silicon-containing crosslinking agent (C2), and the base component (D). The photoacid generating agent (B), the base component (D), and other components are the same as those of the first film-forming composition.

Hereinafter, the silicon-containing crosslinking agent (C2) in the second film-forming composition will be described.

### [Silicon-Containing Crosslinking Agent (C2)]

The second film-forming composition contains the silicon-containing crosslinking agent (C2) (hereinafter, also referred to as “component (C2)”) as the crosslinking agent (C). The silicon-containing crosslinking agent (C2) has a methylol group and/or an alkoxymethyl group, and a phenolic hydroxy group.

The component (C2) has a phenolic hydroxy group in addition to a methylol group and/or an alkoxymethyl group, and therefore, the component (C2) can exhibit the same action as the silicon-containing polymer (A).

The component (C2) is the same as the component (C1) except that the component (C2) has a phenolic hydroxy group in addition to a methylol group and/or an alkoxymethyl group.

The silicon-containing crosslinking agent (C2) preferably contains at least one selected from the group consisting of a cage-type silsesquioxane (C2-1) represented by the following formula (c2-1) and a cyclic siloxane (C2-2) represented by the following formula (c2-2).

### (Cage-Type Silsesquioxane (C2-1))

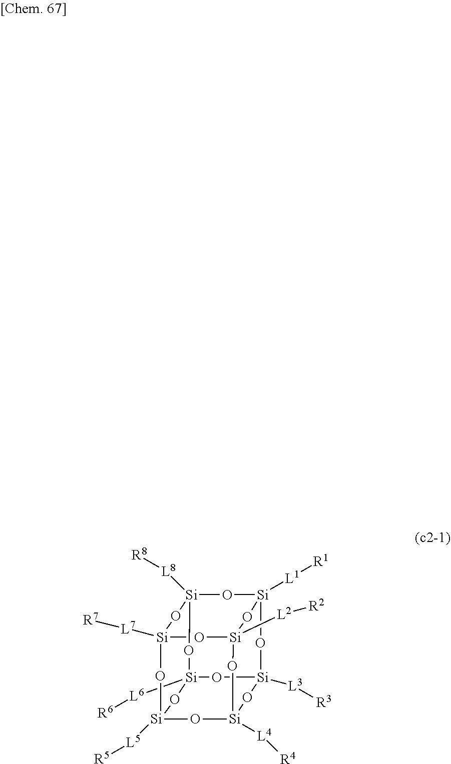

(In the formula (c2-1), R¹ to R⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R¹ to R⁸ represents an aromatic group having a methylol group or an alkoxymethyl group, or a nitrogen atom-containing group having a methylol group or an alkoxymethyl group, at least another one of R¹ to R⁸ represents an aromatic group having a phenolic hydroxy group. L¹ to L⁸ each independently represent a divalent linking group represented by any one of the formulas (c1-L-1) to (c1-L-7).)

### (Cyclic Siloxane (C2-2))

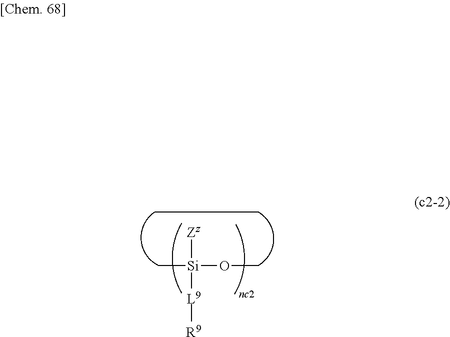

(In the formula (c2-2), R⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R⁹ represents an aromatic group having a methylol group or an alkoxymethyl group, or a nitrogen atom-containing group having a methylol group or an alkoxymethyl group, at least another one of R⁹ represents an aromatic group having a phenolic hydroxy group. L⁹ each independently represent a divalent linking group represented by any one of the above formulas (c2-L-1) to (c2-L-6). nc2 represents an integer of 3 or more and 7 or less. Z^{Z} each independently represent a hydrocarbon group having 1 or more and 6 or less carbon atoms or a hydrogen atom.)

The content of the silicon-containing crosslinking agent (C2) is preferably less than 5 mass %, more preferably 2 mass % or less, still more preferably 1 mass % or less, and particularly preferably 0.10 mass % or more and 1 mass % or less with respect to the total mass of the second film-forming composition. When the content of the silicon-containing crosslinking agent (C2) is within the above preferable range, it is effective in reducing the film thickness in pattern formation.

In the second film-forming composition, the content of the component (B) is preferably 1 part by mass or more and 60 parts by mass or less, more preferably 10 parts by mass or more and 50 parts by mass or less, still more preferably 15 parts by mass or more and 45 parts by mass or less, and particularly preferably 20 parts by mass or more and 40 parts by mass or less with respect to 100 parts by mass of the component (C2). When the content of the component (B) is equal to or more than the lower limit value of the above preferable range, lithography properties such as sensitivity, resolution performance, and line width roughness (LWR) reduction property are easily improved in the formation of a resist pattern. On the other hand, when the content is equal to or less than the upper limit value of the preferable range, a uniform solution is easily obtained when the components of the film-forming composition are dissolved in an organic solvent, and the storage stability as a composition is more easily enhanced.

When the second film-forming composition contains the component (D0), the content of the component (D0) is appropriately set according to the molar ratio with respect to the component (B), and is, for example, preferably 5 parts by mass or more and 70 parts by mass or less, more preferably 20 parts by mass or more and 60 parts by mass or less, and still more preferably 30 parts by mass or more and 50 parts by mass or less with respect to 100 parts by mass of the component (C2).

When the second film-forming composition contains the component (D2), the content of the component (D2) is generally within a range of 0.01 parts by mass or more and 5 parts by mass or less with respect to 100 parts by mass of the component (C2). Within the above range, the resist pattern shape, and the post coating delay stability and post exposure delay stability are improved.

When the second film-forming composition contains the component (E), the content of the component (E) is preferably 0.1 parts by mass or more and 10 parts by mass or less, and more preferably 1 part by mass or more and 5 parts by mass or less with respect to 100 parts by mass of the component (C2). Within the above range, the temporal stability of the film-forming composition is improved.

When the second film-forming composition contains the component (F), the content of the component (F) is preferably 0.5 parts by mass or more and 10 parts by mass or less, and more preferably 1 part by mass or more and 10 parts by mass or less with respect to 100 parts by mass of the component (C2).

### <Application of Film-Forming Composition>

The film-forming composition is suitable for applications in which a cured film is used, and can be used, for example, as a composition for a so-called resist mask, a composition for a hard mask, or a composition for forming a lower resist film formed between a support and a resist film during etching in the formation of a processed pattern in a semiconductor production process.

The film-forming composition is particularly useful in an alkaline development process using an alkaline developing solution in the developing treatment during formation of a resist pattern, and is suitable as a “negative resist composition for an alkaline development process” among them.

### <<Method for Producing Patterned Cured Film>>

A method for producing a patterned cured film includes forming a coating film made of a film-forming composition on a support (hereinafter, also referred to as a “coating film formation step”), position-selectively exposing the coating film (hereinafter, also referred to as an “exposure step”), and developing the exposed coating film to form a patterned cured film (hereinafter, also referred to as a “development step”).

### <Coating Film Formation Step>

First, a film-forming composition described above is applied to a support using a spinner or the like, and a bake (post apply bake (PAB)) treatment is conducted under a temperature condition of 80° C. or higher and 150° C. or lower for 40 seconds or longer and 120 seconds or shorter, preferably 60 seconds or longer and 90 seconds or shorter, to form a coating film (resist film).

### <Exposure Step>

Next, using an exposure apparatus such as an electron beam drawing apparatus or an extreme ultraviolet rays (EUV) exposure apparatus, the resist film is subjected to exposure through a mask on which a predetermined pattern is formed (mask pattern) or selective exposure based on drawing by direct irradiation with an electron beam without using a mask pattern. After the exposure, a bake (post exposure bake (PEB)) treatment is conducted under a temperature condition of 80° C. or higher and 150° C. or lower for 40 seconds or longer and 120 seconds or shorter, preferably 60 seconds or longer and 90 seconds or shorter.

### <Development Step>

Next, the resist film after the exposure is subjected to the developing treatment. The developing treatment is performed using an alkaline developing solution in the case of an alkaline development process, and using a developing solution containing an organic solvent (organic developing solution) in the case of a solvent development process.

After the developing treatment, a rinse treatment is preferably performed. For the rinse treatment, rinsing with pure water is preferable in the case of an alkaline development process, and a rinse solution containing an organic solvent is preferable in the case of a solvent development process. In the case of a solvent development process, after the developing treatment or the rinse treatment, the developing solution or the rinse solution remaining on the pattern may be removed by a treatment using a supercritical fluid. After the developing treatment or the rinse treatment, drying is performed. If desired, the bake treatment (post bake) may be conducted following the developing treatment.

The support is not particularly limited, and a commonly known support can be used. Examples of the support include a substrate for an electronic component and a support on which a predetermined wiring pattern is formed. More specific examples of the support include a silicon wafer, a substrate made of metal such as copper, chromium, iron, and aluminum, and a glass substrate. For example, copper, aluminum, nickel, and gold may be used as a material of the wiring pattern. In addition, the support may be a support in which an inorganic and/or organic film is provided on the above-described substrate. Examples of the inorganic film include an inorganic anti-reflective film (inorganic BARC). Examples of the organic film include an organic anti-reflective film (organic BARC) and an organic film such as a lower organic film in a multilayer resist method. Here, the multilayer resist method is a method in which at least one layer of an organic film (lower organic film) and at least one layer of a resist film (upper resist film) are provided on a substrate, and the lower organic film is patterned using a resist pattern formed on the upper resist film as a mask, and it is said that a pattern having a high aspect ratio can be formed. That is, according to the multilayer resist method, a required thickness can be ensured by the lower organic film, and therefore, the thickness of the resist film can be reduced, and a fine pattern having a high aspect ratio can be formed. The multilayer resist method is basically divided into a method for forming a two-layer structure of an upper resist film and a lower organic film (two-layer resist method) and a method for forming a multilayer structure of three or more layers in which one or more intermediate layers (thin metal film or the like) are provided between the upper resist film and the lower organic film (three-layer resist method).

The wavelength to be used for exposure is not particularly limited and the exposure can be performed using a radiation such as a ArF excimer laser, a KrF excimer laser, a F₂ excimer laser, extreme ultraviolet rays (EUV), vacuum ultraviolet (VUV), an electron beam (EB), an X-ray, and a soft X-ray. The method for forming a resist pattern according to the present embodiment is particularly useful for a method for exposing the resist film to the extreme ultraviolet rays (EUV) or the electron beam (EB) in the step of exposing the resist film.

The exposure method of the resist film may be a general exposure (dry lithography) performed in air or an inert gas such as nitrogen, or may be liquid immersion lithography. The liquid immersion lithography is an exposure method for performing exposure (immersion lithography) while a region between the resist film and a lens at a lowermost position of an exposure apparatus is pre-filled with a solvent (liquid immersion medium) having a refractive index larger than a refractive index of air. The liquid immersion medium is preferably a solvent that has a refractive index larger than the refractive index of air but smaller than a refractive index of the resist film to be exposed. The refractive index of such a solvent is not particularly limited as long as it falls within the above range. Examples of the solvent having a refractive index that is larger than the refractive index of air but smaller than the refractive index of the resist film include water, fluorine-based inert liquids, silicon-based solvents, and hydrocarbon-based solvents. Specific examples of the fluorine-based inert liquids include liquids containing a fluorine-based compound such as C₃HCl₂F₅, C₄F₉OCH₃, C₄F₉OC₂H₅, and C₅H₃F₇ as a main component. A liquid having a boiling point of 70° C. or higher and 180° C. or lower is preferable, and a liquid having a boiling point of 80° C. or higher and 160° C. or lower is more preferable. A fluorine-based inert liquid having a boiling point within the above range is preferable in that the removal of the medium used for liquid immersion after the exposure is ended can be performed by a simple method. The fluorine-based inert liquid is particularly preferably a perfluoroalkyl compound obtained by substituting all hydrogen atoms of an alkyl group with fluorine atoms. Specific examples of the perfluoroalkyl compound include perfluoroalkylether compounds and perfluoroalkylamine compounds. Specific examples of the perfluoroalkylether compounds include perfluoro(2-butyl-tetrahydrofuran) (boiling point: 102° C.), and examples of the perfluoroalkylamine compounds include perfluorotributylamine (boiling point: 174° C.). The liquid immersion medium is preferably water from the viewpoint of cost, safety, environment, and versatility.

Examples of the alkaline developing solution used for the developing treatment in an alkaline development process include an aqueous solution of tetramethylammonium hydroxide (TMAH) of 0.1 mass % to 10 mass %.

The organic solvent contained in the organic developing solution used for the developing treatment in the solvent development process can be appropriately selected from known organic solvents as long as it is an organic solvent capable of dissolving the component (A) (the component (A) prior to exposure). Specific examples thereof include polar solvents such as a ketone-based solvent, an ester-based solvent, an alcohol-based solvent, a nitrile-based solvent, an amide-based solvent, and an ether-based solvent, and a hydrocarbon-based solvent. The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxy group in the structure thereof. The term “alcoholic hydroxy group” refers to a hydroxy group bonded to a carbon atom in an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof. In the organic solvent, there is also an organic solvent containing a plurality kinds of functional groups characterizing each of the above solvents in the structure, and in that case, the organic solvent falls under the category of any type of solvent containing the functional group contained in the organic solvent. For example, diethylene glycol monomethyl ether falls under the category of both an alcohol-based solvent and an ether-based solvent in the above classification. The hydrocarbon-based solvent is a hydrocarbon solvent containing a hydrocarbon which may be halogenated, and not having a substituent other than a halogen atom. The halogen atom is preferably a fluorine atom. Among them, the organic solvent contained in the organic developing solution is preferably a polar solvent, and preferably a ketone-based solvent, an ester-based solvent, and a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, γ-butyrolactone, and methyl amyl ketone (2-heptanone). Among them, the ketone-based solvent is preferably methyl amyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among them, the ester-based solvent is preferably butyl acetate.

Examples of the nitrile-based solvent include acetonitrile, propionitrile, valeronitrile, and butyronitrile.

A known additive may be blended in the organic developing solution as necessary. Examples of the additive include a surfactant. The surfactant is not particularly limited, and for example, an ionic or nonionic fluorine-based and/or silicon-based surfactant can be used.

The developing treatment can be performed by a known developing method, and examples thereof include a method of immersing a support in a developing solution for a certain period of time (dipping method), a method of piling up a developing solution on a surface of a support by surface tension and standing still for a certain period of time (puddle method), a method of spraying a developing solution on a surface of a support (spray method), and a method of continuously applying a developing solution onto a support rotating at a constant speed while scanning a developing solution application nozzle at a constant speed (dynamic dispensing method).

As the organic solvent contained in the rinse solution used for the rinse treatment after the developing treatment in the solvent development process, for example, among the organic solvents listed as organic solvents used in the above organic developing solution, an organic solvent in which the resist pattern is hardly dissolved can be appropriately selected and used. In general, at least one type of solvent selected from the group consisting of hydrocarbon-based solvents, ketone-based solvents, ester-based solvents, alcohol-based solvents, amide-based solvents, and ether-based solvents is used. One kind of these organic solvents may be used alone, or two or more kinds thereof may be used in combination. Further, an organic solvent other than those described above or water may be used in combination.

The rinse treatment using a rinse solution (washing treatment) can be conducted by a known rinse method. Examples of the rinse treatment method include a method of continuously applying a rinse liquid onto a support while rotating the support at a constant rate (rotational coating method), a method of immersing a support in a rinse solution for a certain period of time (dipping method), and a method of spraying a rinse liquid onto a surface of a support (spray method).

According to the method for forming a resist pattern in the present embodiment described above, the film-forming composition described above is used, and therefore, even if the composition contains a silicon-containing compound as a base component, a pattern having small dimensions can be formed in which both etching resistance and lithography properties such as a pattern roughness reduction effect are achieved. For example, even in the lithography using EUV, the film-forming composition described above can have excellent fine resolution and sufficient etching resistance, and can form a fine pattern of ten and several nanometers in a good shape. In the case of a line and space pattern (LS pattern), the roughness of a line side wall is small, and an LS pattern having a more uniform width can be easily formed. In particular, the method for forming a resist pattern according to the present embodiment is a method useful for forming a negative resist pattern by developing the exposed resist film with alkali in the step (iii).

It is preferable that the film-forming composition in the embodiment described above and various materials used in the resist pattern-forming method in the embodiment described above (for example, a resist solvent, a developing solution, a rinse solution, an anti-reflective film-forming composition, and a topcoat-forming composition) do not contain impurities such as a metal, a metal salt containing halogen, an acid, an alkali, a component containing a sulfur atom or a phosphorus atom. Here, examples of the impurity containing a metal atom include Na, K, Ca, Fe, Cu, Mn, Mg, Al, Cr, Ni, Zn, Ag, Sn, Pb, Li, and salts thereof. The content of impurities contained in these materials is preferably 200 ppb or less, more preferably 1 ppb or less, still more preferably 100 parts per trillion (ppt) or less, particularly preferably 10 ppt or less, and is most preferably substantially zero (equal to or less than a detection limit of a measurement device).

### <<Cage-Type Silsesquioxane>>

The cage-type silsesquioxane is represented by the following formula (c0-1).

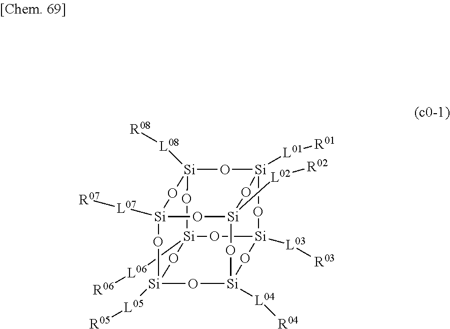

(In the formula (c0-1), R⁰¹ to R⁰⁸ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R⁰¹ to R⁰⁸ represents an aromatic group having a methylol group or an alkoxymethyl group, or a nitrogen atom-containing group having a methylol group or an alkoxymethyl group. L⁰¹ to L⁰⁸ each independently represent a divalent linking group represented by any one of the following formulas (c0-L-1) to (c0-L-3) and (c0-L-5) to (c0-L-7).)

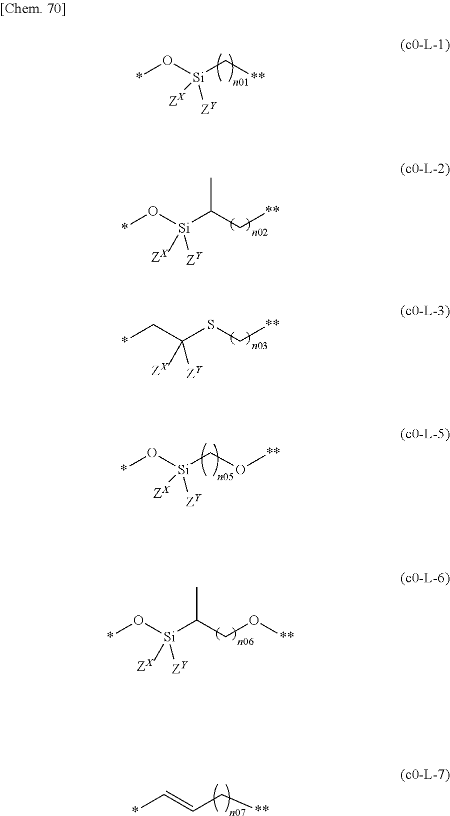

(In the formulas (c0-L-1) to (c0-L-3) and (c0-L-5) to (c0-L-7), Z^{X} and Z^{Y} each independently represent a hydrocarbon group having 1 to 6 carbon atoms or a hydrogen atom. n01 represents an integer of 0 or more. n02 represents an integer of 0 or more. n03 represents an integer of 0 or more. n05 represents an integer of 0 or more. n06 represents an integer of 0 or more. n07 represents an integer of 0 or more. When all R⁰¹ to R⁰⁸ represent an aromatic group having a methylol group, n01 represents an integer of 3 or more, and n02 represents an integer of 1 or more. * represents a bonding site to Si. ** represents a bonding site to any one of R⁰¹ to R⁰⁸.)

Preferable aspects of R⁰¹ to R⁰⁸ are the same as those of R⁰¹ to R⁰⁸ in formula (c1-1).

Preferable aspects of Z^{X} and Z in the formulas (c0-L-1) to (c0-L-3) and (c0-L-5) to (c0-L-7) are the same as those of Z^{X} and Z^{Y} in the formulas (c1-L-1) to (c1-L-3) and (c1-L-5) to (c1-L-7).

In the formula (c0-L-1), n01 is preferably an integer of 2 or more, more preferably an integer of 2 or more and 10 or less, still more preferably an integer of 2 or more and 7 or less, particularly preferably an integer of 2 or more and 5 or less, and most preferably 2 or 3. When all R⁰¹ to R⁰⁸ represent an aromatic group having a methylol group, n01 is preferably an integer of 3 or more and 10 or less, more preferably an integer of 3 or more and 7 or less, still more preferably an integer of 3 or more and 5 or less, and particularly preferably 3. In the formula (c0-L-2), n02 is preferably an integer of 0 or more and 10 or less, more preferably an integer of 0 or more and 5 or less, still more preferably an integer of 0 or more and 3 or less, and particularly preferably 0 or 1. When all R⁰¹ to R⁰⁸ represent an aromatic group having a methylol group, n02 is preferably an integer of 1 or more and 10 or less, more preferably an integer of 1 or more and 5 or less, still more preferably an integer of 1 or more and 3 or less, and particularly preferably 1. In the formula (c1-L-3), n3 is preferably an integer of 0 or more and 10 or less, more preferably an integer of 0 or more and 5 or less, and still more preferably an integer of 0 or more and 3 or less. In the formula (c0-L-5), n05 is preferably an integer of 2 or more, more preferably an integer of 2 or more and 10 or less, and still more preferably an integer of 2 or more and 8 or less. In the formula (c0-L-6), n06 is preferably an integer of 0 or more and 10 or less, and more preferably an integer of 0 or more and 6 or less. In the formula (c0-L-7), n07 is preferably an integer of 0 or more and 10 or less, and more preferably an integer of 0 or more and 8 or less.

### <<Cyclic Siloxane>>

The cyclic siloxane is represented by the following formula (c0-2).

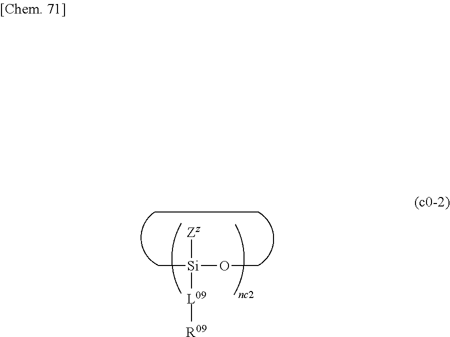

(In the formula (c0-2), R⁰⁹ each independently represent an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom. At least one of R⁰⁹ represents an aromatic group having a methylol group or an alkoxymethyl group, or a nitrogen atom-containing group having a methylol group or an alkoxymethyl group. L⁰⁹ each independently represent a divalent linking group represented by any one of the following formulas (c0-L-8) to (c0-L-10), (c0-L-12), and (c0-L-13). nc2 represents an integer of 3 or more and 7 or less. Z^{Z} each independently represent a hydrocarbon group having 1 or more and 6 or less carbon atoms or a hydrogen atom.)

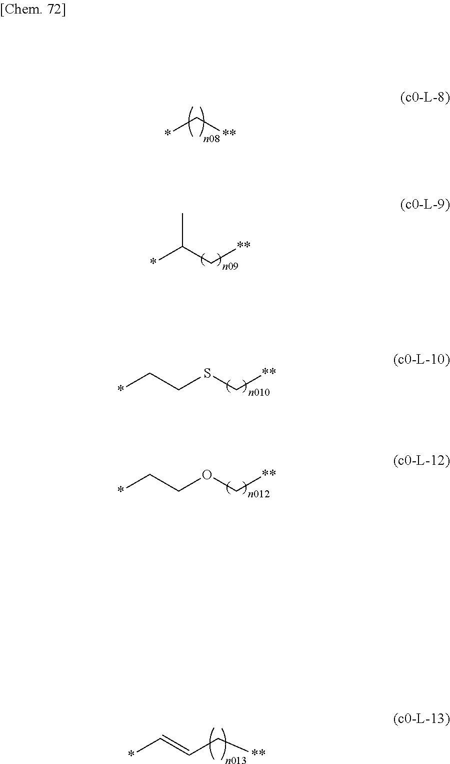

(In the formulas (c0-L-8) to (c0-L-12), n08 represents an integer of 0 or more. n09 represents an integer of 0 or more. n010 represents an integer of 0 or more. n012 represents an integer of 0 or more. n013 represents an integer of 0 or more. When all R⁰⁹ represent an aromatic group having a methylol group or an alkoxymethyl group, n08 represents an integer of 2 or more, and n012 represent an integer of 2 or more. * represents a bonding site to Si. ** represents a bonding site to R⁰⁹.)

Preferable aspects of nc2, R⁰⁹, and Z^{Z} are the same as those of nc2, R⁹, and Z^{Z} in the formula (c1-2).

In the formula (c0-L-8), n8 is preferably an integer of 2 or more, more preferably an integer of 2 or more and 10 or less, still more preferably an integer of 2 or more and 7 or less, particularly preferably an integer of 2 or more and 5 or less, and most preferably 2 or 3. When all R⁰⁹ represent an aromatic group having a methylol group or an alkoxymethyl group, n8 is preferably an integer of 2 or more and 10 or less, more preferably an integer of 2 or more and 7 or less, still more preferably an integer of 2 or more and 5 or less, and particularly preferably 2 or 3. In the formula (c0-L-9), n9 is preferably an integer of 0 or more and 10 or less, more preferably an integer of 0 or more and 5 or less, still more preferably an integer of 0 or more and 3 or less, and particularly preferably 0 or 1. In the formula (c0-L-10), n10 is preferably an integer of 0 or more and 10 or less, more preferably an integer of 0 or more and 5 or less, and still more preferably an integer of 0 or more and 3 or less. In the formula (c0-L-12), n12 is preferably an integer of 2 or more, more preferably an integer of 2 or more and 10 or less, still more preferably an integer of 2 or more and 5 or less, and particularly preferably an integer of 2 or more and 5 or less. When all R⁰⁹ represent an aromatic group having a methylol group or an alkoxymethyl group, n12 is preferably an integer of 2 or more and 10 or less, more preferably an integer of 2 or more and 5 or less, and still more preferably an integer of 2 or more and 5 or less. In the formula (c0-L-13), n13 is preferably an integer of 0 or more and 10 or less, more preferably an integer of 0 or more and 5 or less, and still more preferably an integer of 0 or more and 3 or less.

### EXAMPLES

The present invention will be described in more detail based on Examples, but the present invention is not limited to these Examples.

### <<Production of Silicon-Containing Crosslinking Agent>>

Cage-type silsesquioxanes (C-1) to (C-4) and cyclic siloxanes (C-5) to (C-8) were produced according to Synthesis Examples (1) to (8) shown below, respectively.

### Synthesis Example (1): Production of Cage-Type Silsesquioxane (C-1)

One-point-five grams of octakis(dimethylsilyloxy)octasilsesquioxane, 1.8 g of (4-vinylphenyl)methanol, 1.5 mg of a platinum(0)-1,3-divinyl-1,1,3,3-tetramethyldisiloxane complex xylene solution (platinum content: 2%), and 18 g of toluene were mixed, and the mixed solution was stirred at room temperature for 13 hours. The mixed solution was concentrated with a rotary evaporator. Twenty grams of tetrahydrofuran and 0.15 g of activated carbon were added to the concentrated solution, followed by stirring at room temperature for 30 minutes, and then the filtrate was collected by filtration using Celite. The filtrate was concentrated with a rotary evaporator. After 2.3 g of tetrahydrofuran was added to the concentrated solution and dissolved, 9.0 g of heptane was added to reprecipitate the product, and the supernatant was removed to purify the product. The purification based on reprecipitation was repeated five times in total. Propylene glycol monomethyl ether (PGME) was added to the obtained product, followed by concentrating and drying with a rotary evaporator, and the process was repeated three times. Thereafter, PGME was added to obtain a concentration of 15%, and the concentrate was dissolved, thereby obtaining 19 g of a 15% PGME solution of the cage-type silsesquioxane (C-1).

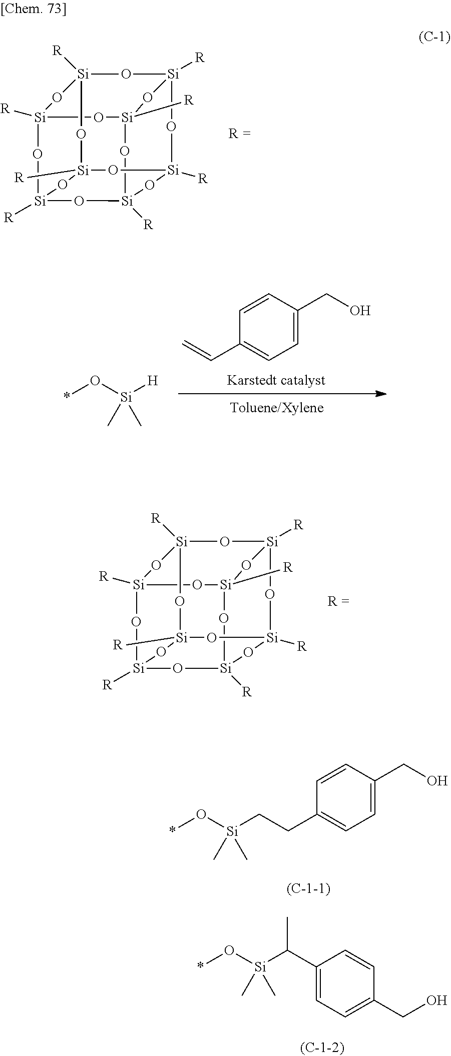

The obtained cage-type silsesquioxane (C-1) is a mixture of cage-type silsesquioxanes in which a group represented by the formula (C-1-1) and a group represented by the formula (C-1-2) are bonded to R in the cage-type structure. The ratio of these groups introduced to R in the cage-type structure was (C-1-1):(C-1-2)=58:42 (molar ratio). The introduction ratio of the groups was calculated based on results of NMR (the same applies hereinafter).

Regarding the obtained cage-type silsesquioxane (C-1), the weight average molecular weight (Mw) in terms of standard polystyrene measured by GPC was 2,000, the molecular weight dispersity (Mw/Mn) was 1.01, and the silicon content was 21%.

The following structure was found by analysis of 1H-NMR, ¹³C-NMR, and ²⁹Si-NMR.
[¹H-NMR (600 MHz, DMSO-d₆)]
a: 8H, 4.9 ppm, b: 16H, 4.3 ppm
[¹³C-NMR (150 MHz, DMSO-d₆)]
c: 16C, 65 ppm
[²⁹Si-NMR (120 MHz, DMSO-d₆)]
d: 8Si, 14 ppm, e: 8Si, −109 ppm

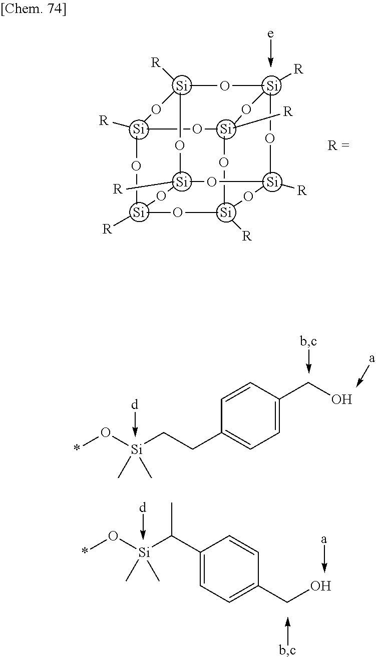

### Synthesis Example (2): Production of Cage-Type Silsesquioxane (C-2)

A cage-type silsesquioxane (C-2) was synthesized in the same manner as in Synthesis Example (1) except that 1.8 g of (4-vinylphenyl)methanol was changed to 2.0 g of (4-allylphenyl)methanol.

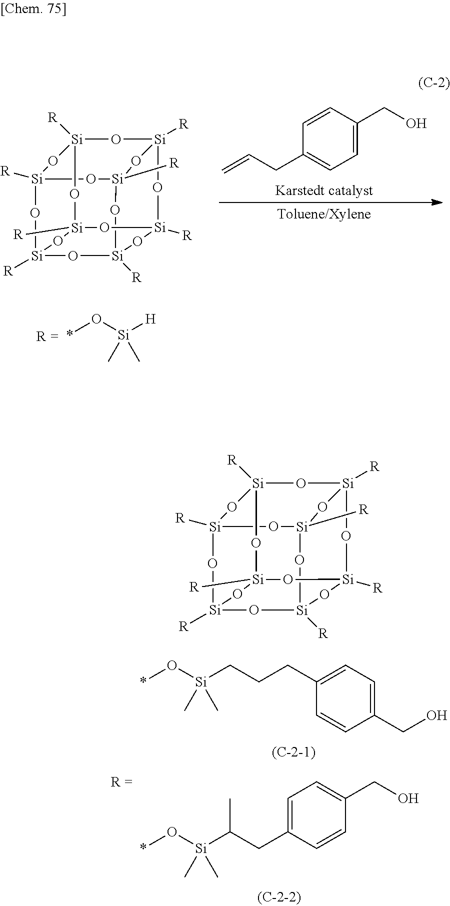

The obtained cage-type silsesquioxane (C-2) is a mixture of cage-type silsesquioxanes in which a group represented by the formula (C-2-1) and a group represented by the formula (C-2-2) are bonded to R in the cage-type structure. The ratio of these groups introduced to R in the cage-type structure was (C-2-1):(C-2-2)=61:39 (molar ratio). The introduction ratio of the groups was calculated based on results of NMR.

Regarding the obtained cage-type silsesquioxane (C-2), the weight average molecular weight (Mw) in terms of standard polystyrene measured by GPC was 2,100, the molecular weight dispersity (Mw/Mn) was 1.01, and the silicon content was 20%.

The following structure was found by analysis of 1H-NMR, ¹³C-NMR, and ²⁹Si-NMR.
[¹H-NMR (600 MHz, DMSO-d₆)]
a: 8H, 4.8 ppm, b: 16H, 4.3 ppm
[¹³C-NMR (150 MHz, DMSO-d₆)]
c: 16C, 64 ppm
[²⁹Si-NMR (120 MHz, DMSO-d₆)]
d: 8Si, 15 ppm, e: 8Si, −110 ppm

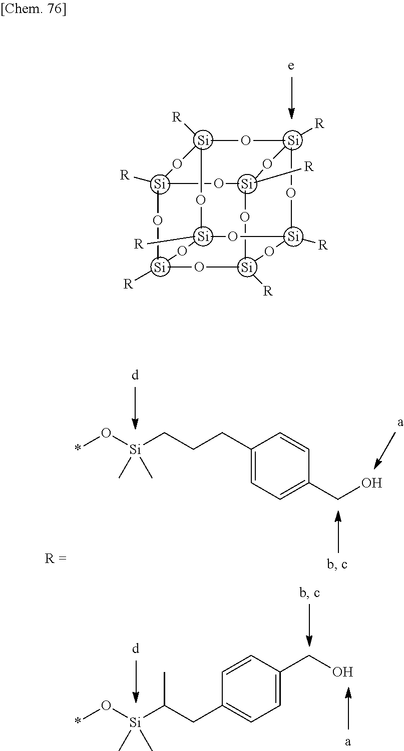

### Synthesis Example (3): Production of Cage-Type Silsesquioxane (C-3)

A cage-type silsesquioxane (C-3) was synthesized in the same manner as in Synthesis Example (1) except that 1.8 g of (4-vinylphenyl)methanol was changed to 2.0 g of 1-ethenyl-4-(methoxymethyl)benzene.

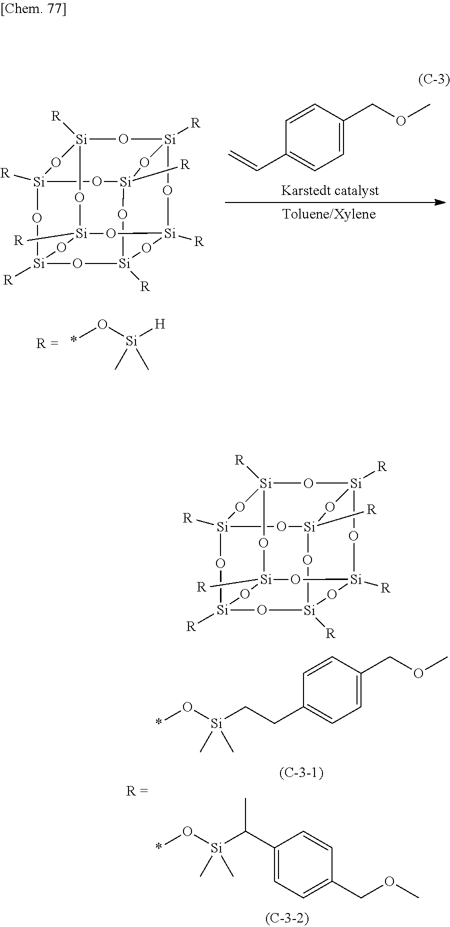

The obtained cage-type silsesquioxane (C-3) is a mixture of cage-type silsesquioxanes in which a group represented by the formula (C-3-1) and a group represented by the formula (C-3-2) are bonded to R in the cage-type structure. The ratio of these groups introduced to R in the cage-type structure was (C-3-1):(C-3-2)=56:44 (molar ratio). The introduction ratio of the groups was calculated based on results of NMR.

Regarding the obtained cage-type silsesquioxane (C-3), the weight average molecular weight (Mw) in terms of standard polystyrene measured by GPC was 2,100, the molecular weight dispersity (Mw/Mn) was 1.02, and the silicon content was 20%.

The following structure was found by analysis of ¹H-NMR, ¹³C-NMR, and ²⁹Si-NMR.
[¹H-NMR (600 MHz, DMSO-d₆)]
a: 24H, 3.4 ppm, b: 16H, 4.1 ppm
[¹³C-NMR (150 MHz, DMSO-d₆)]
c: 16C, 75 ppm
[²⁹Si-NMR (120 MHz, DMSO-d₆)]
d: 8Si, 14 ppm, e: 8Si, −109 ppm

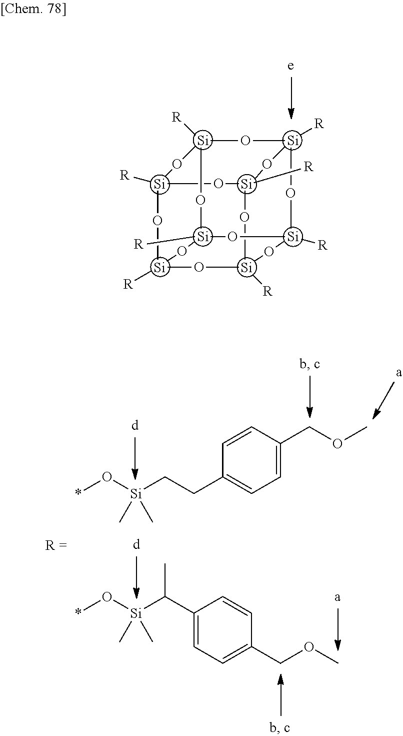

### Synthesis Example (4): Production of Cage-Type Silsesquioxane (C-4)

One-point-five grams of octakis(dimethylsilyloxy)octasilsesquioxane, 1.26 g of 4-vinylphenol, 15 mg of a platinum(0)-1,3-divinyl-1,1,3,3-tetramethyldisiloxane complex xylene solution (platinum content: 2%), and 15 g of toluene were mixed, and the mixed solution was stirred at room temperature for 1.5 hours. To the mixed solution were added 0.40 g of (4-vinylphenyl)methanol and 15 mg of a platinum(0)-1,3-divinyl-1,1,3,3-tetramethyldisiloxane complex xylene solution (platinum content: 2%), followed by stirring at room temperature for 14 hours. To the mixed solution was added 0.15 g of activated carbon, followed by stirring at room temperature for 30 minutes, and then the filtrate was collected by filtration using Celite. The filtrate was concentrated with a rotary evaporator. After 1.5 g of tetrahydrofuran was added to the concentrated solution and dissolved, 4.5 g of heptane was added to reprecipitate the product, and the supernatant was removed to purify the product. The purification based on reprecipitation was repeated five times in total. Propylene glycol monomethyl ether (PGME) was added to the obtained product, followed by concentrating and drying with a rotary evaporator, and the process was repeated three times. Thereafter, PGME was added to obtain a concentration of 15%, and the concentrate was dissolved, thereby obtaining 17 g of a 15% PGME solution of the cage-type silsesquioxane (C-4).

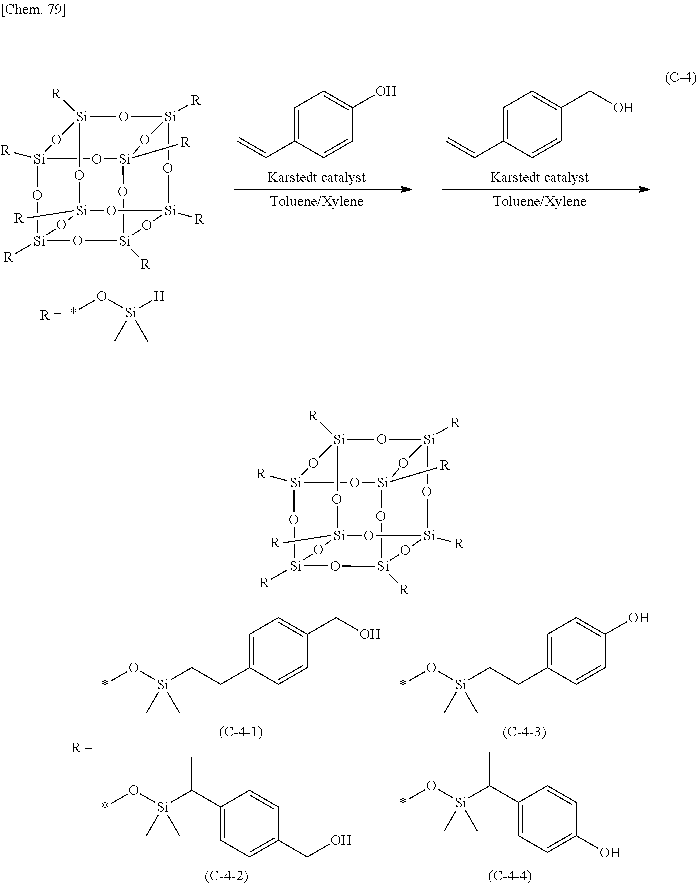

The obtained cage-type silsesquioxane (C-4) is a mixture of cage-type silsesquioxanes in which a group represented by the formula (C-4-1), a group represented by the formula (C-4-2), a group represented by the formula (C-4-3), and a group represented by the formula (C-4-4) are bonded to R in the cage-type structure. The ratio of these groups introduced to R in the cage-type structure was (C-4-1):(C-4-2):(C-4-3):(C-4-4)=7:5:49:39 (molar ratio). The introduction ratio of the groups was calculated based on results of NMR.

Regarding the obtained cage-type silsesquioxane (C-4), the weight average molecular weight (Mw) in terms of standard polystyrene measured by GPC was 1,900, the molecular weight dispersity (Mw/Mn) was 1.04, and the silicon content was 22%.

The following structure was found by analysis of ¹H-NMR, ¹³C-NMR, and ²⁹Si-NMR.
[¹H-NMR (600 MHz, DMSO-d₆)]
a: 7.0H, 8.9 ppm, b: 0.96H, 4.3 ppm
[¹³C-NMR (150 MHz, DMSO-d₆)]
c: 7.0C, 156 ppm, d: 1.9C, 65 ppm
[²⁹Si-NMR (120 MHz, DMSO-d₆)]
e: 8Si, 14 ppm, f: 8Si, −109 ppm

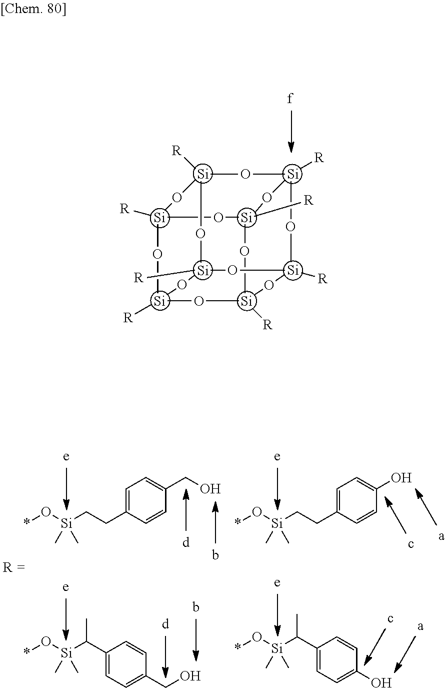

### Synthesis Example (5): Production of Cyclic Siloxane (C-5)

One gram of 2,4,6,8-tetramethylcyclotetrasiloxane, 2.5 g of (4-vinylphenyl)methanol, 10 mg of a platinum(0)-1,3-divinyl-1,1,3,3-tetramethyldisiloxane complex xylene solution (platinum content: 2%), and 10 g of toluene were mixed, and the mixed solution was stirred for 6 hours at 80° C. The mixed solution was concentrated with a rotary evaporator. To the concentrated solution were added 10 g of tetrahydrofuran and 0.10 g of activated carbon, followed by stirring at room temperature for 30 minutes, and then the filtrate was collected by filtration using Celite. The filtrate was concentrated with a rotary evaporator. After 2.0 g of tetrahydrofuran was added to the concentrated solution and dissolved, 12 g of heptane was added to reprecipitate the product, and the supernatant was removed to purify the product. The purification based on reprecipitation was repeated five times in total. Propylene glycol monomethyl ether (PGME) was added to the obtained product, followed by concentrating and drying with a rotary evaporator, and the process was repeated three times. Thereafter, PGME was added to obtain a concentration of 15%, and the concentrate was dissolved, thereby obtaining 17 g of a 15% PGME solution of the cyclic siloxane (C-5).

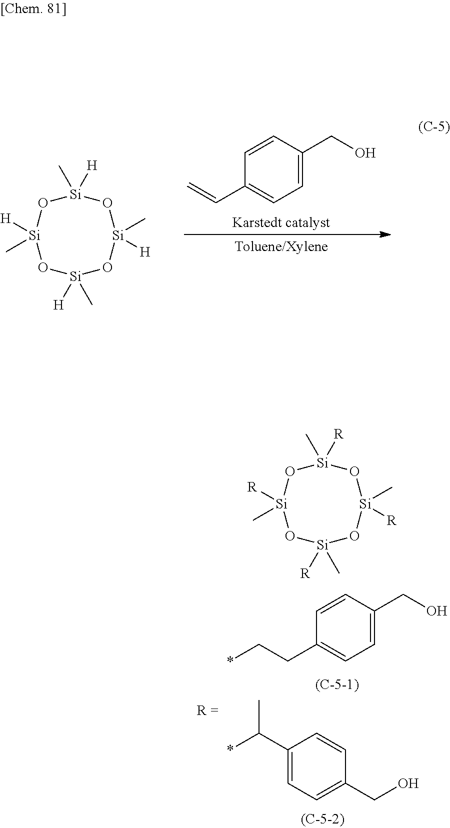

The obtained cyclic siloxane (C-5) is a mixture of cyclic siloxanes in which a group represented by the formula (C-5-1) and a group represented by the formula (C-5-2) are bonded to R in the cyclic structure. The ratio of these groups introduced to R in the cyclic structure was (C-5-1):(C-5-2)=68:32 (molar ratio). The introduction ratio of the groups was calculated based on results of NMR.

Regarding the obtained cyclic siloxane (C-5), the weight average molecular weight (Mw) in terms of standard polystyrene measured by GPC was 700, the molecular weight dispersity (Mw/Mn) was 1.01, and the silicon content was 14%.

The following structure was found by analysis of ¹H-NMR, ¹³C-NMR, and ²⁹Si-NMR.
[¹H-NMR (600 MHz, DMSO-d₆)]
a: 8H, 5.0 ppm, b: 16H, 4.4 ppm
[¹³C-NMR (150 MHz, DMSO-d₆)]
c: 16C, 64 ppm
[²⁹Si-NMR (120 MHz, DMSO-d₆)]
d: 4Si, −24, −20 ppm

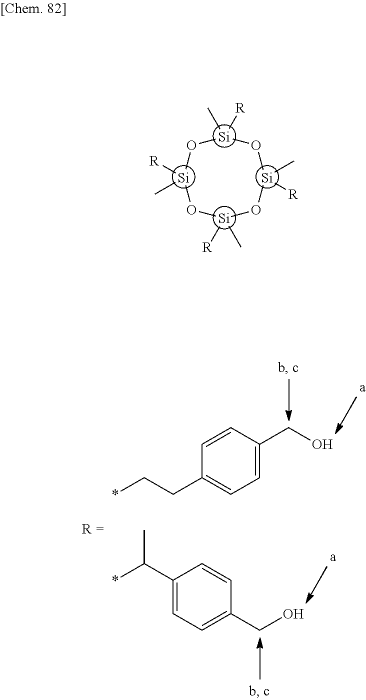

### Synthesis Example (6): Production of Cyclic Siloxane (C-6)

A cyclic siloxane (C-6) was synthesized in the same manner as in Synthesis Example (5) except that 2.5 g of (4-vinylphenyl)methanol was changed to 2.7 g of (4-allylphenyl) methanol.

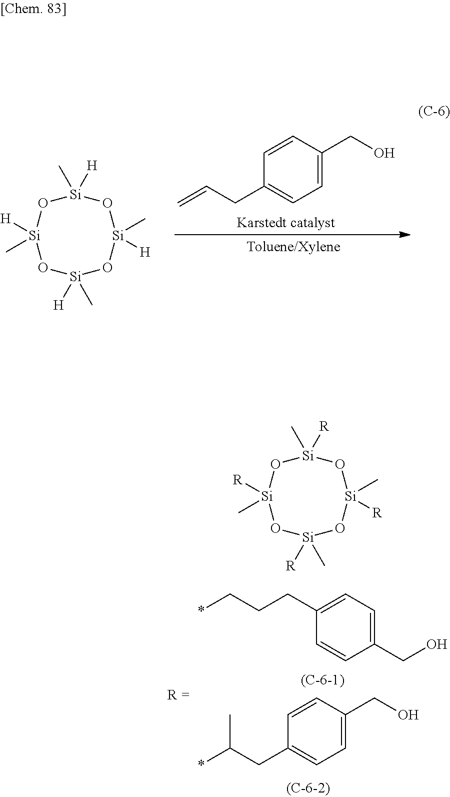

The obtained cyclic siloxane (C-6) is a mixture of cyclic siloxanes in which a group represented by the formula (C-6-1) and a group represented by the formula (C-6-2) are bonded to R in the cyclic structure. The ratio of these groups introduced to R in the cyclic structure was (C-6-1):(C-6-2)=72:28 (molar ratio). The introduction ratio of the groups was calculated based on results of NMR.

Regarding the obtained cyclic siloxane (C-6), the weight average molecular weight (Mw) in terms of standard polystyrene measured by GPC was 800, the molecular weight dispersity (Mw/Mn) was 1.01, and the silicon content was 13%.

The following structure was found by analysis of ¹H-NMR, ¹³C-NMR, and ²⁹Si-NMR.
[¹H-NMR (600 MHz, DMSO-d₆)]
a: 8H, 4.9 ppm, b: 16H, 4.4 ppm
[¹³C-NMR (150 MHz, DMSO-d₆)]
c: 16C, 63 ppm
[²⁹Si-NMR (120 MHz, DMSO-d₆)]
d: 4Si, −25, −21 ppm

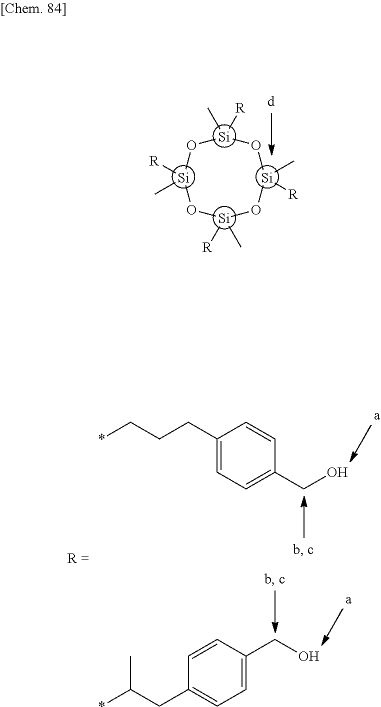

### Synthesis Example (7): Production of Cyclic Siloxane (C-7)

A cyclic siloxane (C-7) was synthesized in the same manner as in Synthesis Example (5) except that 2.5 g of (4-vinylphenyl)methanol was changed to 2.7 g of 1-ethenyl-4-(methoxymethyl)benzene.

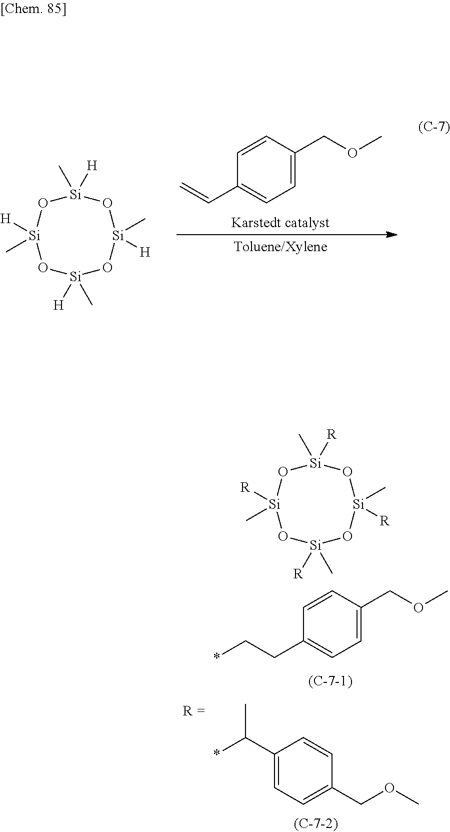

The obtained cyclic siloxane (C-7) is a mixture of cyclic siloxanes in which a group represented by the formula (C-7-1) and a group represented by the formula (C-7-2) are bonded to R in the cyclic structure. The ratio of these groups introduced to R in the cyclic structure was (C-7-1):(C-7-2)=65:35 (molar ratio). The introduction ratio of the groups was calculated based on results of NMR.

Regarding the obtained cyclic siloxane (C-7), the weight average molecular weight (Mw) in terms of standard polystyrene measured by GPC was 800, the molecular weight dispersity (Mw/Mn) was 1.02, and the silicon content was 13%.

The following structure was found by analysis of ¹H-NMR, ¹³C-NMR, and ²⁹Si-NMR.
[¹H-NMR (600 MHz, DMSO-d₆)]
a: 12H, 3.4 ppm, b: 16H, 4.2 ppm
[¹³C-NMR (150 MHz, DMSO-d₆)]
c: 16C, 75 ppm
[²⁹Si-NMR (120 MHz, DMSO-d₆)]
d: 4Si, −24, −20 ppm

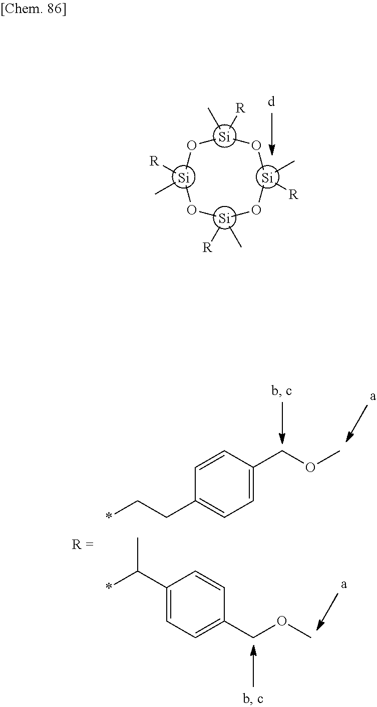

### Synthesis Example (8): Production of Cyclic Siloxane (C-8)

One gram of 2,4,6,8-tetramethylcyclotetrasiloxane, 1.8 g of 4-vinylphenol, 10 mg of a platinum(0)-1,3-divinyl-1,1,3,3-tetramethyldisiloxane complex xylene solution (platinum content: 2%), and 10 g of toluene were mixed, followed by stirring for 2 hours at 80° C. To the mixed solution were added 0.56 g of (4-vinylphenyl)methanol and 10 mg of a platinum(0)-1,3-divinyl-1,1,3,3-tetramethyldisiloxane complex xylene solution (platinum content: 2%), followed by stirring for 6 hours at 80° C. The mixed solution was concentrated with a rotary evaporator. To the concentrated solution were added 10 g of tetrahydrofuran and 0.10 g of activated carbon, followed by stirring at room temperature for 30 minutes, and then the filtrate was collected by filtration using Celite. The filtrate was concentrated with a rotary evaporator. After 2.0 g of tetrahydrofuran was added to the concentrated solution and dissolved, 12 g of heptane was added to reprecipitate the product, and the supernatant was removed to purify the product. The purification based on reprecipitation was repeated five times in total. Propylene glycol monomethyl ether (PGME) was added to the obtained product, followed by concentrating and drying with a rotary evaporator, and the process was repeated three times. Thereafter, PGME was added to obtain a concentration of 15%, and the concentrate was dissolved, thereby obtaining 18 g of a 15% PGME solution of the cyclic siloxane (C-8).

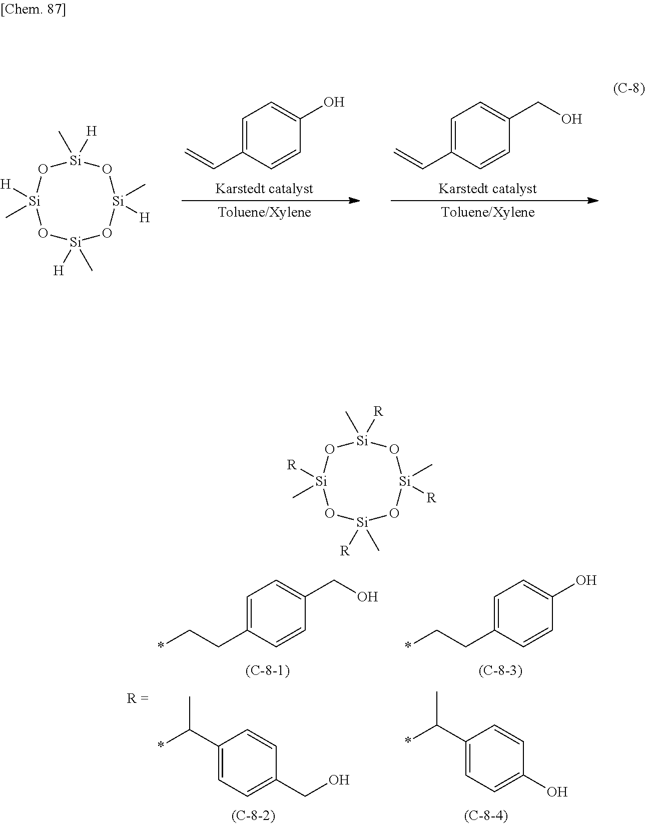

The obtained cyclic siloxane (C-8) is a mixture of cyclic siloxanes in which a group represented by the formula (C-8-1), a group represented by the formula (C-8-2), a group represented by the formula (C-8-3), and a group represented by the formula (C-8-4) are bonded to R in the cyclic structure. The ratio of these groups introduced to R in the cyclic structure was (C-8-1):(C-8-2):(C-8-3):(C-8-4)=8:4:53:35 (molar ratio). The introduction ratio of the groups was calculated based on results of NMR.

Regarding the obtained cyclic siloxane (C-8), the weight average molecular weight (Mw) in terms of standard polystyrene measured by GPC was 700, the molecular weight dispersity (Mw/Mn) was 1.04, and the silicon content was 15%.

The following structure was found by analysis of ¹H-NMR, ¹³C-NMR, and ²⁹Si-NMR.
[¹H-NMR (600 MHz, DMSO-d₆)]
a: 3.5H, 8.9 ppm, b: 0.48H, 5.0 ppm
[¹³C-NMR (150 MHz, DMSO-d₆)]
c: 3.5C, 155 ppm, d: 0.96C, 64 ppm
[²⁹Si-NMR (120 MHz, DMSO-d₆)]
e: 4Si, −24, −20 ppm

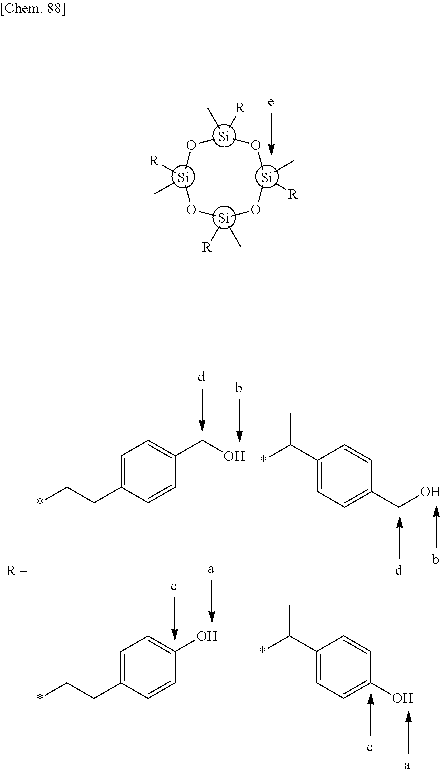

### Preparation of Film-Forming Composition

### Examples 1 to 24 and Comparative Examples 1 to 6

The components shown in Tables 1 to 3 were mixed and dissolved to prepare a film-forming composition in each example.

TABLE 1

| | (A) | (B) | (C) | (D) | (E) | (S) | |
|---|---|---|---|---|---|---|---|
| | Component | Component | Component | Component | Component | Component | |
| Example 1 | A-1 | B-1 | C-1 | D-1 | E-1 | F-1 | F-2 |
| | [100} | [32] | [10] | [41] | [3] | [15800] | [4000] |
| Example 2 | A-1 | B-1 | C-2 | D-1 | E-1 | F-1 | F-2 |
| | [100} | [32] | [10] | [41] | [3] | [15800] | [4000] |
| Example 3 | A-1 | B-1 | C-3 | D-1 | E-1 | F-1 | F-2 |
| | [100} | [32] | [10] | [41] | [3] | [15800] | [4000] |
| Example 4 | A-1 | B-1 | C-4 | D-1 | E-1 | F-1 | F-2 |
| | [100} | [32] | [10] | [41] | [3] | [15800] | [4000] |
| Example 5 | A-1 | B-1 | C-5 | D-1 | E-1 | F-1 | F-2 |
| | [100} | [32] | [10] | [41] | [3] | [15800] | [4000] |
| Example 6 | A-1 | B-1 | C-6 | D-1 | E-1 | F-1 | F-2 |
| | [100} | [32] | [10] | [41] | [3] | [15800] | [4000] |
| Example 7 | A-1 | B-1 | C-7 | D-1 | E-1 | F-1 | F-2 |
| | [100} | [32] | [10] | [41] | [3] | [15800] | [4000] |
| Example 8 | A-1 | B-1 | C-8 | D-1 | E-1 | F-1 | F-2 |
| | [100} | [32] | [10] | [41] | [3] | [15800] | [4000] |
| Example 9 | A-2 | B-1 | C-1 | D-1 | E-1 | F-1 | F-2 |
| | [100] | [32] | [10] | [41] | [3] | [15800] | [4000] |
| Example 10 | A-2 | B-1 | C-5 | D-1 | E-1 | F-1 | F-2 |
| | [100] | [32] | [10] | [41] | [3] | [15800] | [4000] |
| Example 11 | A-1 | B-2 | C-1 | D-1 | E-1 | F-1 | F-2 |
| | [100} | [32] | [10] | [41] | [3] | [15800] | [4000] |
| Example 12 | A-1 | B-2 | C-5 | D-1 | E-1 | F-1 | F-2 |
| | [100} | [32] | [10] | [41] | [3] | [15800] | [4000] |

TABLE 2

| | (A) | (B) | (C) | (D) | (E) | (S) | |
|---|---|---|---|---|---|---|---|
| | Component | Component | Component | Component | Component | Component | |
| Example 13 | A-1 | B-1 | C-1 | D-2 | E-1 | F-1 | F-2 |
| | [100} | [32] | [10] | [27] | [3] | [15800] | [4000] |
| Example 14 | A-1 | B-1 | C-5 | D-2 | E-1 | F-1 | F-2 |
| | [100} | [32] | [10] | [27] | [3] | [15800] | [4000] |
| Example 15 | A-2 | B-2 | C-1 | D-1 | E-1 | F-1 | F-2 |
| | [100] | [36] | [10] | [41] | [3] | [15800] | [4000] |
| Example 16 | A-2 | B-2 | C-5 | D-1 | E-1 | F-1 | F-2 |
| | [100] | [36] | [10] | [41] | [3] | [15800] | [4000] |
| Example 17 | A-2 | B-1 | C-1 | D-2 | E-1 | F-1 | F-2 |
| | [100] | [32] | [10] | [27] | [3] | [15800] | [4000] |
| Example 18 | A-2 | B-1 | C-5 | D-2 | E-1 | F-1 | F-2 |
| | [100] | [32] | [10] | [27] | [3] | [15800] | [4000] |
| Example 19 | A-1 | B-2 | C-1 | D-2 | E-1 | F-1 | F-2 |
| | [100} | [36] | [10] | [27] | [3] | [15800] | [4000] |
| Example 20 | A-1 | B-2 | C-5 | D-2 | E-1 | F-1 | F-2 |
| | [100} | [36] | [10] | [27] | [3] | [15800] | [4000] |
| Example 21 | A-2 | B-2 | C-1 | D-2 | E-1 | F-1 | F-2 |
| | [100] | [36] | [10] | [27] | [3] | [15800] | [4000] |
| Example 22 | A-2 | B-2 | C-5 | D-2 | E-1 | F-1 | F-2 |
| | [100] | [36] | [10] | [27] | [3] | [15800] | [4000] |
| Example 23 | — | B-1 | C-4 | D-1 | E-1 | F-1 | F-2 |
| | | [32] | [100] | [41] | [3] | [15800] | [4000] |
| Example 24 | — | B-1 | C-8 | D-1 | E-1 | F-1 | F-2 |
| | | [32] | [100] | [41] | [3] | [15800] | [4000] |

TABLE 3

| | (A) | (B) | (C) | (D) | (E) | (S) | |
|---|---|---|---|---|---|---|---|
| | Component | Component | Component | Component | Component | Component | |
| Comparative | A-1 | B-1 | C-9 | D-1 | E-1 | F-1 | F-2 |
| Example 1 | [100} | [32] | [10] | [41] | [3] | [15800] | [4000] |
| Comparative | A-1 | B-1 | C-10 | D-1 | E-1 | F-1 | F-2 |
| Example 2 | [100} | [32] | [10] | [41] | [3] | [15800] | [4000] |
| Comparative | A-1 | B-1 | C-11 | D-1 | E-1 | F-1 | F-2 |
| Example 3 | [100} | [32] | [10] | [41] | [3] | [15800] | [4000] |
| Comparative | A-1 | B-1 | C-12 | D-1 | E-1 | F-1 | F-2 |
| Example 4 | [100} | [32] | [10] | [41] | [3] | [15800] | [4000] |
| Comparative | A-1 | B-1 | C-13 | D-1 | E-1 | F-1 | F-2 |
| Example 5 | [100} | [32] | [10] | [41] | [3] | [15800] | [4000] |
| Comparative | A-1 | B-1 | C-14 | D-1 | E-1 | F-1 | F-2 |
| Example 6 | [100} | [32] | [10] | [41] | [3] | [15800] | [4000] |

In Tables 1 to 3, each abbreviation has the following meaning. The numerical value in [ ] is a blending amount (part (s) by mass).

A-1: a resin represented by the following formula (weight average molecular weight (Mw) in terms of standard polystyrene measured by GPC: 4,400, molecular weight dispersity (Mw/Mn): 1.89, silicon content: 24.9%)

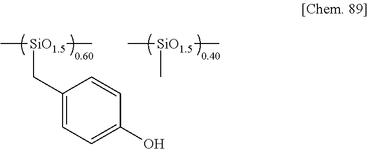

A-2: a resin represented by the following formula (weight average molecular weight (Mw) in terms of standard polystyrene measured by GPC: 4,400, molecular weight dispersity (Mw/Mn): 1.75, silicon content: 20.4%)

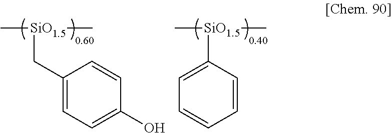

B-1: A compound represented by the following formula

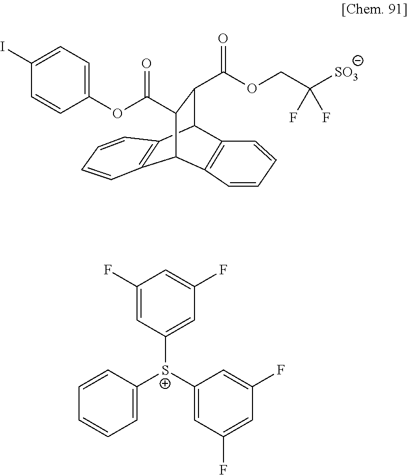

B-2: a compound represented by the following formula

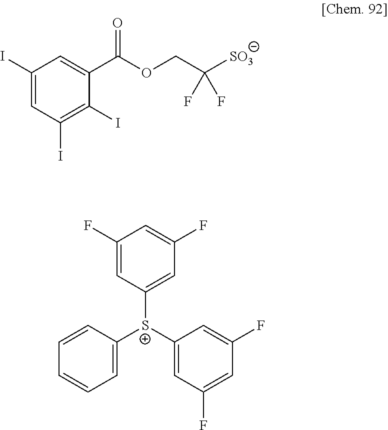

C-1 to C-4: the above cage-type silsesquioxanes (C-1) to (C-4) C-5 to C-8: the cyclic siloxanes (C-5) to (C-8)
C-9: a compound represented by the following formula (molecular weight dispersity (Mw/Mn): 1.01)

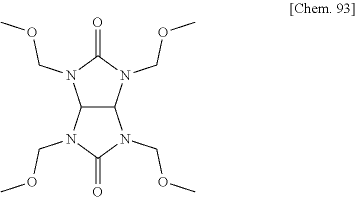

C-10: a compound represented by the following formula

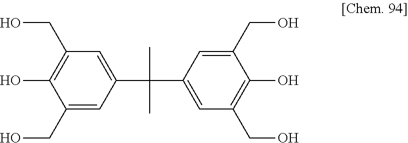 [SMILES: CC(C)(c1cc(CO)c(O)c(CO)c1)c1cc(CO)c(O)c(CO)c1]

C-11: a cage-type silsesquioxane represented by the following formula (molecular weight dispersity (Mw/Mn): 1.02)

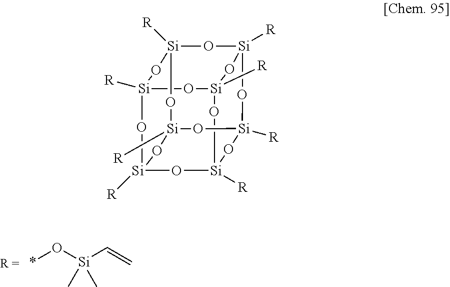

C-12: a cage-type silsesquioxane represented by the following formula (ratio of upper group to lower group introduced to R in cyclic structure: upper group:lower group=56:44 (molar ratio); molecular weight dispersity (Mw/Mn): 1.01)

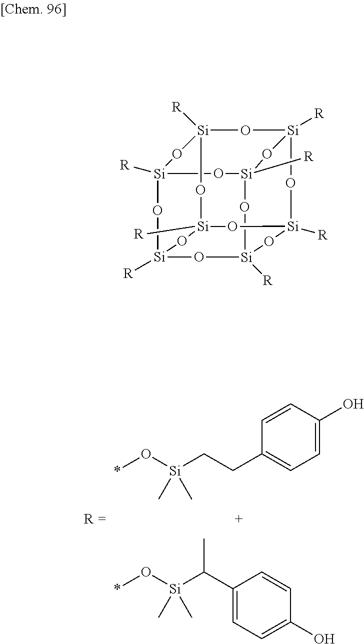

C-13: a cyclic siloxane represented by the following formula (molecular weight dispersity (Mw/Mn): 1.01)

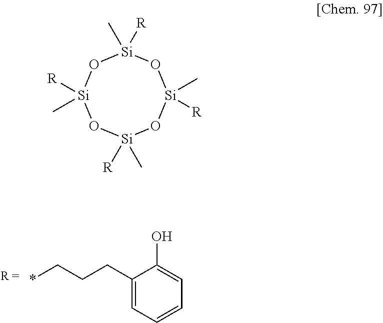

C-14: a cyclic siloxane represented by the following formula (molecular weight dispersity (Mw/Mn): 1.01)

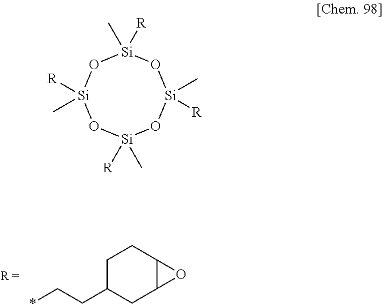

D-1: a compound represented by the following formula

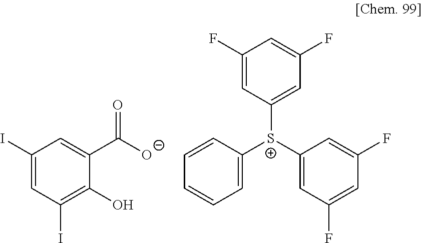 [SMILES: O=C([O-])c1cc(I)cc(I)c1O ; Fc1cc(F)cc([S+](c2ccccc2)c2cc(F)cc(F)c2)c1]

D-2: a compound represented by the following formula

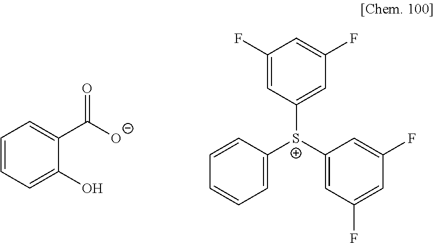 [SMILES: O=C([O-])c1ccccc1O ; Fc1cc(F)cc([S+](c2ccccc2)c2cc(F)cc(F)c2)c1]

E-1: salicylic acid
S-1: propylene glycol monomethyl ether
S-2: propylene glycol monomethyl ether acetate

### <Formation of Resist Pattern>

An organic resist underlayer film composition “AL412” (manufactured by Brewer Science, Inc.) was applied onto a 12-inch silicon wafer using a spin coater and baked on a hot plate at 205° C. for 60 seconds to form an organic underlayer film having a film thickness of 20 nm. The film-forming composition in each example was applied onto the organic underlayer film using a spin coater, and a prebake (PAB) treatment was performed on a hot plate at 90° C. for 60 seconds to form a resist film having a film thickness of 22 nm. The resist film was irradiated with EUV light (13.5 nm) through a photomask by an EUV exposure apparatus NXE3400 (manufactured by ASML, NA (number of aperture)=0.33, illumination conditions: Annular σ-in =0.60, σ-out=0.82). Thereafter, the resist film was subjected to a PEB treatment for 60 seconds at 90° C. Subsequently, alkaline development was performed for 10 seconds with a 2.38 mass % TMAH aqueous solution (product name: NMD-3, manufactured by Tokyo Ohka Kogyo Co., Ltd.) at 23° C. Thereafter, rinsing was performed with pure water for 30 seconds, and drying with shaking was performed. As a result, a line and space pattern (LS pattern) having a line width of 14 nm was formed.

### [Evaluation of Optimum Exposure Dose (Eop)]

The optimum exposure dose Eop (mJ/cm²) at which an LS pattern having a line width of 14 nm was formed by the formation of a resist pattern was determined. The results are shown in Tables 4 to 6.

### [Evaluation of Line Width Roughness (LWR)]

Regarding an LS pattern having a line width of 14 nm formed by the formation of a resist pattern, 3σ, which is a scale indicating LWR, was determined. The results are shown in Tables 4 to 6. “3σ” indicates a triple value (3σ) (unit: nm) of a standard deviation (o) determined from a measurement result obtained by measuring 400 line positions in a longitudinal direction of the line with a scanning electron microscope (acceleration voltage: 800 V, product name: S-9380, manufactured by Hitachi High-Technologies Corporation). The roughness of the line sidewall is reduced as the 3σ value decreases, which means that a LS pattern with a more uniform width is obtained.

TABLE 4

| | Eop | LWR |
|---|---|---|
| | (mJ/cm²) | (nm) |
| Example 1 | 56 | 2.11 |
| Example 2 | 57 | 2.16 |
| Example 3 | 55 | 2.13 |
| Example 4 | 60 | 2.28 |
| Example 5 | 57 | 2.17 |
| Example 6 | 56 | 2.23 |
| Example 7 | 56 | 2.19 |
| Example 8 | 59 | 2.30 |
| Example 9 | 58 | 2.14 |
| Example 10 | 59 | 2.18 |
| Example 11 | 53 | 2.15 |
| Example 12 | 54 | 2.20 |

TABLE 5

| | Eop | LWR |
|---|---|---|
| | (mJ/cm²) | (nm) |
| Example 13 | 59 | 2.17 |
| Example 14 | 59 | 2.18 |
| Example 15 | 54 | 2.14 |
| Example 16 | 53 | 2.19 |
| Example 17 | 58 | 2.18 |
| Example 18 | 58 | 2.20 |
| Example 19 | 56 | 2.16 |
| Example 20 | 57 | 2.21 |
| Example 21 | 60 | 2.17 |
| Example 22 | 61 | 2.20 |
| Example 23 | 58 | 2.23 |
| Example 24 | 59 | 2.25 |

TABLE 6

| | Eop | LWR |
|---|---|---|
| | (mJ/cm²) | (nm) |
| Comparative | 56 | 2.70 |
| Example 1 | | |
| Comparative | 60 | 2.79 |
| Example 2 | | |
| Comparative | 58 | 3.64 |
| Example 3 | | |
| Comparative | — | — |
| Example 4 | | |
| Comparative | — | — |
| Example 5 | | |
| Comparative | 59 | 3.80 |
| Example 6 | | |

From the results of Tables 4 to 6, it was found that when the film-forming compositions in Examples 1 to 24 were used, the roughness of the line side wall was reduced and a resist pattern having a better shape was formed as compared with the case where the film-forming compositions in Comparative Examples 1 to 3 and Comparative Example 6 were used. When the film-forming compositions in Comparative Examples 4 and 5 were used, resolution was not achieved.

What is claimed is:

1. A film-forming composition comprising: a silicon-containing polymer (A) having a phenolic hydroxy group; a photoacid generating agent (B); a silicon-containing crosslinking agent (C1) having a methylol group and/or an alkoxymethyl group; and a base component (D) that controls diffusion of an acid generated upon exposure to light, or the photoacid generating agent (B); a silicon-containing crosslinking agent (C2) having a methylol group and/or an alkoxymethyl group and a phenolic hydroxy group; and the base component (D).

2. The film-forming composition according to claim 1, wherein the methylol group and/or the alkoxymethyl group contained in the silicon-containing crosslinking agent (C1) or the silicon-containing crosslinking agent (C2) are/is bonded to an aromatic group or a nitrogen atom.

3. The film-forming composition according to claim 1, wherein the silicon-containing crosslinking agent (C1) comprises at least one selected from the group consisting of a cage-type silsesquioxane (C1-1) represented by the following formula (c1-1) and a cyclic siloxane (C1-2) represented by the following formula (c1-2), and
the silicon-containing crosslinking agent (C2) comprises at least one selected from the group consisting of a cage-type silsesquioxane (C2-1) represented by the following formula (c2-1) and a cyclic siloxane (C2-2) represented by the following formula (c2-2): 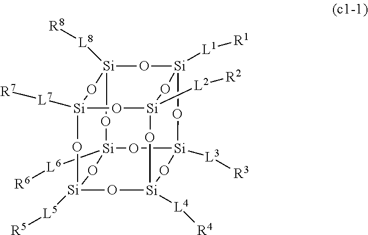
wherein R¹ to R⁸ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R¹ to R⁸ represents an aromatic group having a methylol group or an alkoxymethyl group, or a nitrogen atom-containing group having a methylol group or an alkoxymethyl group, L¹ to L⁸ each independently represents a divalent linking group represented by any one of the following formulas (c1-L-1) to (c1-L-7): 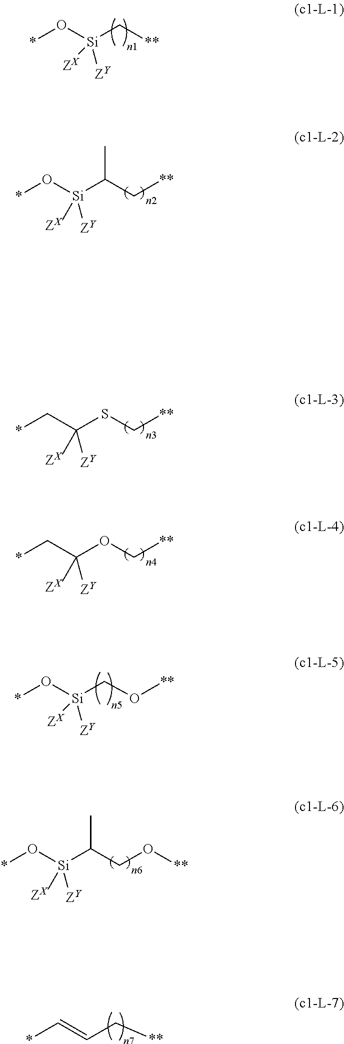
wherein Z^{X} and Z^{Y} each independently represents a hydrocarbon group having 1 or more and 6 or less carbon atoms or a hydrogen atom, n1 to n7 each independently represent an integer of 0 or more and 10 or less, * represents a bonding site to Si, ** represents a bonding site to any one of R¹ to R⁸, 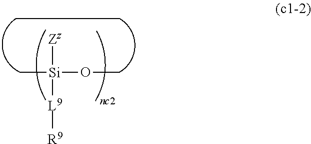
wherein R⁹ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁹ represents an aromatic group having a methylol group or an alkoxymethyl group, or a nitrogen atom-containing group having a methylol group or an alkoxymethyl group, L⁹ each independently represents a divalent linking group represented by any one of the following formulas (c2-L-1) to (c2-L-6), nc2 represents an integer of 3 or more and 7 or less, and Z^{Z} each independently represents a hydrocarbon group having 1 or more and 6 or less carbon atoms or a hydrogen atom, 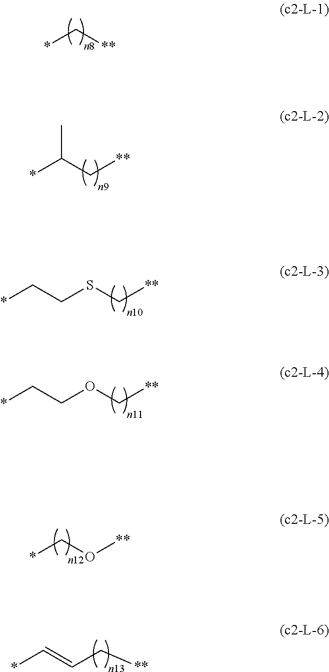
wherein n8 to n13 each independently represents an integer of 0 or more and 10 or less, * represents a bonding site to Si, ** represents a bonding site to R⁹, 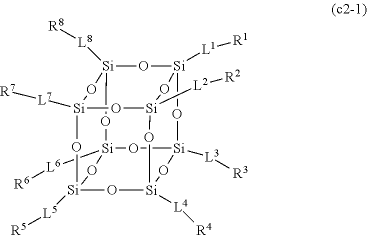
wherein R¹ to R⁹ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R¹ to R⁸ represents an aromatic group having a methylol group or an alkoxymethyl group, or a nitrogen atom-containing group having a methylol group or an alkoxymethyl group, at least another one of R¹ to R⁸ represents an aromatic group having a phenolic hydroxy group, L¹ to L⁸ each independently represents a divalent linking group represented by any one of the formulas (c1-L-1) to (c1-L-7): 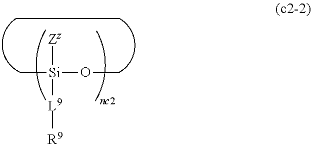
wherein R⁹ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁹ represents an aromatic group having a methylol group or an alkoxymethyl group, or a nitrogen atom-containing group having a methylol group or an alkoxymethyl group, at least another one of R⁹ represents an aromatic group having a phenolic hydroxy group, L⁹ each independently represents a divalent linking group represented by any one of the above formulas (c2-L-1) to (c2-L-6), nc2 represents an integer of 3 or more and 7 or less, and Z^{Z} each independently represents a hydrocarbon group having 1 or more and 6 or less carbon atoms or a hydrogen atom.

4. The film-forming composition according to claim 1, wherein the silicon-containing polymer (A) comprises a silicon-containing polymer (A0) having a constitutional unit represented by the following formula (a0-1): 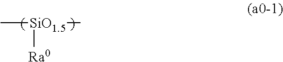
wherein Ra⁰ represents an organic group having 1 or more and 40 or less carbon atoms or a hydrogen atom.

5. The film-forming composition according to claim 4, wherein the silicon-containing polymer (A0) has a constitutional unit represented by the following formula (a0-1-1) 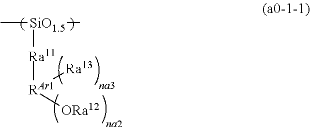
wherein R^{Ar1} represents an aromatic hydrocarbon group, Ra¹¹ represents a divalent linking group or a single bond, Ra¹² represents a hydrocarbon group having 1 or more and 6 or less carbon atoms or a hydrogen atom, Ra¹³ represents a hydrocarbon group having 1 or more and 6 or less carbon atoms or a hydrogen atom, na2 represents 1 or 2, and na3 represents an integer of 0 or more and 4 or less.

6. The film-forming composition according to claim 1, wherein the photoacid generating agent (B) comprises an onium salt represented by the following formula (b0): 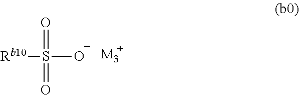
wherein R^{b10} represents an organic group having 1 or more and 40 or less carbon atoms, and M₃⁺ represents an onium cation.

7. The film-forming composition according to claim 1, wherein the base component (D) comprises at least one selected from the group consisting of a compound represented by the following formula (d0-1) and a compound represented by the following formula (d0-2): 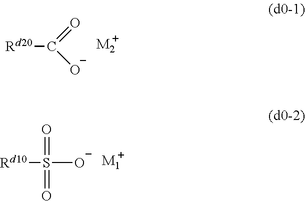
wherein R^{d20} represents an organic group having 1 or more and 40 or less carbon atoms, M₂⁺ represents an onium cation, wherein R^{d10} represents an organic group having 1 or more and 40 or less carbon atoms, and M₁⁺ represents an onium cation.

8. A method for producing a patterned cured film, the method comprising: forming a coating film made of the film-forming composition according to claim 1 on a support;
exposing the coating film position-selectively; and
developing the exposed coating film to form a patterned cured film.

9. The method for producing a patterned cured film according to claim 8, wherein the coating film is exposed to extreme ultraviolet rays.

10. A cage-type silsesquioxane represented by the following formula (c0-1): 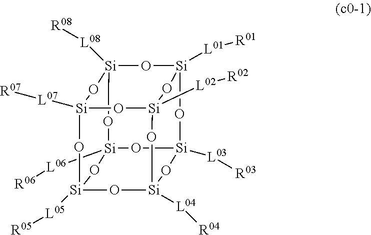
wherein R⁰¹ to R⁰⁸ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁰¹ to R⁰⁸ represents an aromatic group having a methylol group or an alkoxymethyl group, or a nitrogen atom-containing group having a methylol group or an alkoxymethyl group, L⁰¹ to L⁰⁸ each independently represents a divalent linking group represented by any one of the following formulas (c0-L-1) to (c0-L-3) and (c0-L-5) to (c0-L-7): 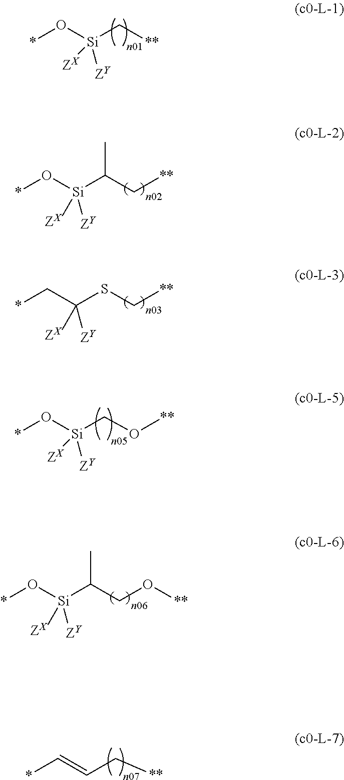
wherein Z^{X} and Z^{Y} each independently represents a hydrocarbon group having 1 to 6 carbon atoms or a hydrogen atom, n01 represents an integer of 0 or more, n02 represents an integer of 0 or more, n03 represents an integer of 0 or more, n05 represents an integer of 0 or more, n06 represents an integer of 0 or more, n07 represents an integer of 0 or more, when all R⁰¹ to R⁰⁸ represent an aromatic group having a methylol group, n01 represents an integer of 3 or more, and n02 represents an integer of 1 or more, * represents a bonding site to Si, ** represents a bonding site to any one of R⁰¹ to R⁰⁸.

11. A cyclic siloxane represented by the following formula (c0-2): 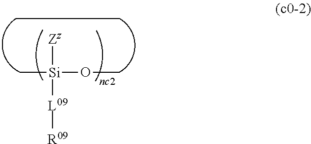
wherein R⁰⁹ each independently represents an aromatic group having a methylol group or an alkoxymethyl group, a nitrogen atom-containing group having a methylol group or an alkoxymethyl group, an aromatic group having a phenolic hydroxy group, a hydrocarbon group having 1 or more and 10 or less carbon atoms, or a hydrogen atom, at least one of R⁰⁹ represents an aromatic group having a methylol group or an alkoxymethyl group, or a nitrogen atom-containing group having a methylol group or an alkoxymethyl group, L⁰⁹ each independently represents a divalent linking group represented by any one of the following formulas (c0-L-8) to (c0-L-10), (c0-L-12), and (c0-L-13), nc2 represents an integer of 3 or more and 7 or less, Z^{Z} each independently represents a hydrocarbon group having 1 or more and 6 or less carbon atoms or a hydrogen atom, 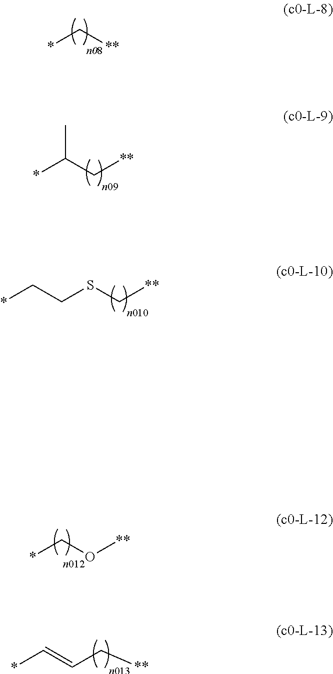
wherein n08 represents an integer of 0 or more, n09 represents an integer of 0 or more, n010 represents an integer of 0 or more, n012 represents an integer of 0 or more, n013 represents an integer of 0 or more, when all R⁰⁹ represent an aromatic group having a methylol group or an alkoxymethyl group, n08 represents an integer of 2 or more, and n012 represent an integer of 2 or more, * represents a bonding site to Si, and ** represents a bonding site to R⁰⁹.
